(19) United States
(12) Patent Application Publication
(10) Pub. No.: US 2026/0314420 A1
(43) Pub. Date: Oct. 8, 2026

(54) SEMICONDUCTOR DEVICES AND METHODS OF FORMATION

(71) Applicant: Taiwan Semiconductor Manufacturing Company, Ltd., Hsinchu (TW)

(72) Inventors: Chun-Hao LIN, Tainan City (TW); Yu-Jen WANG, Kaohsiung City (TW); Meng-Ying LI, Tainan City (TW); Chun-Hao CHOU, Tainan City (TW)

(21) Appl. No.: 19/169,678

(22) Filed: Apr. 3, 2025

(51) Int. Cl. H10W 42/00; G03F 7/00

(52) U.S. Cl. CPC H10W 42/121; G03F 7/70475; G03F 7/70033

(57) ABSTRACT

A multiple-reticle exposure technique is used to manufacture monolithic superchips that have a greater amount of device area than if single-reticle exposures were used to manufacture the monolithic superchips. As described herein, different lateral regions of a semiconductor device (e.g., a monolithic superchip) may be patterned by different sets of lithography reticles. The multiple-reticle exposure technique may be expanded to manufacture a seal ring structure around the lateral regions of the semiconductor device. The multiple-reticle exposure technique may be used to manufacture the seal ring structure to have different attributes (e.g., different sizes, different shapes, different configurations) in different lateral regions of the semiconductor device, which provides for increased manufacturing flexibility in manufacturing monolithic superchips.

### BACKGROUND

An extreme ultraviolet (EUV) radiation source includes a collector, which includes a curved mirror that is configured to collect EUV radiation and to focus the EUV radiation toward an intermediate focus near an intermediate focus cap (IF cap) of the EUV radiation source. The EUV radiation is produced from a laser produced plasma (LPP) that is generated by exposing droplets of tin (Sn) to a carbon dioxide (CO₂) laser. The Sn droplets are generated by a droplet generator (DG) head, which provides the Sn droplets into a vacuum chamber to an irradiation site where the Sn droplets are irradiated by a focused laser beam.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an embodiment of a lithography system described herein.

FIGS. 2A and 2B are diagrams of an example implementation of a semiconductor device described herein.

FIGS. 3A-3L are diagrams of an example implementation of forming a semiconductor device described herein.

FIGS. 4A and 4B are diagrams of an example implementation of a semiconductor device described herein.

FIGS. 5A-5K are diagrams of an example implementation of forming a semiconductor device described herein.

FIGS. 6A and 6B are diagrams of an example stacked semiconductor device described herein.

FIGS. 7A-7P are diagrams of an example implementation of forming a stacked semiconductor device described herein.

FIG. 8 illustrates an example implementation of reticles for a multiple-reticle exposure technique described herein.

FIGS. 9A and 9B are diagrams of example implementations of semiconductor devices described herein.

FIG. 10 is a diagram of example implementation of a semiconductor device described herein.

FIG. 11 is a diagram of example implementation of a semiconductor device described herein.

FIG. 12 is a diagram of example implementation of a semiconductor device described herein.

FIG. 13 is a diagram of an example implementation of a semiconductor package described herein.

FIG. 14 is a flowchart of an example process associated with forming a semiconductor device described herein.

FIG. 15 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A lithography system may include a radiation source and an exposure tool. The radiation source (e.g., an EUV radiation source or another type of radiation source) may be configured to generate radiation such as EUV radiation and/or another type of electromagnetic radiation (e.g., light). An exposure tool (e.g., an EUV scanner or another type of exposure tool) may be configured to focus the radiation onto a reflective reticle (or a photomask) such that a pattern is transferred from the reticle onto a semiconductor substrate using the radiation. The radiation may reflect off of the reticle based on a pattern of the reticle. The radiation may be reflected onto the semiconductor substrate such that the pattern of the reticle is transferred to the semiconductor substrate.

Various industries rely on advanced semiconductor devices for high speed, low power, and/or specialized operations. High performance computing (HPC) devices may process large amounts of data at high speed to perform complex calculations. HPC devices may include computer chips capable of performing multiple functions to perform parallel processing of data. Internet of Things (IOT) devices may include computer chips that include a diverse set of features (including processing, memory, wireless communication, and storage) all the while needing to operate efficiently and sometimes off of battery power. Communications devices (e.g., radio frequency (RF) devices, datacenter communication devices) may include computer chips that perform high speed and high bandwidth communication.

Each specialized computer chip may be integrated with multiple devices and contact structures that would otherwise be found on multiple non-specialized chips. As a result, the size of such specialized computer chips (e.g., “superchips”) may need to be larger than the non-specialized chips to include the devices and/or contact structures that may be required to perform a diverse set of functions. However, the size of a computer chip (e.g., a semiconductor die manufactured on a wafer) may be limited by the size of a reticle used to pattern the layers of the computer chip. This may prevent specialized computer chips from having the requisite device density to execute a diverse set of functions. As a result, multiple specialized computer chips may need to be interconnected to achieve such function sets, which may increase manufacturing complexity.

In some implementations described herein, a multiple-reticle exposure technique is used to manufacture monolithic superchips that have a greater amount of device area than if single-reticle exposures were used to manufacture the monolithic superchips. As described herein, different lateral regions of a semiconductor device (e.g., a monolithic superchip) may be patterned by different sets of lithography reticles. For example, a first set of reticles may be used to pattern a first lateral region of the semiconductor device, and a second set of reticles may be used to pattern a second lateral region of the semiconductor device. This enables the lateral regions of the semiconductor device to be manufactured to have particular functional areas (e.g., memory, logic, analog, communication) that are integrated onto a single monolithic superchip as opposed to being distributed across multiple discrete computer chips that are each manufactured using a single-reticle exposure technique.

As further described herein, the multiple-reticle exposure technique may be expanded to manufacture a seal ring structure around the lateral regions of the semiconductor device. The multiple-reticle exposure technique may be used to manufacture the seal ring structure to have different attributes (e.g., different sizes, different shapes, different configurations) in different lateral regions of the semiconductor device, which provides for increased manufacturing flexibility in manufacturing monolithic superchips.

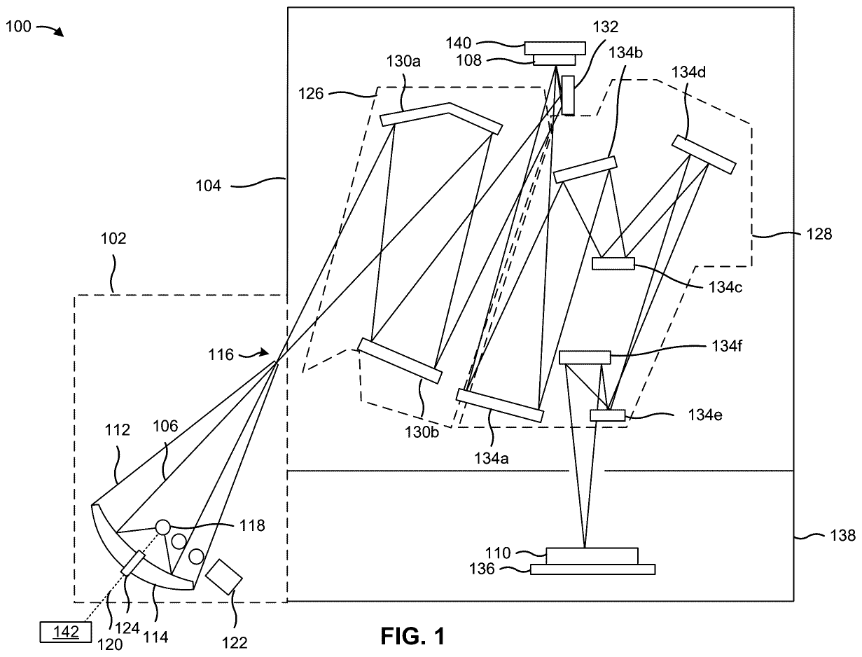

FIG. 1 is a diagram of an embodiment of a lithography system 100 described herein. The lithography system 100 includes an EUV lithography system or another type of lithography system that is configured to transfer a pattern to a semiconductor substrate using mirror-based optics. The lithography system 100 may be configured for use in a semiconductor processing environment such as a semiconductor foundry or a semiconductor fabrication facility.

As shown in FIG. 1, the lithography system 100 includes the radiation source 102 and an exposure tool 104. The radiation source 102 (e.g., an EUV radiation source or another type of radiation source) is configured to generate radiation 106 such as EUV radiation and/or another type of electromagnetic radiation (e.g., light). The exposure tool 104 (e.g., an EUV scanner or another type of exposure tool) is configured to focus the radiation 106 onto a reflective reticle 108 (or a photomask) such that a pattern is transferred from the reticle 108 onto a semiconductor wafer 110 using the radiation 106.

The radiation source 102 includes a vessel 112 and a collector 114 in the vessel 112. The collector 114, includes a curved mirror that is configured to collect the radiation 106 generated by the radiation source 102 and to focus the radiation 106 toward an intermediate focus 116. The radiation 106 is produced from a plasma that is generated from droplets 118 (e.g., tin (Sn) droplets or another type of droplets) being exposed to a laser beam 120. The droplets 118 are provided across the front of the collector 114 by a droplet generator (DG) head 122. The DG head 122 is pressurized to provide a fine and controlled output of the droplets 118.

A laser source, such as a pulse carbon dioxide (CO2) laser, generates the laser beam 120. The laser beam 120 is provided (e.g., by a beam delivery system to a focus lens) such that the laser beam 120 is focused through a window 124 of the collector 114. The laser beam 120 is focused onto the droplets 118 which generates the plasma. The plasma produces a plasma emission, some of which is the radiation 106. The laser beam 120 is pulsed at a timing that is synchronized with the flow of the droplets 118 from the DG head 122.

The exposure tool 104 includes an illuminator 126 and a projection optics box (POB) 128. The illuminator 126 includes a plurality of reflective mirrors that are configured to focus and/or direct the radiation 106 onto the reticle 108 so as to illuminate the pattern on the reticle 108. The plurality of mirrors include, for example, a mirror 130a and a mirror 130b. The mirror 130a includes a field facet mirror (FFM) or another type of mirror that includes a plurality of field facets. The mirror 130b includes a pupil facet mirror (PFM) or another type of mirror that also includes a plurality of pupil facets. The facets of the mirrors 130a and 130b are arranged to focus, polarize, and/or otherwise tune the radiation 106 from the radiation source 102 to increase the uniformity of the radiation 106 and/or to increase particular types of radiation components (e.g., transverse electric (TE) polarized radiation, transverse magnetic (TM) polarized radiation). Another mirror 132 (e.g., a relay mirror) is included to direct radiation 106 from the illuminator 126 onto the reticle 108.

The projection optics box 128 includes a plurality of mirrors that are configured to project the radiation 106 onto the semiconductor wafer 110 after the radiation 106 is modified based on the pattern of the reticle 108. The plurality of reflective mirrors include, for example, mirrors 134a-134f. In some implementations, the mirrors 134a-134f are configured to focus or reduce the radiation 106 into an exposure field, which may include one or more die areas on the semiconductor wafer 110.

The exposure tool 104 includes a wafer stage 136 (e.g., a substrate stage) configured to support the semiconductor wafer 110. Moreover, the wafer stage 136 is configured to move (or step) the semiconductor wafer 110 through a plurality of exposure fields as the radiation 106 transfers the pattern from the reticle 108 onto the semiconductor wafer 110. The wafer stage 136 is included in a bottom module 138 of the exposure tool 104. The bottom module 138 includes a removable subsystem of the exposure tool 104. The bottom module 138 may slide out of the exposure tool 104 and/or otherwise may be removed from the exposure tool 104 to enable cleaning and inspection of the wafer stage 136 and/or the components of the wafer stage 136. The bottom module 138 isolates the wafer stage 136 from other areas in the exposure tool 104 to reduce and/or minimize contamination of the semiconductor wafer 110. Moreover, the bottom module 138 may provide physical isolation for the wafer stage 136 by reducing the transfer of vibrations (e.g., vibrations in the semiconductor processing environment in which the lithography system 100 is located, vibrations in the lithography system 100 during operation of the lithography system 100) to the wafer stage 136 and, therefore, the semiconductor wafer 110. This reduces movement and/or disturbance of the semiconductor wafer 110, which reduces the likelihood that the vibrations may cause a pattern misalignment.

The exposure tool 104 also includes a reticle stage 140 that configured to support and/or secure the reticle 108. Moreover, the reticle stage 140 is configured to move or slide the reticle through the radiation 106 such that the reticle 108 is scanned by the radiation 106. In this way, a pattern that is larger than the field or beam of the radiation 106 may be transferred to the semiconductor wafer 110.

The lithography system 100 includes a laser source 142. The laser source 142 is configured to generate the laser beam 120. The laser source 142 may include a CO2-based laser source or another type of laser source. Due to the wavelength of the laser beams generated by a CO2-based laser source in an infrared (IR) region, the laser beams may be highly absorbed by tin, which enables the CO2-based laser source to achieve high power and energy for pumping tin-based plasma. In some implementations, the laser beam 120 includes a plurality of types of laser beams that the laser source 142 generates using a multi-pulse technique (or a multi-stage pumping technique), in which the laser source 142 generates a pre-pulse laser beam and main-pulse laser beam to achieve greater heating efficiency of tin (Sn)-based plasma to increase conversion efficiency.

In an example exposure operation (e.g., an EUV exposure operation), the DG head 122 provides the stream of the droplets 118 across the front of the collector 114. The laser beam 120 contacts the droplets 118, which causes a plasma to be generated. The laser source 142 generates and provides a pre-pulse laser beam toward a target material droplet in the stream of the droplets 118, and the pre-pulse laser beam is absorbed by the target material droplet. This transforms the target material droplet into disc shape or a mist. Subsequently, the laser source 142 provides a main-pulse laser beam with large intensity and energy toward the disc-shaped target material or target material mist. Here, the atoms of the target material are neutralized, and ions are generated through thermal flux and shock wave. The main-pulse laser beam pumps ions to a higher charge state, which causes the ions to radiate the radiation 106 (e.g., EUV light).

The radiation 106 is collected by the collector 114 and directed out of the vessel 112 and into the exposure tool 104 toward the mirror 130a of the illuminator 126. The mirror 130a reflects the radiation 106 onto the mirror 130b, which reflects the radiation 106 onto the mirror 132 toward the reticle 108. The radiation 106 is modified by the pattern in the reticle 108. In other words, the radiation 106 reflects off of the reticle 108 based on the pattern of the reticle 108. The reflective reticle 108 directs the radiation 106 toward the mirror 134a in the projection optics box 128, which reflects the radiation 106 onto the mirror 134b. The radiation 106 continues to be reflected and reduced in the projection optics box 128 by the mirrors 134c-134f. The mirror 134f reflects the radiation 106 onto the semiconductor wafer 110 such that the pattern of the reticle 108 is transferred to the semiconductor wafer 110. The above-described exposure operation is an example, and the lithography system 100 may operate according to other EUV techniques and radiation paths that include a greater quantity of mirrors, a lesser quantity of mirrors, and/or a different configuration of mirrors.

As indicated above, FIG. 1 is provided as an example. Other examples may differ from what is described with regard to FIG. 1.

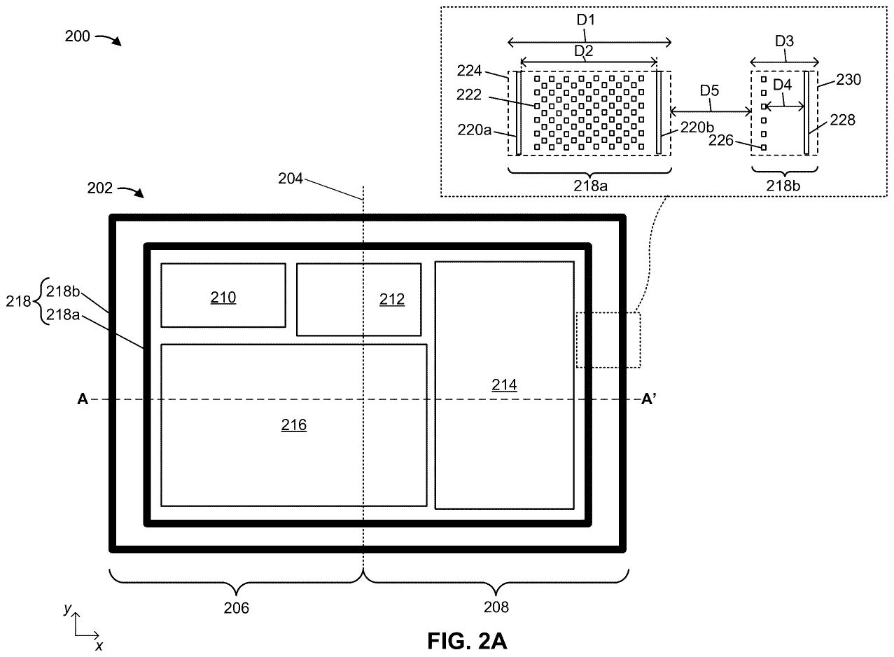

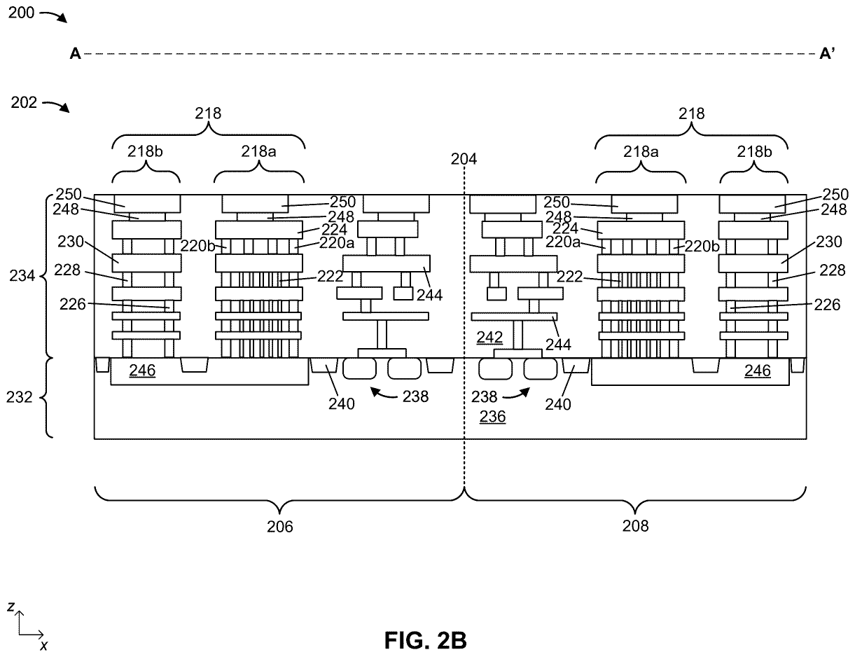

FIGS. 2A and 2B are diagrams of an example implementation 200 of a semiconductor device 202 described herein. FIG. 2A illustrates a top view of the semiconductor device 202, and FIG. 2B illustrates a cross-section view of the semiconductor device 202 along the line A-A′ in FIG. 2A.

As shown in FIG. 2A, the semiconductor device 202 may include an interface 204 between different lateral regions 206 and 208 of the semiconductor device 202. The lateral regions 206 and 208 may be laterally adjacent in an x-direction and/or in a y-direction in the semiconductor device 202, and may include different top view layouts of functional regions. For example, functional regions 210-216 may be laterally distributed across the lateral regions 206 and 208, where the functional region 210 is included in the lateral region 206, portions of the functional region 212 are included in the lateral regions 206 and 208, the functional region 214 is included in the lateral region 208, and portions of the functional region 216 are included in the lateral regions 206 and 208. The top view layout and the quantity, sizes, shapes, and/or arrangements of functional regions 210-216 in the semiconductor device 202 are examples, and other layouts, quantities, sizes, shapes, and/or arrangements are within the scope of the present disclosure.

The semiconductor device 202 may be a system-on-chip (SoC) die, a central processing unit (CPU) die, a graphics processing unit (GPU) die, a digital signal processing (DSP) die, an application specific integrated circuit (ASIC) die, an image sensor die, an HPC die, and/or another type of semiconductor die that includes a plurality of functional regions 210-216. Each of the functional regions 210-216 may be manufactured to include integrated circuits that are configured to perform a particular set of functions of the semiconductor device 202. For example, the functional region 210 may be a memory region (or a memory core) of the semiconductor device 202 that includes integrated circuitry configured to perform memory functions of the semiconductor device 202. As another example, the functional region 212 may be an analog circuitry region (or an analog core) of the semiconductor device 202 that includes integrated circuitry configured to perform analog functions of the semiconductor device 202. As another example, the functional region 214 may be an RF circuitry region (or an RF core) of the semiconductor device 202 that includes integrated circuitry configured to perform RF communication functions of the semiconductor device 202. As another example, the functional region 216 may be a logic circuitry region (or a logic core) of the semiconductor device 202 that includes integrated circuitry configured to perform logic functions of the semiconductor device 202. In some implementations, the semiconductor device 202 include another type of functional region or a different combination of functional regions.

The lateral regions 206 and 208 are regions of the semiconductor device 202 that were patterned by different sets of reticles 108 of the lithography system 100 during manufacturing of the semiconductor device 202. For example, one or more layers and/or structures of the lateral region 206 were patterned using a first set of reticles 108, and one or more layers and/or structures of the lateral region 208 were patterned using a second set of reticles 108. The first set of reticles and the second set of reticles 108 may be used sequentially to form different layouts in the lateral regions 206 and 208 from the same layer formed across the semiconductor device 202. The interface 204 may correspond to a boundary between the area (e.g., the lateral region 206) that was patterned using the first set of reticles 108, and the area (e.g., the lateral region 208) that was patterned using the second set of reticles 108. Thus, one or more of the functional regions 210-216, such as the functional region 210, are formed using only the first set of reticles 108. One or more of the functional regions 210-216, such as the functional region 214, are formed using only the second set of reticles 108. One or more of the functional regions 210-216, such as the functional regions 212 and 216, are formed using both the first and second sets of reticles 108. For example, the first set of reticles 108 may be used to form the portions of the functional regions 212 and 216 located in the lateral region 206, and the second set of reticles 108 may be used to form the portions of the functional regions 212 and 216 located in the lateral region 208.

This multiple-reticle exposure technique enables the lateral regions 206 and 208 of the semiconductor device 202 to be formed using a plurality of sets of reticles 108 so that the lateral footprint of the semiconductor device 202 may be expanded monolithically. In other words, the functional regions 210-216 may be formed on the same substrate using a plurality of sets of reticles 108 such that the functional regions 210-216 are integrated onto a single work piece, as opposed to the functional regions 210-216 being formed on separate work pieces and bonded together or otherwise integrated by wire-bonding on a package substrate. In some implementations, the multiple-reticle exposure technique enables the semiconductor device 202 to be formed as a monolithic “superchip” that has a lateral size of approximately 25 millimeters by approximately 30 millimeters or greater.

As further shown in FIG. 2A, the semiconductor device 202 may include a multiple seal ring structure 218 that laterally surrounds the functional regions 210-216 of the semiconductor device 202. The multiple seal ring structure 218 may include a plurality of seal ring structures that each include a plurality of interconnected layers of metallization structures and interconnect structures that provide increased structural rigidity for the semiconductor device 202, which may reduce the likelihood of cracking, warpage, and/or another type of physical damage that might otherwise result from physical stresses that are exerted on the semiconductor device 202. Additionally and/or alternatively, the multiple seal ring structure 218 may be configured to provide a humidity seal for the semiconductor device 202, which may reduce the likelihood of humidity ingress in the semiconductor device 202.

The multiple seal ring structure 218 may include a plurality of segments, including a first set of segments around the perimeter of the lateral region 206 and a second set of segments around the perimeter of the lateral region 208. The first set of segments and the second set of segments may be connected together to form a continuous seal around the perimeter of the semiconductor device 202.

As further shown in FIG. 2A, the multiple seal ring structure 218 may include a seal ring structure 218a that laterally surrounds the functional regions 210-216, and a seal ring structure 218b that laterally surrounds the seal ring structure 218a. The seal ring structure 218a may be referred to as an inner seal ring structure, and the seal ring structure 218b may be referred to as an outer seal ring structure 218b. The seal ring structures 218a and 218b may each include a closed-loop structure that fully and continuously surrounds the perimeter of the semiconductor device 202.

As shown in a detailed view in FIG. 2A, the seal ring structure 218a may include an arrangement of layers of interconnect structures and layers of metallization structures. A layer of interconnect structures of the seal ring structure 218a may include an arrangement of an inner line interconnect structure 220a, an outer line interconnect structure 220b, and a plurality of pillar interconnect structures 222 laterally between the inner line interconnect structure 220a and the outer line interconnect structure 220b. The inner line interconnect structure 220a and the outer line interconnect structure 220b may each include a trench-like via that continuously extends around the perimeter of the semiconductor device 202, whereas the pillar interconnect structures 222 include vertically elongated interconnect structures that are spaced apart from each other. The pillar interconnect structures 222 may be arranged in a checkerboard pattern around the perimeter of the semiconductor device 202 and/or another type of pattern.

Vertically adjacent layers of interconnect structures of the seal ring structure 218a may be coupled together by a metallization structure 224 located vertically between the adjacent layers of interconnect structures. A metallization structure 224 may include a substantially planar metal line that continuously extends around the perimeter of the semiconductor device 202.

The seal ring structure 218a may have a lateral width (indicated in FIG. 2A as dimension D1) and a lateral spacing (indicated in FIG. 2A as dimension D2) between the inner line interconnect structure 220a and the outer line interconnect structure 220b of the seal ring structure 218a. The lateral width may be in a direction that is approximately perpendicular to the length of the seal ring structure 218a, and may be included in a range of approximately 4 microns to approximately 6 microns. However, other values and ranges are within the scope of the present disclosure. In some implementations, the lateral width of the seal ring structure 218a may be included in a range of approximately 3 microns to approximately 5 microns. However, other values and ranges are within the scope of the present disclosure.

As further shown in the detailed view in FIG. 2A, the seal ring structure 218b may include an arrangement of layers of interconnect structures and layers of metallization structures. A layer of interconnect structures of the seal ring structure 218b may include an arrangement of an inner pillar interconnect structures 226 and an outer line interconnect structure 228. The outer line interconnect structure 228 may include a trench-like via that continuously extends around the perimeter of the semiconductor device 202, whereas the inner pillar interconnect structures 226 include vertically elongated interconnect structures that are spaced apart from each other. The inner pillar interconnect structures 226 may be arranged around the perimeter of the semiconductor device 202.

Vertically adjacent layers of interconnect structures of the seal ring structure 218b may be coupled together by a metallization structure 230 located vertically between the adjacent layers of interconnect structures. A metallization structure 230 may include a substantially planar metal line that continuously extends around the perimeter of the semiconductor device 202.

The seal ring structure 218b may have a lateral width (indicated in FIG. 2A as dimension D3) and a lateral spacing (indicated in FIG. 2A as dimension D4) between the inner pillar interconnect structures 226 and the outer line interconnect structure 228 of the seal ring structure 218b. The lateral width may be in a direction that is approximately perpendicular to the length of the seal ring structure 218b, and may be included in a range of approximately 1.5 microns to approximately 2.5 microns. However, other values and ranges are within the scope of the present disclosure. In some implementations, the lateral width of the seal ring structure 218b may be included in a range of approximately 1.0 microns to approximately 2 microns. However, other values and ranges are within the scope of the present disclosure.

In some implementations, the lateral width of the seal ring structures 218a is greater than the lateral width of the seal ring structure 218b (e.g., D1>D3). In some implementations, the lateral width of the seal ring structures 218a is less than the lateral width of the seal ring structure 218b (e.g., D1<D3). In some implementations, the lateral width of the seal ring structures 218a and the lateral width of the seal ring structure 218b are approximately equal (e.g., D1=D3).

The seal ring structure 218a may be spaced apart from the seal ring structures 218b by a distance (indicated in FIG. 2A as dimension D5). In some implementations, the distance between the seal ring structure 218a and the seal ring structure 218b is included in a range of approximately 2 microns to approximately 3 microns. However, other values and ranges are within the scope of the present disclosure.

As shown in FIG. 2B, the semiconductor device 202 may include a device layer 232 and a frontside interconnect layer 234 on a frontside of the device layer 232. The device layer 232 and the front interconnect layer 234 may be vertically arranged in the z-direction in the semiconductor device 202.

The device layer 232 may include a substrate layer 236. The substrate layer 236 may correspond to a portion of a semiconductor wafer on which the semiconductor device 202 was formed. The substrate layer 236 may include a silicon (Si) substrate, a substrate formed of a material including silicon, a III-V compound semiconductor material substrate such as gallium arsenide (GaAs), a silicon on insulator (SOI) substrate, or another type of semiconductor substrate.

The device layer 232 may further include one or more integrated circuit devices 238 in and/or on the frontside of the substrate layer 236. The integrated circuit devices 238 may each include transistors (e.g., planar transistors, fin field effect transistors (finFETs), gate all around (GAA) transistors), pixel sensors, capacitors, resistors, inductors, photodetectors, transceivers, transmitters, receives, optical circuits, diodes, and/or other types of passive and/or active integrated circuit devices.

The lateral regions 206 and 208 may include different arrangements of integrated circuit devices 238 that were formed using different sets of reticles 108. The integrated circuit devices 238 in the lateral region 206 may be arranged in integrated circuits that implement the functionality of the functional regions 210, 212, and 216. Similarly, the integrated circuit devices 238 in the lateral region 208 may be arranged in integrated circuits that implement the functionality of the functional regions 212, 214, and 216.

Isolation regions 240 may also be included in the substrate layer 236 to provide electrical isolation for the integrated circuit devices 238. One or more isolation regions 240 may include implant regions of the substrate layer 236 in which dopants were implanted. The dopants may include, for example, n-type dopants (such as phosphorous (P) and/or arsenic (As)) and/or p-type dopants (such as boron (B)). Additionally and/or alternatively, one or more of the isolation regions 240 may include shallow trench isolation (STI) structures. An STI structure may be a dielectric structure that extends into the frontside of the substrate layer 236, and may include one or more dielectric materials such as a silicon oxide material (SiOx such as SiO₂), a silicon nitride material (SiₓN_{y} such as Si₃N₄), and/or another suitable dielectric material.

The frontside interconnect layer 234 includes one or more dielectric layers 242 that may be arranged in a direction (e.g., the z-direction) that is approximately perpendicular to the substrate layer 236. The dielectric layer(s) 242 may include backend dielectric layers (e.g., interlayer dielectric (ILD) layers, intermetal dielectric (IMD) layers) and etch stop layers (ESLs) that are arranged in an alternating manner in the frontside interconnect layer 234. The dielectric layer(s) 242 may each include an oxide (e.g., a silicon oxide (SiOx) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SixNy), silicon carbide (SiC), silicon oxynitride (SiON), and/or another suitable dielectric material.

The frontside interconnect layer 234 further includes one or more layers of conductive structures 244 (e.g., electrically conductive structures) in the dielectric layer(s) 242. The conductive structures 244 may be electrically coupled and/or physically coupled to one or more of the integrated circuit devices 238 in the device layer 232, and/or may be electrically interconnected together in the frontside interconnect layer 234. The conductive structures 244 correspond to circuit routing that enables signals and/or power to be provided to and/or from the integrated circuit devices 238. The conductive structures 244 may include a combination of conductive structures that extend primarily horizontally in the frontside interconnect layer 234 (e.g., trenches, conductive lines) and that are interconnected by interconnect structures (e.g., vias) that extend primarily vertically in the frontside interconnect layer 234. The conductive structures 244 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The layers of conductive structures 244 of the frontside interconnect layer 234 may be arranged in a vertical manner to facilitate electrical signals and/or power to be routed between the device layer 232 and external connectors coupled to the semiconductor device 202. The conductive structures 244 may be arranged in alternating layers of metallization layers (referred to as “M”-layers) and via layers (referred to as “V”-layers). Each metallization layer may include one or more conductive structures laterally arranged in the frontside interconnect layer 234, and each via layer may include one or more interconnect structures that interconnect the metallization layers in the frontside interconnect layer 234. As an example, a metal-0 (M0) layer may be located at the bottom of the frontside interconnect layer 234 (e.g., interfacing the frontside of the device layer 232) and may be coupled to the integrated circuit devices 238 in the substrate layer 236, a via-0 (V0) layer may be located above and coupled to the MO layer in the frontside interconnect layer 234, a metal-1 (M1) layer may be located above and coupled to the V0 layer in the frontside interconnect layer 234, a via-1 (V1) layer may be located above and coupled to the MI layer in the frontside interconnect layer 234, a metal-2 (M2) layer may be located above and electrically coupled to the V1 layer in the frontside interconnect layer 234, and so on. In some implementations, the frontside interconnect layer 234 includes nine (9) stacked metallization layers (e.g., M0-M8). In other implementations, the contact layer (referred to as “CO”-layer) may be located at the bottom of the frontside interconnect layer 234 and may be coupled to the integrated circuit devices 238 in the substrate layer 236, a metal-1 (M1) layer may be located above and coupled to the CO layer in the frontside interconnect layer 234, and so on. In some implementations, the frontside interconnect layer 234 includes another quantity of stacked metallization layers.

The lateral regions 206 and 208 may include different arrangements of conductive structures 244 that were formed using different sets of reticles 108. The conductive structures 244 in the lateral region 206 may be arranged to distribute signals and/or power for the integrated circuits in the functional regions 210, 212, and 216. Similarly, the conductive structures 244 in the lateral region 208 may be arranged to distribute signals and/or power for the integrated circuits in the functional regions 212, 214, and 216. In some implementations, the conductive structures 244 in the lateral regions 206 and/or 208 may be arranged to distribute signals and/or power between two or more of the functional regions 210-216.

The multiple seal ring structure 218 may also be located in the dielectric layer(s) 242 of the frontside interconnect layer 234. The seal ring structure 218 may include a plurality of vertically-arranged layers (e.g., in the z-direction) of conductive structures that laterally surround the semiconductor device 202. For example, the seal ring structure 218a may include vertically alternating layers of interconnect structures and metallization structures in the frontside interconnect layer 234. As another example, the seal ring structure 218b may include vertically alternating layers of interconnect structures and metallization structures in the frontside interconnect layer 234.

The one or more layers of interconnect structures of the seal ring structure 218a may include an inner line interconnect structure 220a, an outer line interconnect structure 220b, and a plurality of pillar interconnect structures 222 laterally between the inner line interconnect structure 220a and the outer line interconnect structure 220b. In some implementations, the lateral width of the inner line interconnect structure 220a, the lateral width of the outer line interconnect structure 220b, and/or the lateral width of the pillar interconnect structures 222 may gradually increase in ascending layers from the bottom of the frontside interconnect layer 234 (e.g. vertically adjacent to the device layer 232) to the top of the frontside interconnect layer 234. Vertically adjacent layers of inner line interconnect structures 220a, outer line interconnect structures 220b, and pillar interconnect structures 222 may be interconnected by layers of metallization structures 224. The inner line interconnect structure 220a, the outer line interconnect structure 220b, the pillar interconnect structures 222, and/or the metallization structures 224 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The one or more layers of interconnect structures of the seal ring structure 218b may include a plurality of inner pillar interconnect structures 226 and an outer line interconnect structure 228 laterally adjacent to the inner pillar interconnect structures 226. In some implementations, the lateral width of the inner pillar interconnect structures 226 and/or the lateral width of the outer line interconnect structure 228 may gradually increase in ascending layers from the bottom of the frontside interconnect layer 234 (e.g. vertically adjacent to the device layer 232) to the top of the frontside interconnect layer 234. Vertically adjacent layers of inner pillar interconnect structures 226 and outer line interconnect structures 228 may be interconnected by layers of metallization structures 230. The inner pillar interconnect structure 226, the outer line interconnect structure 228, and/or the metallization structures 230 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

In some implementations, the multiple seal ring structure 218 extends into the substrate layer 236 of the device layer 232 of the semiconductor device 202. For example, the multiple seal ring structure 218 may further include one or more isolation regions 240 in the substrate layer 236 and/or one or more doped regions 246 in the substrate layer 236 such that the additional isolation regions 240 and the doped regions 246 are vertically adjacent to the layers of conductive structures of the multiple seal ring structure 218 in the frontside interconnect layer 234. This extends the electrical isolation provided by the multiple seal ring structure 218 into the device layer 232.

At the top of the multiple seal ring structure 218, the seal ring structure 218a and the seal ring structure 218b may each include top vias 248 and top pads 250. The top vias 248 and the top pads 250 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The lateral regions 206 and 208 may include different arrangements of conductive structures for the sections of the seal ring structures 218a and/or 218b that were formed in the lateral regions 206 and 208 using different sets of reticles 108. For example, a first set of reticles 108 may be used to form a layer of an inner line interconnect structure 220a, an outer line interconnect structure 220b, and a plurality of pillar interconnect structures 222 in a section of the seal ring structure 218a in the lateral region 206 that have first sizes, first shapes, first spacings, and/or a first arrangement. A second set of reticles 108 may be used to form the layer of the inner line interconnect structure 220a, the outer line interconnect structure 220b, and the plurality of pillar interconnect structures 222 in a section of the seal ring structure 218a in the lateral region 208 that have second sizes different than the first sizes, second shapes different than the first shapes, second spacings different than the first spacings, and/or a second arrangement different than the first arrangement.

As another example, the first set of reticles 108 may be used to form a layer of a metallization structure 224 in a section of the seal ring structure 218a in the lateral region 206 that has a first width, a first thickness, and/or a first shape. The second set of reticles 108 may be used to form the layer of a metallization structure 224 in a section of the seal ring structure 218a in the lateral region 208 that has a second width that is different than the first width, a second thickness that is different than the first thickness, and/or a second shape that is different than the first shape.

As another example, the first set of reticles 108 may be used to form a layer of a plurality of inner pillar interconnect structures 226 and an outer line interconnect structure 228 in a section of the seal ring structure 218b in the lateral region 206 that have first sizes, first shapes, first spacings, and/or a first arrangement. The second set of reticles 108 may be used to form the layer of the plurality of inner pillar interconnect structures 226 and the outer line interconnect structure 228 in a section of the seal ring structure 218b in the lateral region 208 that have second sizes different than the first sizes, second shapes different than the first shapes, second spacings different than the first spacings, and/or a second arrangement that is different than the first arrangement.

As another example, the first set of reticles 108 may be used to form a layer of a metallization structure 230 in a section of the seal ring structure 218b in the lateral region 206 that has a first width, a first thickness, and/or a first shape. The second set of reticles 108 may be used to form the layer of the metallization structure 230 in a section of the seal ring structure 218b in the lateral region 208 that has a second width that is different than the first width, a second thickness that is different than the first thickness, and/or a second shape that is different than the first shape.

As indicated above, FIGS. 2A and 2B are provided as an example. Other examples may differ from what is described with regard to FIGS. 2A and 2B.

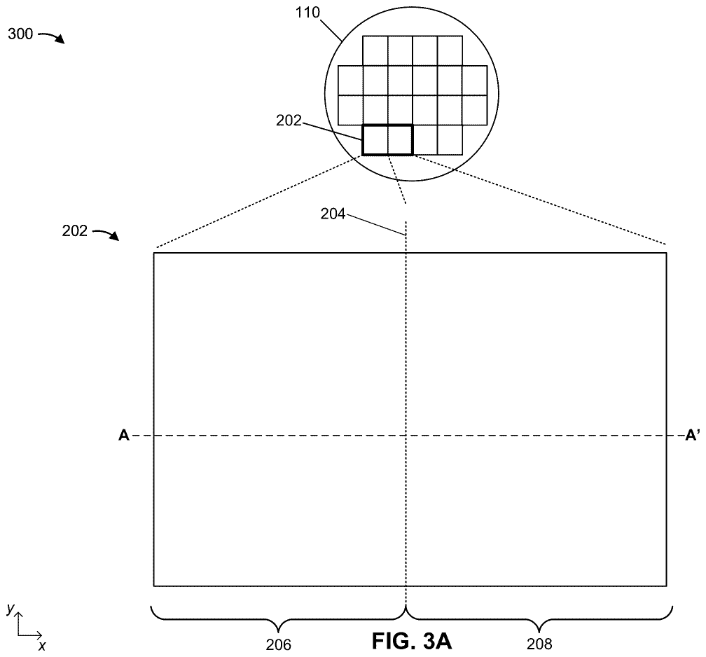

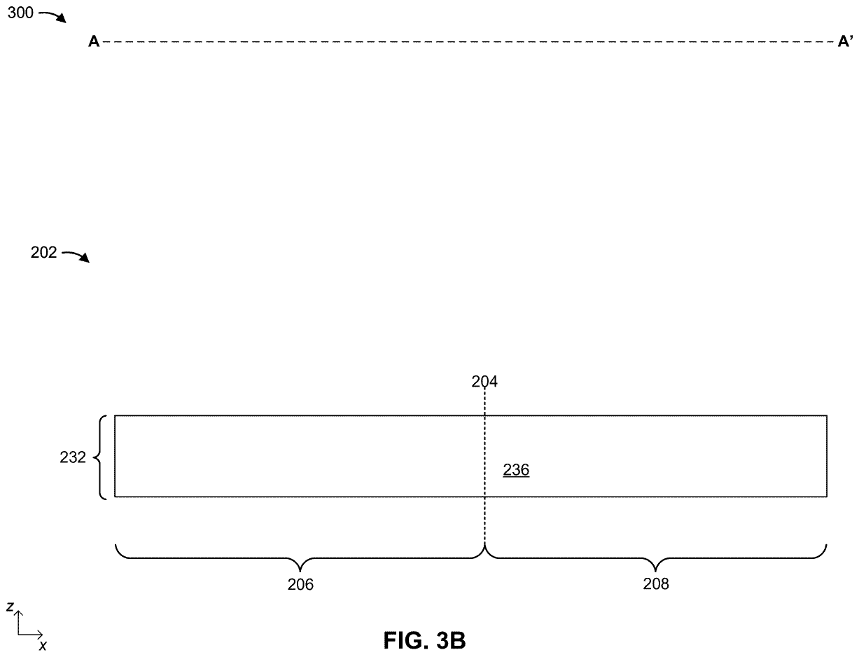

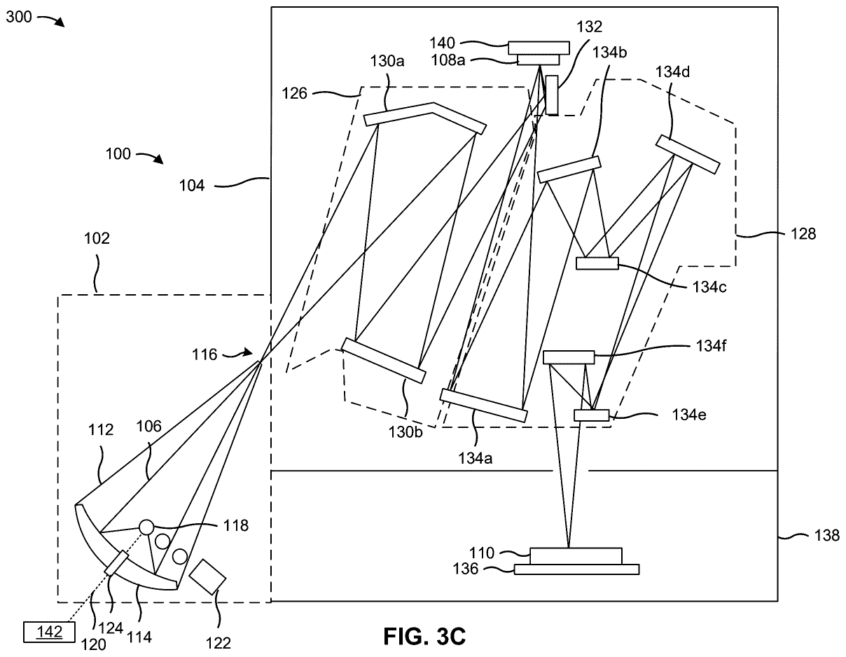

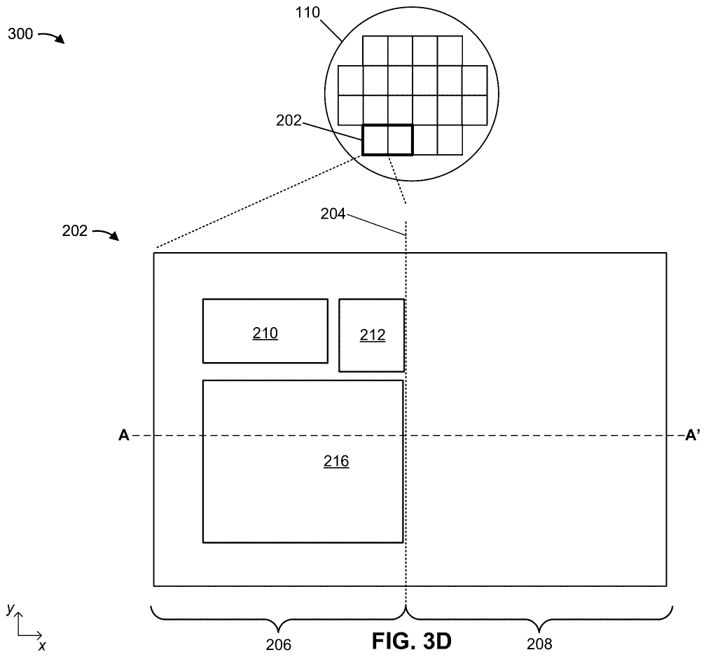

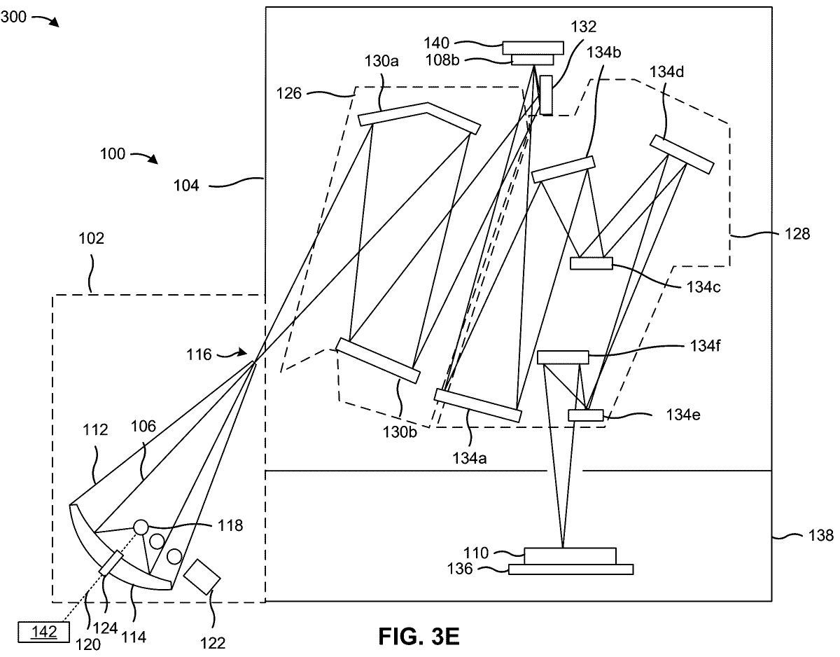

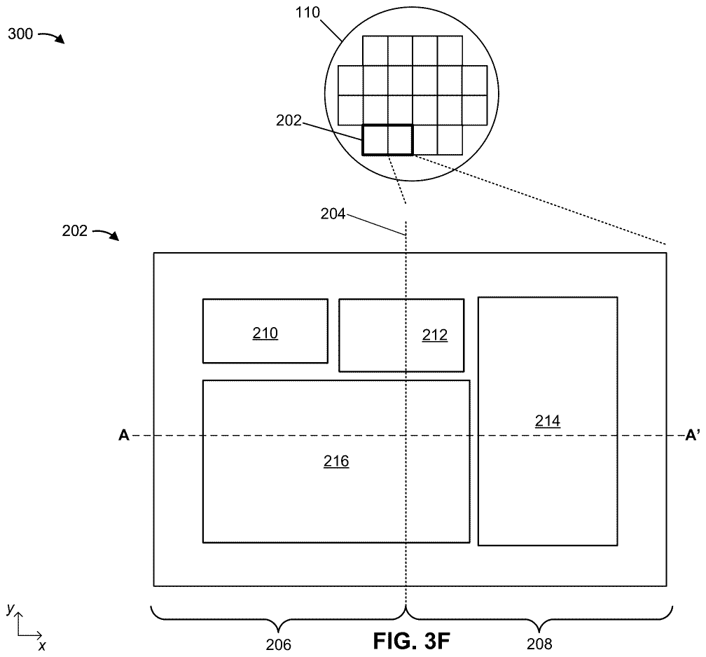

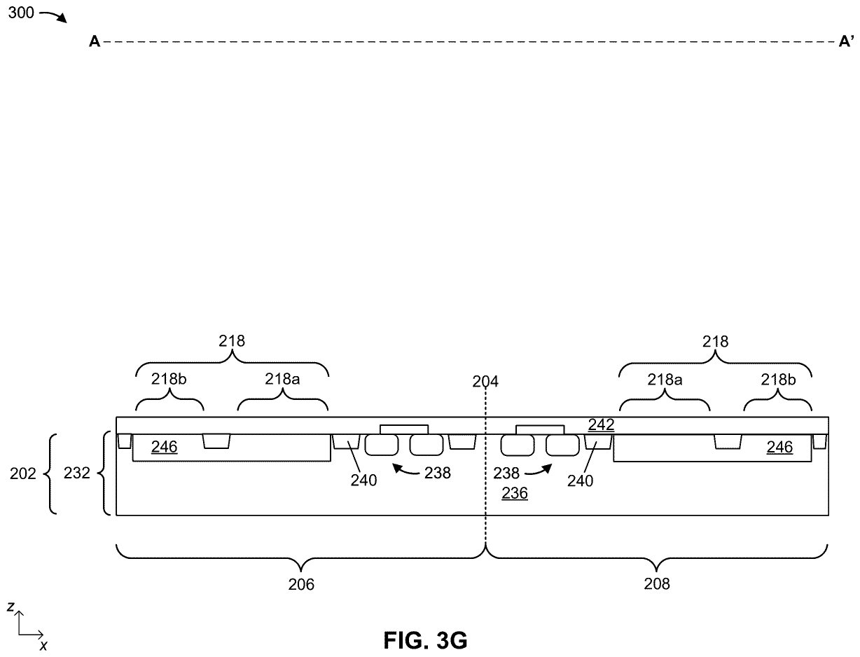

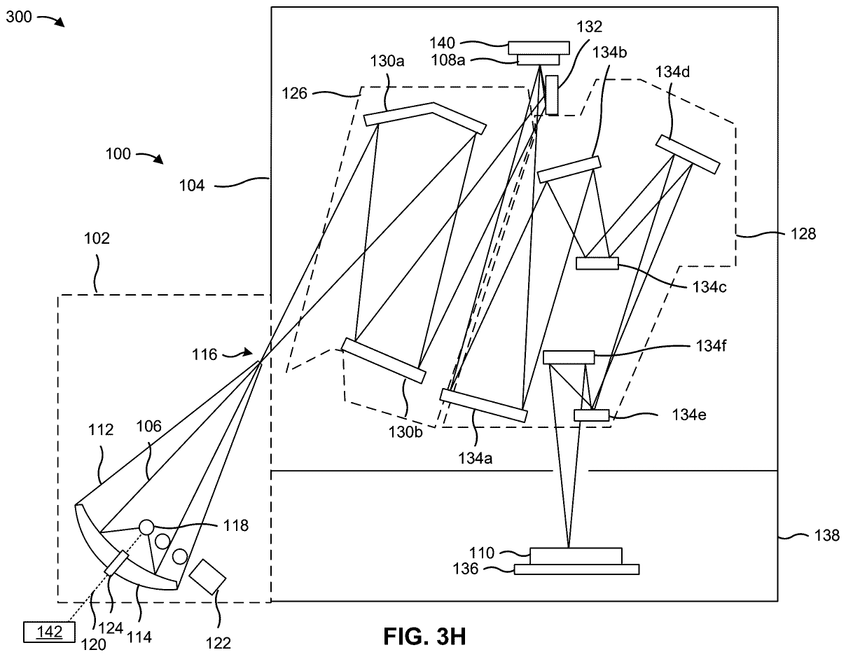

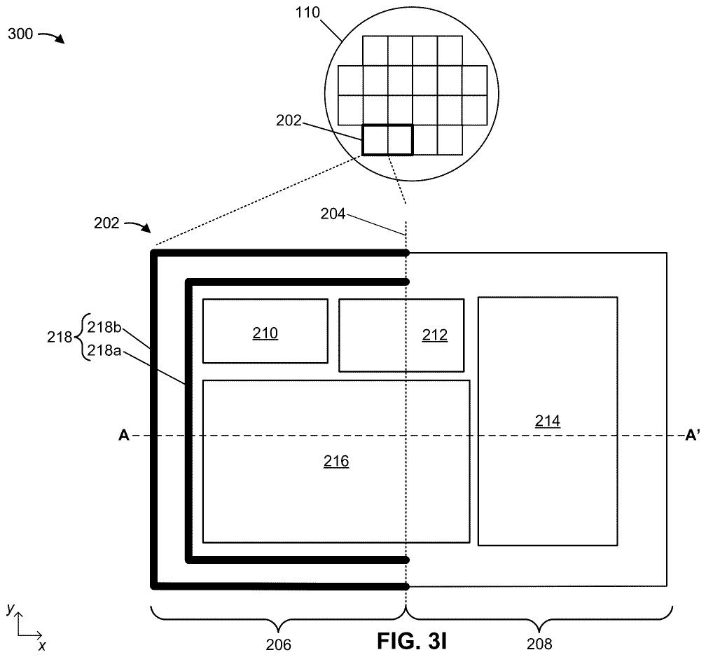

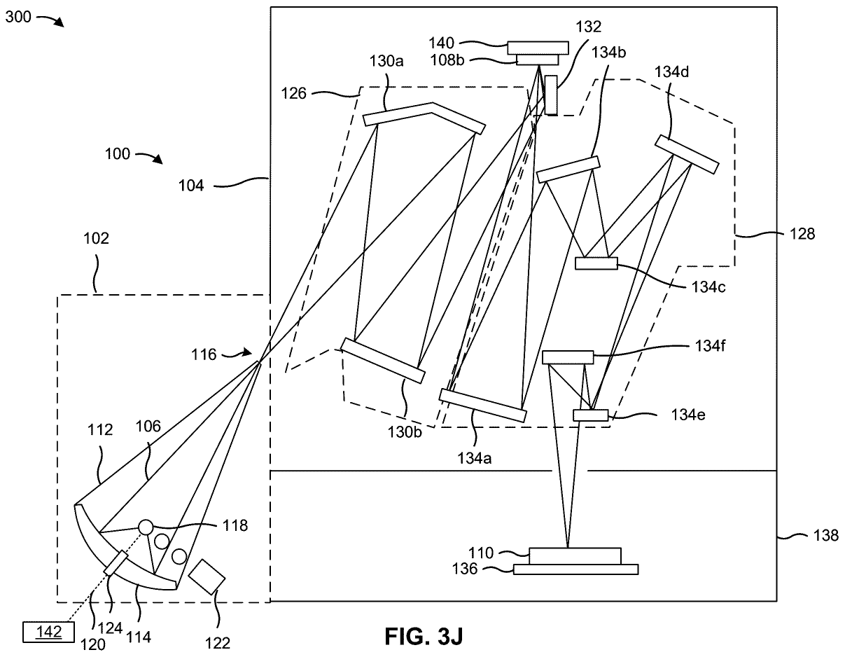

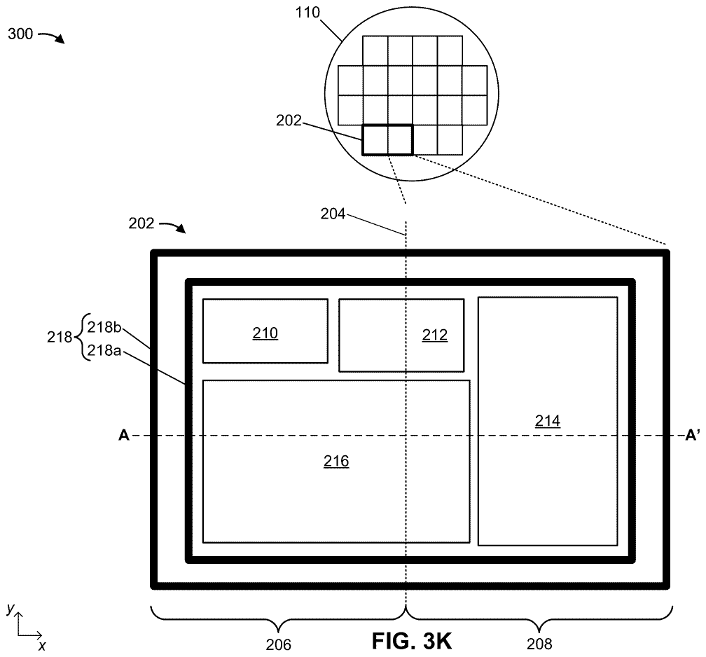

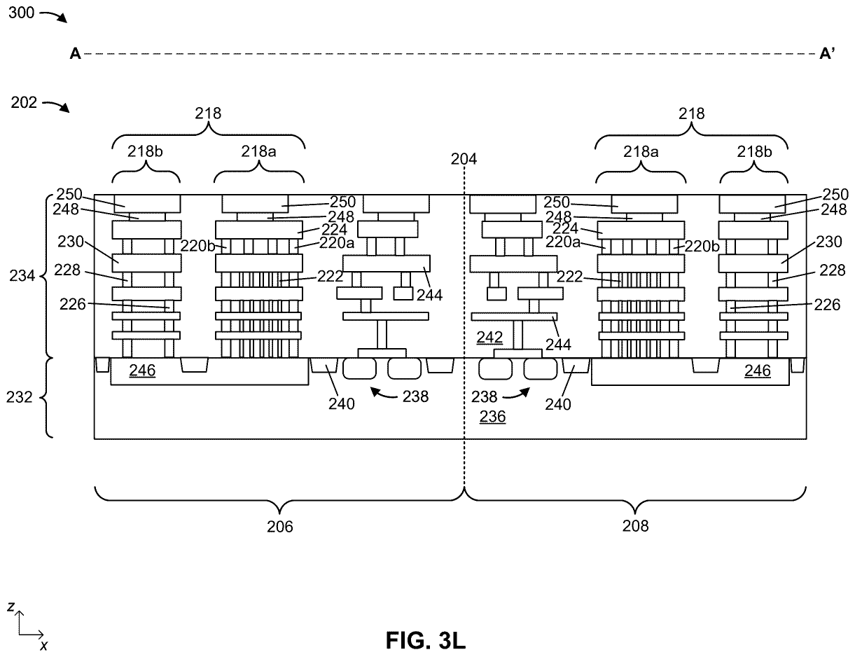

FIGS. 3A-3L are diagrams of an example implementation 300 of forming the semiconductor device 202 described herein. The example implementation 300 includes the use of a multiple-reticle exposure technique to form different layouts on the frontside of the semiconductor device 202 in different lateral regions 206 and 208 using different sets of reticles 108. In some implementations, one or more semiconductor processing tools, such as a deposition tool, an exposure tool (e.g., the lithography system 100), a developer tool, an etch tool, an ion implantation tool, a bonding tool, a planarization tool, and/or another type of semiconductor processing tool, may be used to perform one or more operations described in connection with FIGS. 3A-3L.

As shown in FIG. 3A, the semiconductor device 202 may be fabricated on a semiconductor wafer 110 along with a plurality of other semiconductor devices 202. The operations and/or techniques described in connection with FIGS. 3A-3L may be performed and/or used at the wafer level, meaning that the operations and/or techniques described in connection with FIGS. 3A-3L may be performed and/or used to manufacture a plurality of semiconductor devices 202 formed on the same semiconductor wafer 110.

As shown in FIG. 3B, the substrate layer 236 of the device layer 232 of the semiconductor device 202 may correspond to a portion of the semiconductor wafer 110 on which the semiconductor device 202 is fabricated.

As shown in FIGS. 3C-3G, a multiple-reticle exposure technique may be used to pattern and form different integrated circuit layouts in the lateral regions 206 and 208 on the frontside of the device layer 232 of the semiconductor device 202. For example, and as shown in FIGS. 3C and 3D, a set of reticles 108 a may be used to pattern the frontside of the device layer 232 in the lateral region 206 to form an arrangement of integrated circuit devices 238, isolation regions 240, and/or doped regions 246 in and/or on the frontside of the device layer 232 of the semiconductor device 202 in the lateral region 206. As shown in FIGS. 3E and 3F, a set of reticles 108b may be used to pattern the frontside of the device layer 232 in the lateral region 208 to form an arrangement of integrated circuit devices 238 and isolation regions 240, and/or doped regions 246 in and/or on the frontside of the device layer 232 of the semiconductor device 202 in the lateral region 208.

In some implementations, a deposition tool may be used to form the photoresist layer on the substrate layer 236 in the lateral regions 206 and 208. The use of the sets of reticles 108a and 108b may be sequential. For example, the semiconductor wafer 110 may be placed on the wafer stage 136 of the lithography system 100, a first reticle 108a may be loaded into the reticle stage 140 of the lithography system 100 as shown in FIG. 3C, and the first reticle 108a may be used to perform a first exposure operation to pattern the frontside of the substrate layer 236 in the lateral region 206 to form an arrangement of recesses for the isolation regions 240 in the lateral region 206. The first reticle 108a may be removed from the reticle stage 140 and replaced with a first reticle 108b as shown in FIG. 3E, and the first reticle 108b may be used to perform a second exposure operation (e.g., after the first exposure operation) to pattern the frontside of the substrate layer 236 in the lateral region 208 to form an arrangement of recesses for the isolation regions 240 in the lateral region 208. In some implementations, a developer tool may be used to develop and remove portions of the photoresist layer to expose the pattern in the lateral regions 206 and 208. An etch tool may be used to etch the substrate layer 236 based on the pattern to form the recesses in the lateral regions 206 and 208. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique) in the lateral regions 206 and 208. A deposition tool may be used to deposit dielectric material in the recesses in the lateral regions 206 and 208 using a chemical vapor deposition (CVD) technique, a physical vapor deposition (PVD) technique, an atomic layer deposition (ALD) technique, and/or another suitable deposition technique to form the isolation regions 240. A planarization tool may be used to planarize the isolation regions 240.

As another example, a layer of gate material may be deposited (e.g., by CVD, ALD, PVD, electroplating) over the frontside of the substrate layer 236. The semiconductor wafer 110 may be placed on the wafer stage 136 of the lithography system 100, a second reticle 108a may be loaded into the reticle stage 140 of the lithography system 100 as shown in FIG. 3C, and the second reticle 108a may be used to perform a third exposure operation (e.g., after the second exposure operation) to pattern the layer of gate material over the substrate layer 236 in the lateral region 206 to form an arrangement of gate structures of the integrated circuit devices 238 in the lateral region 206. The second reticle 108a may be removed from the reticle stage 140 and replaced with a second reticle 108b as shown in FIG. 3E, and the second reticle 108b may be used to perform a fourth exposure operation (e.g., after the third exposure operation) to pattern the layer of gate material over the substrate layer 236 in the lateral region 208 to form an arrangement of gate structures of the integrated circuit devices 238 in the lateral region 208.

As another example, a photoresist layer may be deposited over the frontside of the substrate layer 236. The semiconductor wafer 110 may be placed on the wafer stage 136 of the lithography system 100, a third reticle 108a may be loaded into the reticle stage 140 of the lithography system 100 as shown in FIG. 3C, and the third reticle 108a may be used to perform a fifth exposure operation (e.g., after the fourth exposure operation) to pattern the photoresist layer over the substrate layer 236 in the lateral region 206 to form an implant mask in the lateral region 206. The third reticle 108a may be removed from the reticle stage 140 and replaced with a third reticle 108b as shown in FIG. 3E, and the third reticle 108b may be used to perform a sixth exposure operation (e.g., after the fifth exposure operation) to pattern the photoresist layer over the substrate layer 236 in the lateral region 208 to form an implant mask in the lateral region 208. The implant masks in the lateral regions 206 and 208 may be used to respectively form source/drain regions of the integrated circuit devices 238 and/or doped regions 246 of the seal ring structures 218a and/or 218b in the frontside of the substrate layer 236 (e.g., by ion implantation).

As shown in FIGS. 3H-3L, a multiple-reticle exposure technique may be used to pattern and form different metallization layouts in the lateral regions 206 and 208 above the frontside of the device layer 232 of the semiconductor device 202. For example, and as shown in FIGS. 3H and 3I, a set of reticles 108a may be used to pattern the frontside of the semiconductor device 202 in the lateral region 206 to form a first arrangement of conductive structures 244, and to form a first arrangement of the seal rings structures 218a and 218b of the multiple seal ring structure 218, in the frontside interconnect layer 234 of the semiconductor device 202 in the lateral region 206. As shown in FIGS. 3J and 3K, a set of reticles 108b may be used to pattern the frontside of the semiconductor device 202 in the lateral region 208 to form a second arrangement of conductive structures 244, and to form a second arrangement of the seal rings structures 218a and 218b of the multiple seal ring structure 218, in the frontside interconnect layer 234 of the semiconductor device 202 in the lateral region 208.

The use of the sets of reticles 108a and 108b for forming the lateral regions 206 and 208 of the frontside interconnect layer 234 may be sequential. For example, a dielectric layer 242 of the frontside interconnect layer 234 may be deposited over the frontside of the device layer 232 of the semiconductor device 202. The semiconductor wafer 110 may be placed on the wafer stage 136 of the lithography system 100, a fourth reticle 108a may be loaded into the reticle stage 140 of the lithography system 100, and the fourth reticle 108a may be used to perform a seventh exposure operation (e.g., after the sixth exposure operation) to pattern the first dielectric layer 242 in the lateral region 206. The fourth reticle 108a may be removed from the reticle stage 140 and replaced with a fourth reticle 108b in the lithography system 100, and the fourth reticle 108b may be used to perform an eighth exposure operation (e.g., after the seventh exposure operation) to pattern the first dielectric layer 242 in the lateral region 208.

Patterning the first dielectric layer 242 in the lateral regions 206 and 208 may include patterning a photoresist layer or another type of patterning layer by performing the seventh and the eighth exposure operations, and then etching the first dielectric layer 242 (e.g., using an etch tool) based on the patterns formed in the lateral regions 206 and 208 in the photoresist layer to form recesses in the first dielectric layer 242. A layer of metal material may be deposited in the respective patterns of the lateral regions 206 and 208 to form different arrangements in a first layer of conductive structures 244 in the lateral regions 206 and 208. Moreover, the layer of metal material may be deposited in the respective patterns of the lateral regions 206 and 208 to form different arrangements in a first layer of interconnect structures in the seal ring structures 218a and 218b in the lateral regions 206 and 208. The different arrangements in the first interconnect structures may include different arrangements of inner line interconnect structures 220a, different arrangements of outer line interconnect structures 220b, different arrangements of pillar interconnect structures 222, different arrangements of inner pillar interconnect structures 226, and/or different arrangements of outer line interconnect structures 228. Subsequent reticles 108a and 108b may be used in a similar sequential manner for patterning additional layers of conductive structures 244, additional layers of inner line interconnect structures 220a, additional layers of outer line interconnect structures 220b, additional layers of pillar interconnect structures 222, additional layers of metallization structures 224, additional layers of inner pillar interconnect structures 226, additional layers of outer line interconnect structures 228, additional layers of metallization structures 230, additional layers of top vias 248, and/or additional layers of top pads 250, among other examples.

As indicated above, FIGS. 3A-3L are provided as an example. Other examples may differ from what is described with regard to FIGS. 3A-3L.

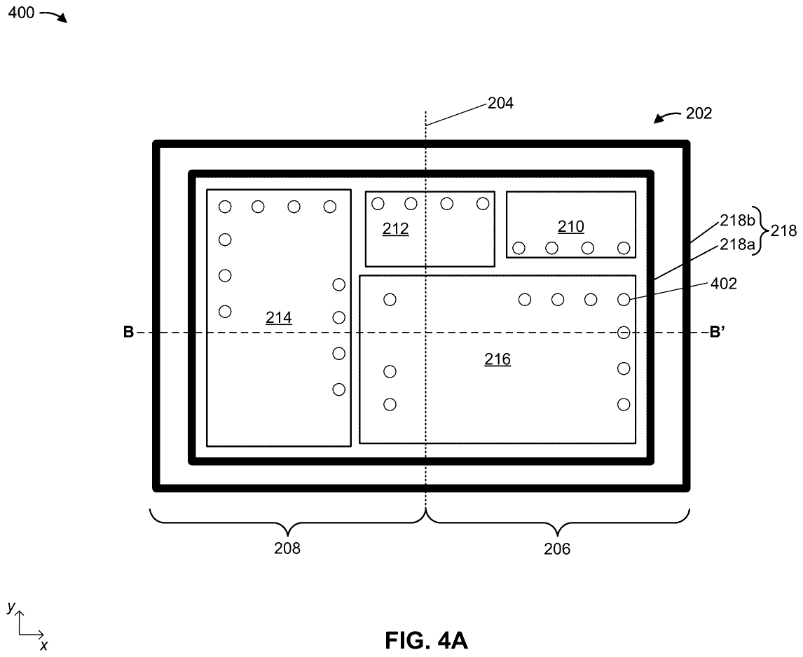

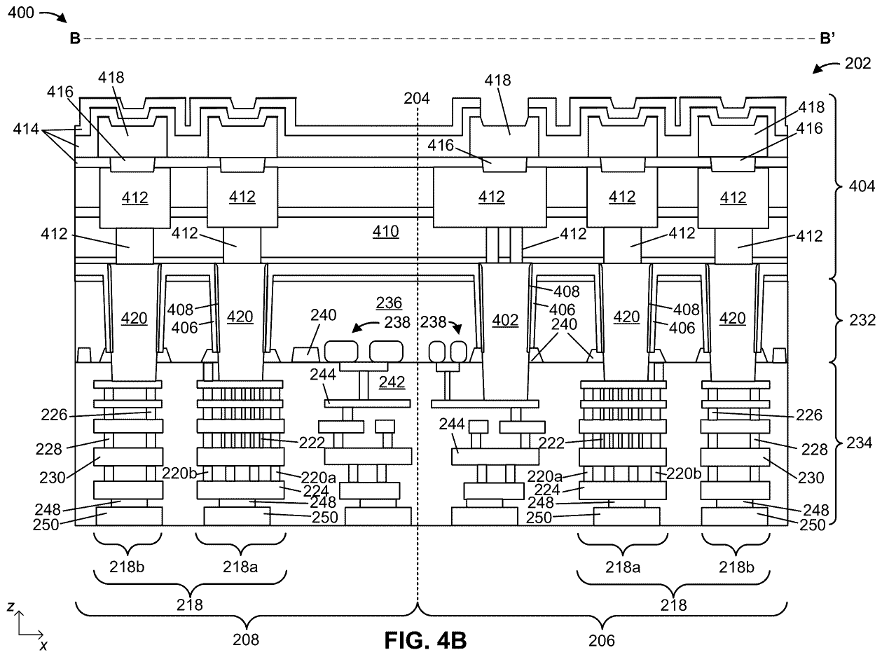

FIGS. 4A and 4B are diagrams of an example implementation 400 of the semiconductor device 202 described herein. FIG. 4A illustrates a top view of the semiconductor device 202, and FIG. 4B illustrates a cross-section view of the semiconductor device 202 along the line B-B′ in FIG. 4A. As shown in FIGS. 4A and 4B, the example implementation 400 of the semiconductor device 202 is similar to the example implementation 200 of the semiconductor device 202 illustrated in FIGS. 2A and 2B. However, the example implementation 400 of the semiconductor device 202 further includes one or more through-substrate interconnect structures 402.

As shown in FIG. 4A, the lateral regions 206 and 208 may include different arrangements of through-substrate interconnect structures 402 that were formed using different sets of reticles 108 and one or more through-substrate interconnect structures 402 may be included in one or more of the functional regions 210-216 of the semiconductor device 202.

As shown in FIG. 4B, a through-substrate interconnect structure 402 may extend through the substrate layer 236 of the semiconductor device 202 and may electrically connect the frontside interconnect layer 234 of the semiconductor device 202. A through-substrate interconnect structure 402 may include a through-silicon via (TSV), a metal pillar, a metal column, and/or other another type of vertically (e.g., in the z-direction) elongated conductive structure. A through-substrate interconnect structure 402 may include one or more electrically conductive materials, such as copper (Cu), gold (Au), silver (Ag), nickel (Ni), tin (Sn), ruthenium (Ru), cobalt (Co), tungsten (W), titanium (Ti), aluminum copper (AlCu), one or more metals, one or more conductive ceramics, alloys thereof, and/or another type of electrically conductive material.

As further shown in FIG. 4B, the example implementation 400 of the semiconductor device 202 may further include a backside interconnect layer 404 on a backside of the device layer 232 of the semiconductor device 202. The frontside interconnect layer 234 may be located on a first side (e.g., the frontside) of the device layer 232, and a backside interconnect layer 404 on a second side (e.g., a backside) of the device layer 232 vertically opposite the first side. Thus, the frontside interconnect layer 234, the device layer 232, and the backside interconnect layer 404 may be vertically arranged in the z-direction in the semiconductor device 202.

A through-substrate interconnect structure 402 may extend through the substrate layer 236 and into the frontside interconnect layer 234, as well as into the backside interconnect layer 404. This enables signals and/or power to be provided between the frontside and the backside of the semiconductor device 202 through the through-substrate interconnect structure(s) 402.

The material(s) of the through-substrate interconnect structure 402 may be susceptible to diffusion into the surrounding substrate layer 236. Accordingly, the isolation region 240 and one or more liners 406, 408 may be included between a through-substrate interconnect structure 402 and the substrate layer 236 to provide a diffusion barrier and/or to promote adhesion between the through-substrate interconnect structure 402 and the substrate layer 236, among other examples. Moreover, in some implementations, an additional barrier layer is deposited on the one or more liners 406, 408 to further suppress metal diffusion from the through-substrate interconnect structure 402 more effectively. The one or more liners 406, 408 may include a high-k dielectric liner, a low-k dielectric liner, and/or another type of liner.

A high-k dielectric liner may include one or more high-k dielectric materials, such as silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. A low-k dielectric liner may include one or more low-k dielectric materials, such as a silicon oxide (SiOₓ), an undoped silicate glass (USG), a boron-containing silicate glass (BSG), and/or a fluorine-containing silicate glass (FSG), among other examples. The barrier layer, if included, may include diffusion blocking materials such as tantalum (Ta) and/or tantalum nitride (TaN), among other examples.

As further shown in FIG. 4B, the backside interconnect layer 404 may include one or more dielectric layers 410 that may be arranged in a direction (e.g., the z-direction) that is approximately perpendicular to the substrate layer 236. The dielectric layer(s) 410 may include backend dielectric layers (e.g., ILD layers, IMD layers) and ESLs that are arranged in an alternating manner in the backside interconnect layer 404. The dielectric layer(s) 410 may each include an oxide (e.g., a silicon oxide (SiOx) and/or another oxide material), an undoped silicate glass (USG), a boron-containing silicate glass (BSG), a fluorine-containing silicate glass (FSG), an ELK dielectric material having a dielectric constant that is less than approximately 2.5, a silicon nitride (SiₓN_{y}), silicon carbide (SiC), silicon oxynitride (SiON), and/or another suitable dielectric material.

The backside interconnect layer 404 may further include one or more layers of conductive structures 412 (e.g., electrically conductive structures) in the dielectric layer(s) 410. The conductive structures 412 may be electrically coupled and/or physically coupled to one or more through-substrate interconnect structures 402 that extend through the device layer 232 between the frontside interconnect layer 234 and the backside interconnect layer 404.

The lateral regions 206 and 208 may include different arrangements of conductive structures 412 that were formed using different sets of reticles 108. The conductive structures 412 in the lateral region 206 may be arranged to distribute signals and/or power for the integrated circuits in the functional regions 210, 212, and 216. Similarly, the conductive structures 412 in the lateral region 208 may be arranged to distribute signals and/or power for the integrated circuits in the functional regions 212, 214, and 216. In some implementations, the conductive structures 412 in the lateral regions 206 and/or 208 may be arranged to distribute signals and/or power between two or more of the functional regions 210-216.

In this way, multiple-reticle exposure techniques may be used for frontside processing and backside processing when manufacturing the semiconductor device 202. Frontside processing of the semiconductor device 202 may include using different sets of reticles 108 to form different circuit layouts in and/or above the frontside of the device layer 232 (including in the frontside interconnect layer 234) in the lateral regions 206 and 208. Backside processing of the semiconductor device 202 may include using different sets of reticles 108 to form different circuit layouts in and/or above the backside of the device layer 232 (including in the backside interconnect layer 404 and for the through-substrate interconnect structures 402) in the lateral regions 206 and 208. Thus, the lateral region 206 may include a frontside region (or frontside portion) and a backside region (or backside portion), and the lateral region 208 may include a frontside region (or frontside portion) and a backside region (or backside portion).

As further shown in FIG. 4B, one or more passivation layers 414 may be included over the backside interconnect layer 404 above the dielectric layer(s) 410. The passivation layer(s) 414 may include silicon nitride (SiₓN_{y}), tantalum nitride (TaN), silicon oxide (SiOₓ), and/or another suitable passivation material. The passivation layers 414 may be included to passivate the backside of the semiconductor device 202 and/or for patterning the backside of the semiconductor device 202 for formation of connection pads 416 and connection structures 418 over the backside of the semiconductor device 202. The one or more conductive structures 412 in the backside interconnect layer 404 may further be coupled to a connection pad 416 and a connection structure 418. The connection pads 416 may include copper (Cu) pads, aluminum (Al) pads, aluminum copper (AlCu) pads, and/or another type of metal pads that provide a surface on which the connection structures 418 may be formed. The connection structures 418 enable the semiconductor device 202 to be attached to a substrate (e.g., an interposer, a printed circuit board (PCB)), another semiconductor package, and/or to be attached to another structure. The connection structures 418 may include solder pads, solder balls, micro-bumps, and/or another type of connection structures.

As further shown in FIG. 4B, the seal ring structure 218a and/or the seal ring structure 218b may further include a through-substrate isolation structure 420 that extends through the substrate layer 236 of the semiconductor device 202. The through-substrate isolation structure 420 of the seal ring structure 218a may be further coupled to a metallization structure 224 of the seal ring structure 218a in the frontside interconnect layer 234, and may be coupled to one or more conductive structures 412 in the backside interconnect layer 404. The one or more conductive structures 412 in the backside interconnect layer 404 may further be coupled to a connection pad 416 and a connection structure 418, thereby extending the seal ring structure 218a through the backside interconnect layer 404.

Similarly, the through-substrate isolation structure 420 of the seal ring structure 218b may be further coupled to a metallization structure 230 of the seal ring structure 218b in the frontside interconnect layer 234, and may be coupled to one or more conductive structures 412 in the backside interconnect layer 404. The one or more conductive structures 412 in the backside interconnect layer 404 may further be coupled to a connection pad 416 and a connection structure 418, thereby extending the seal ring structure 218b through the backside interconnect layer 404.

In some implementations, the seal ring structure 218a includes a plurality of through-substrate isolation structures 420 that are arranged around the perimeter of the semiconductor device 202 in a top view of the semiconductor device 202. A subset of the through-substrate isolation structures 420 may be located in the lateral region 206 and patterned using a first set of reticles 108, and another subset of the through-substrate isolation structures 420 may be located in the lateral region 208 and patterned using a second set of reticles 108. Similarly, the seal ring structure 218b may include a plurality of through-substrate isolation structures 420 that are arranged around the perimeter of the semiconductor device 202 in a top view of the semiconductor device 202. A subset of the through-substrate isolation structures 420 may be located in the lateral region 206 and patterned using a first set of reticles 108, and another subset of the through-substrate isolation structures 420 may be located in the lateral region 208 and patterned using a second set of reticles 108.

The through-substrate isolation structures 420 may block or inhibit electrical effects (e.g., RF interference, electromagnetic interference (EMI), current leakage) from propagating into and/or out of the portion of the substrate layer 236 in the device layer 232. In this way, the through-substrate isolation structures 420 protect the integrated circuit devices 238 in the device layer 232 from being affected by external electrical effects and/or electrical effects from the semiconductor device 202. Moreover, the through-substrate isolation structures 420 may block or inhibit ingress of humidity, vibration, and/or other contaminants from propagating through the substrate layer 236 and into the device layer 232, thereby protecting the integrated circuit devices 238 in the device layer 232 from being exposed to such humidity, vibration, and/or other contaminants.

A through-substrate isolation structure 420 may include a TSV, a metal pillar, a metal column, a through-substrate trench, and/or another type of electrically conductive structure that extends through the substrate layer 236. FIG. 4B illustrates an example implementation in which the through-substrate isolation structures 420 have tapered sidewalls and are formed by a TSV process. In some implementations, a through-substrate isolation structure 420 may have approximately vertical sidewalls and be formed by a backside passivation (BPASS) process. In FIG. 4B, the through-substrate isolation structures 420 may extend through isolation regions 240 that are included in the substrate layer 236. Alternatively, the isolation regions 240 may be omitted, and the through-substrate isolation structures 420 may extend fully through the substrate layer 236.

The through-substrate isolation structures 420 may include one or more electrically conductive materials, such as copper (Cu), gold (Au), silver (Ag), nickel (Ni), tin (Sn), ruthenium (Ru), cobalt (Co), tungsten (W), titanium (Ti), aluminum copper (AlCu), one or more metals, one or more conductive ceramics, alloys thereof, and/or another type of electrically conductive material. In some implementations, one or more liners 406, 408 may be included on the sidewalls of the through-substrate isolation structures 420.

As indicated above, FIGS. 4A and 4B are provided as an example. Other examples may differ from what is described with regard to FIGS. 4A and 4B.

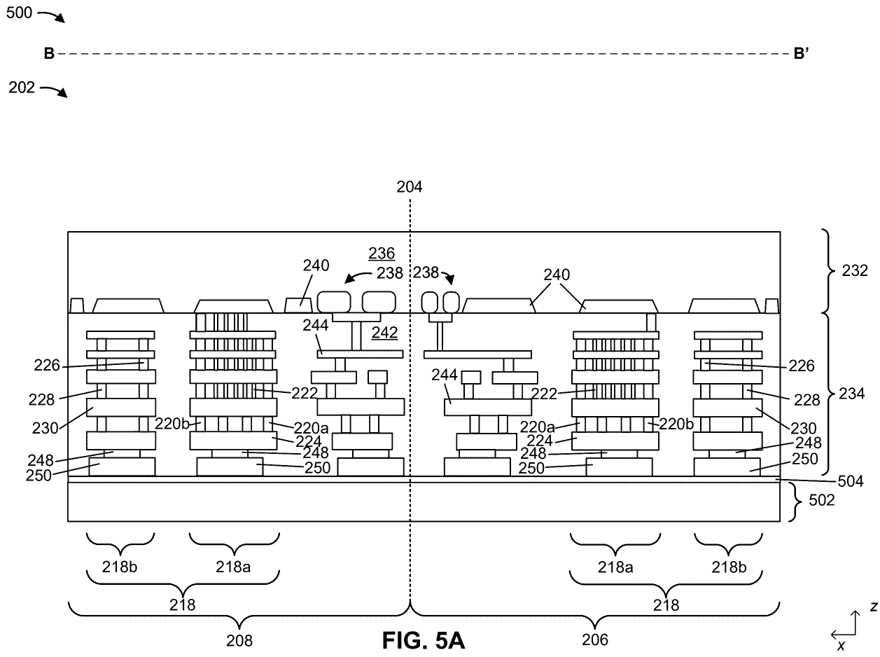

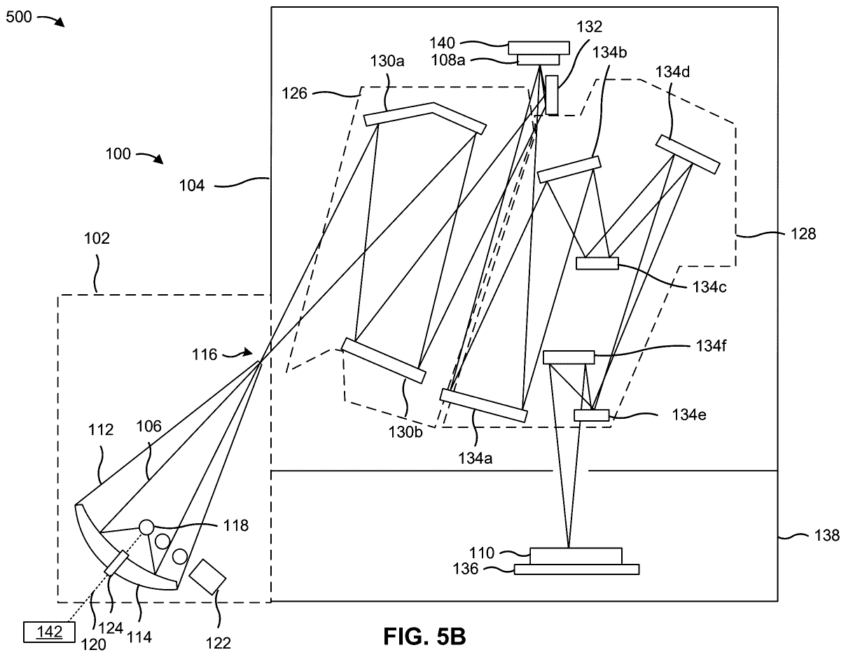

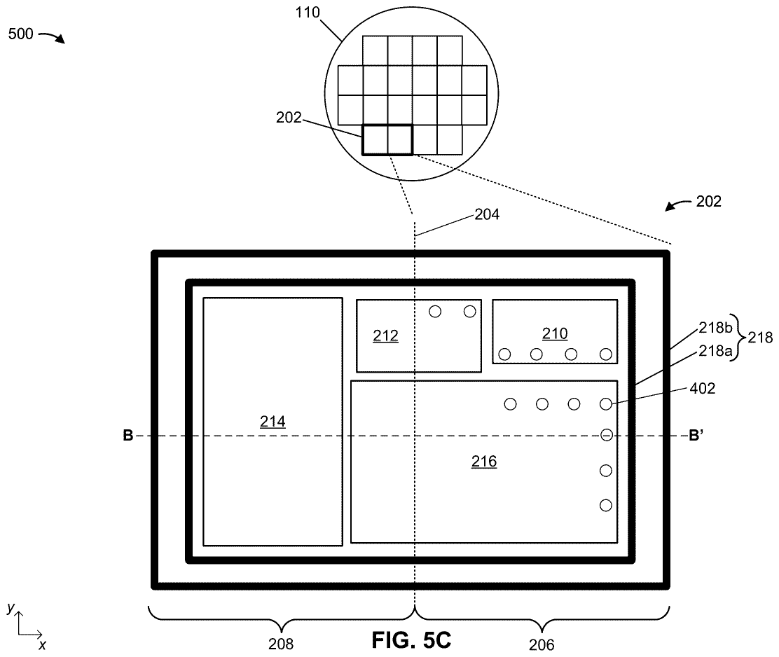

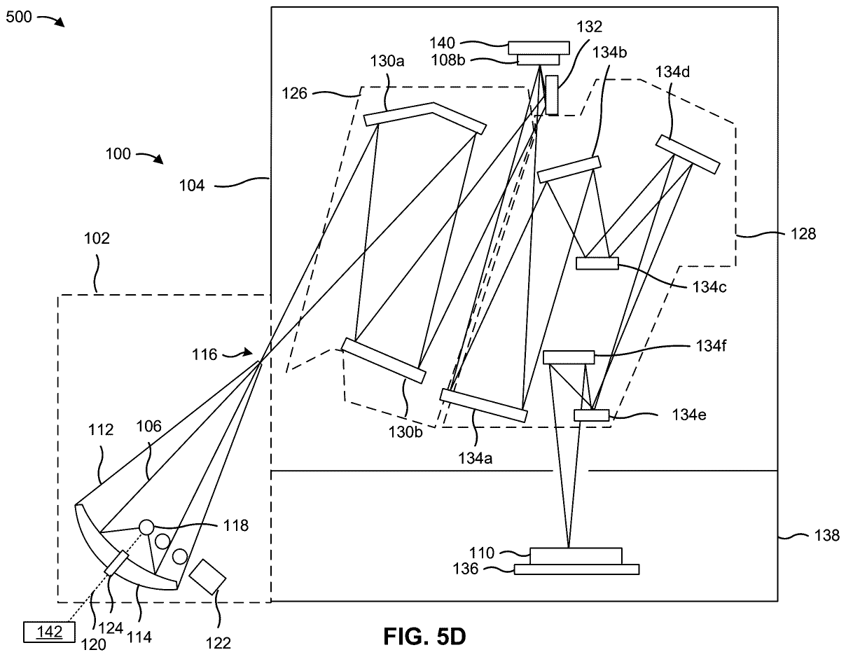

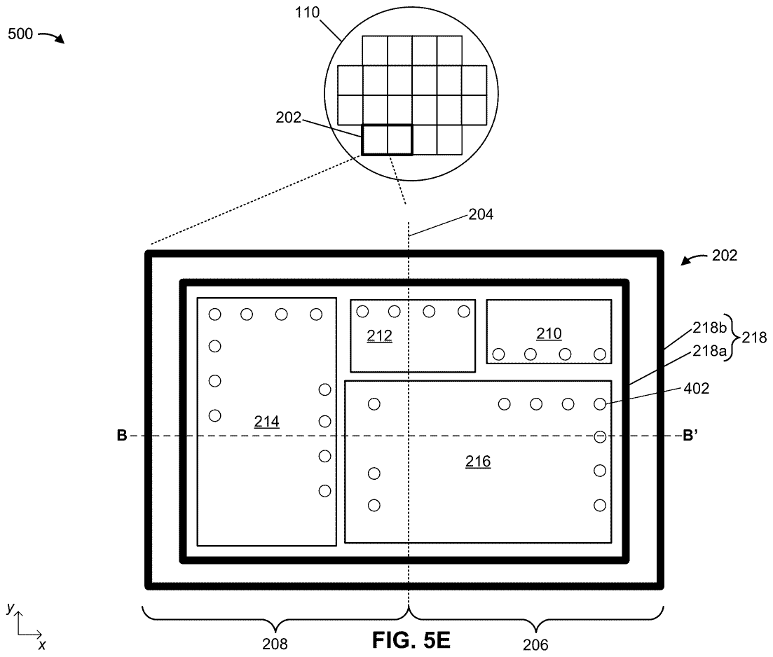

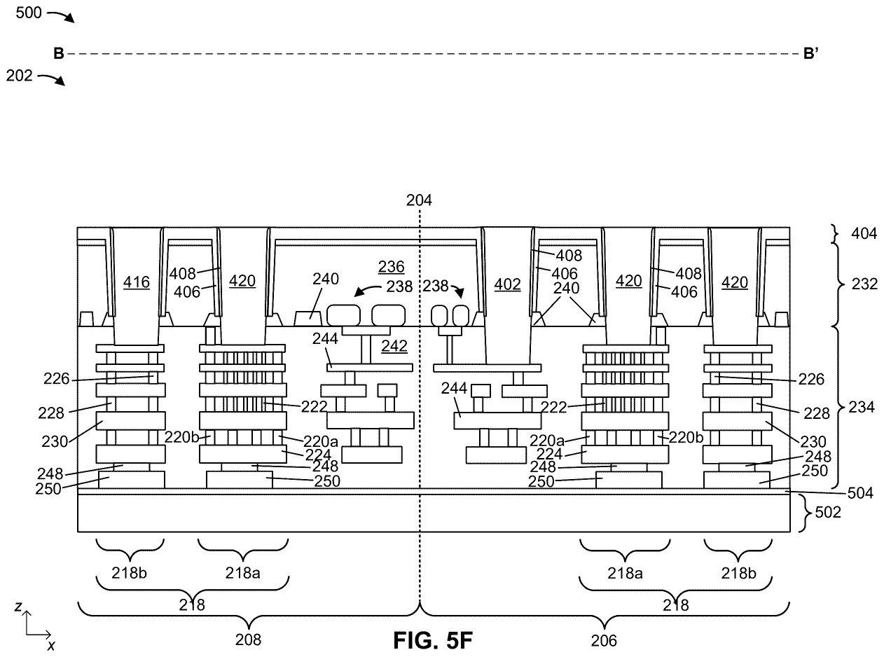

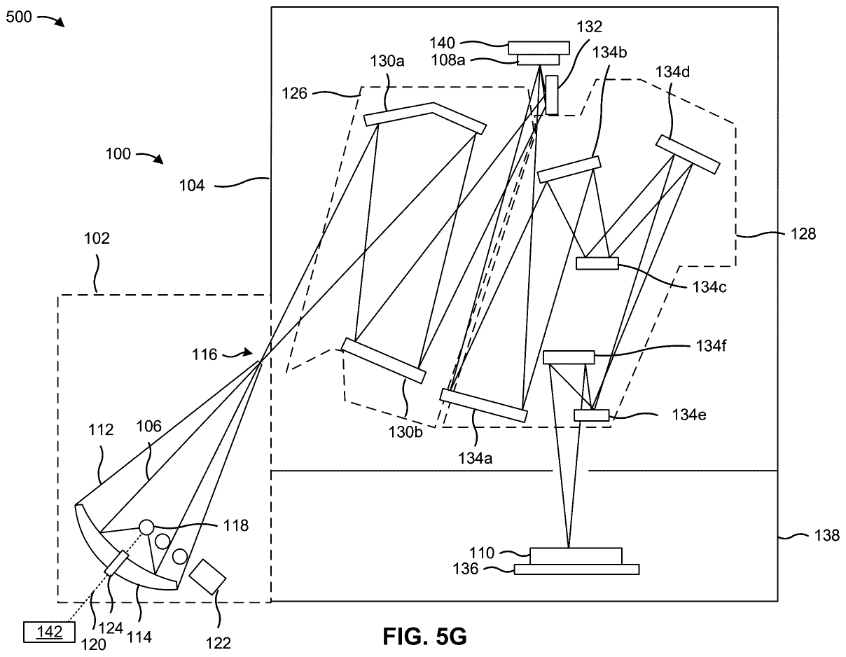

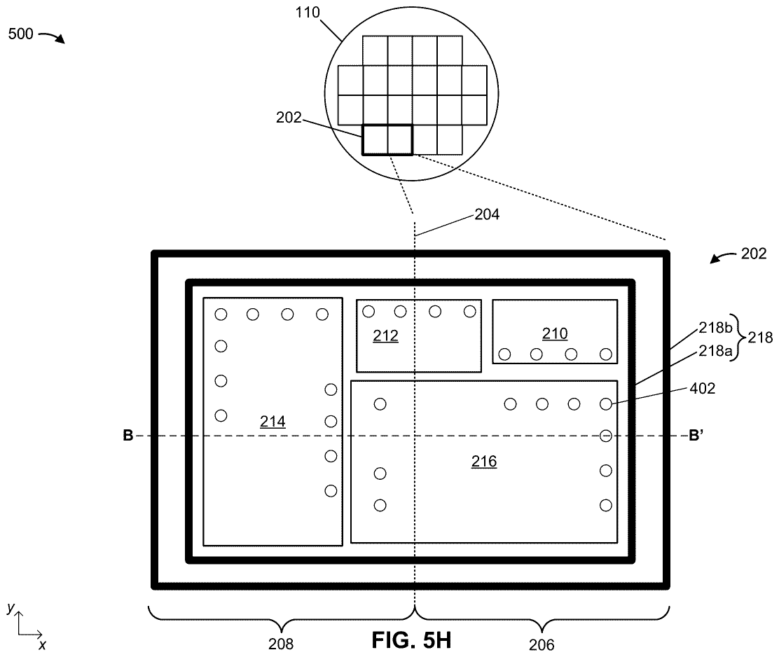

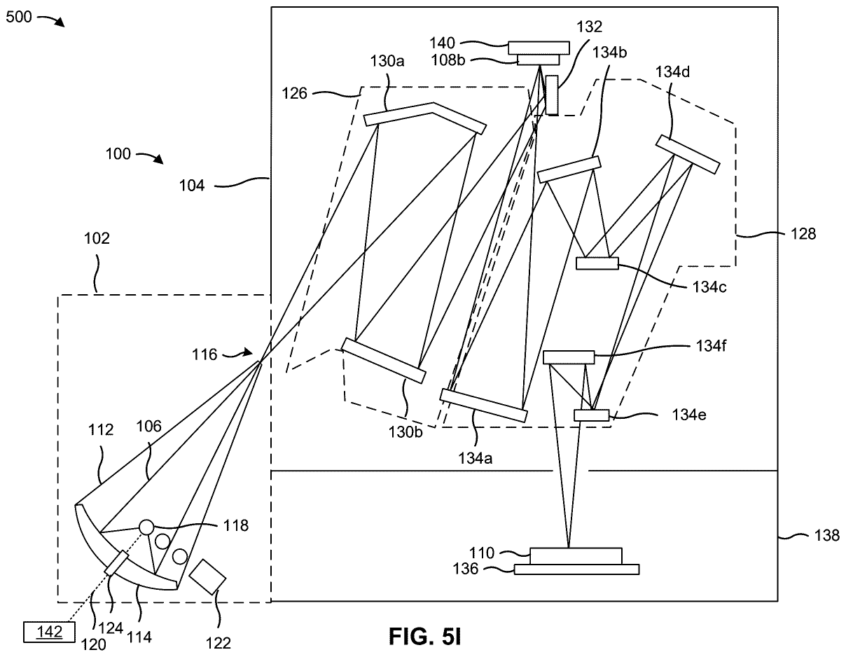

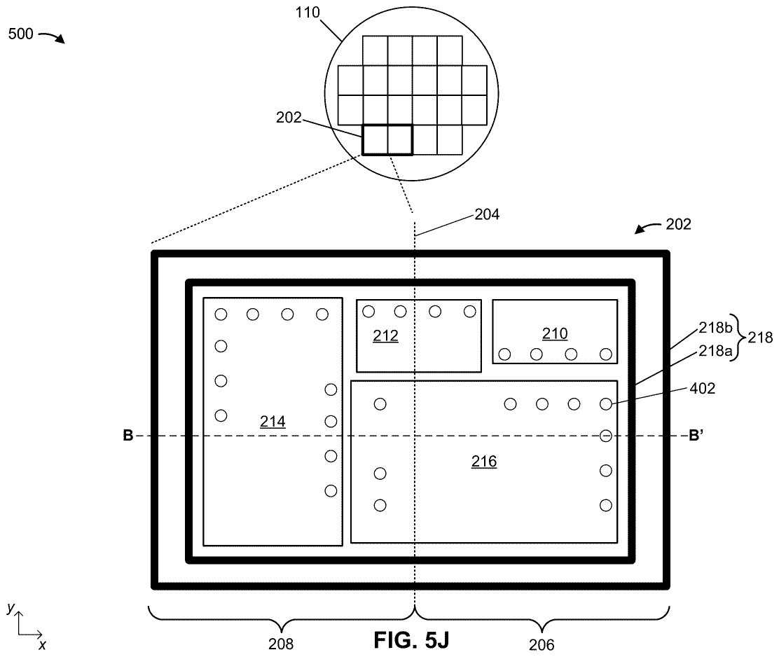

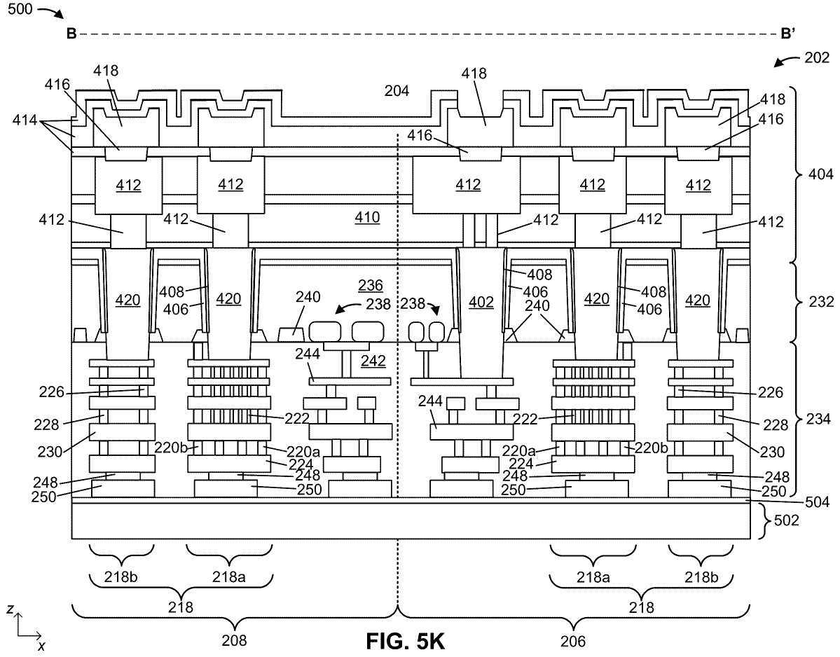

FIGS. 5A-5K are diagrams of an example implementation 500 of forming the stacked semiconductor device described herein. The example implementation 500 includes the use of similar multiple-reticle exposure techniques described in connection with FIGS. 3A-3L to form different layouts on the frontside of the semiconductor device 202, as well as on the backside of the semiconductor device 202, using different sets of reticles 108. In some implementations, one or more semiconductor processing tools, such as a deposition tool, an exposure tool (e.g., the lithography system 100), a developer tool, an etch tool, an ion implantation tool, a bonding tool, a planarization tool, and/or another type of semiconductor processing tool, may be used to perform one or more operations described in connection with FIGS. 5A-5K.

As shown in FIG. 5A, the semiconductor device 202 may be flipped (e.g., after the operations described in connection with FIGS. 3A-3L) to enable backside processing to be performed on the backside of the device layer 232 of the semiconductor device 202. The semiconductor wafer 110 on which the semiconductor device 202 is fabricated may be bonded to a carrier substrate 502 to protect the frontside of the semiconductor devices 202 formed on the semiconductor wafer 110. The semiconductor wafer 110 may be bonded to the carrier substrate 502 using one or more bonding dielectric layers 504 to form a face-to-face dielectric-to-dielectric bond between the bonding dielectric layer 504 and the dielectric region 242.

As shown in FIGS. 5B-5F, a multiple-reticle exposure technique may be used to pattern and form different arrangements of through-substrate interconnect structures 402 and/or different arrangements of through-substrate isolation structures 420 for the seal ring structures 218a and/or 218b in the lateral regions 206 and 208 from the backside of the device layer 232 of the semiconductor device 202. For example, and as shown in FIGS. 5B and 5C, a set of reticles 108a may be used to pattern the backside of the device layer 232 in the lateral region 206 to form an arrangement of through-substrate interconnect structures 402 and an arrangement of through-substrate isolation structures 420 for the sections of the seal ring structures 218a and 218b in the lateral region 206 of the semiconductor device 202. As shown in FIGS. 5D and 5E, a set of reticles 108b may be used to pattern the backside of the device layer 232 in the lateral region 208 to form an arrangement of through-substrate interconnect structures 402 and an arrangement of through-substrate isolation structures 420 for the sections of the seal ring structures 218a and 218b in the lateral region 208.

The use of the sets of reticles 108a and 108b for forming the arrangements of through-substrate interconnect structures 402 and the arrangements of through-substrate isolation structures 420 in the lateral regions 206 and 208 from the backside of the device layer 232 may be sequential. For example, one or more patterning layers may be deposited over the backside of the device layer 232 of the semiconductor device 202. The semiconductor wafer 110 may be placed on the wafer stage 136 of the lithography system 100, a first reticle 108a may be loaded into the reticle stage 140 of the lithography system 100, and the first reticle 108a may be used to perform a first exposure operation to form a pattern in one or more patterning layers in the lateral region 206. The first reticle 108a may be removed from the reticle stage 140 and replaced with a first reticle 108b in the lithography system 100, and the first reticle 108b may be used to perform a second exposure operation (e.g., after the first exposure operation) to form a pattern in the one or more patterning layers in the lateral region 208. An etch tool may be used to etch the substrate layer 236 in the lateral regions 206 and 208 based on the respective patterns formed in the patterning layers in the lateral regions 206 and 208 to form recesses that extend through the substrate layer 236 and into the frontside interconnect layer 234.

The liners 406, 408 may be formed on sidewalls of the recesses, and the recesses may be filled in with electrically conductive material (e.g., by CVD, PVD, ALD, and/or electroplating using a deposition tool) to form the through-substrate interconnect structures 402 and the through-substrate isolation structures 420 in the recesses.

As shown in FIGS. 5G-5K, a multiple-reticle exposure technique may be used to pattern and form different metallization layouts in the lateral regions 206 and 208 above the backside of the device layer 232 of the semiconductor device 202. For example, and as shown in FIGS. 5G and 5H, a set of reticles 108a may be used to pattern the backside interconnect layer 404 in the lateral region 206 to form an arrangement of conductive structures 412, connection pads 416, and connection structures 418 in the backside interconnect layer 404 of the semiconductor device 202 in the lateral region 206. As shown in FIGS. 5I and 5J, a set of reticles 108b may be used to pattern the backside interconnect layer 404 in the lateral region 208 to form an arrangement of conductive structures 412, connection pads 416, and connection structures 418 in the backside interconnect layer 404 of the semiconductor device 202 in the lateral region 208.

The use of the sets of reticles 108a and 108b for forming the lateral regions 206 and 208 of the backside interconnect layer 404 may be sequential. For example, a dielectric layer 410 of the backside interconnect layer 404 may be deposited over the backside of the device layer 232 of the semiconductor device 202. The semiconductor wafer 110 may be placed on the wafer stage 136 of the lithography system 100, a second reticle 108a may be loaded into the reticle stage 140 of the lithography system 100, and the second reticle 108a may be used to perform a third exposure operation (e.g., after the second exposure operation) to pattern the first dielectric layer 410 in the lateral region 206. The second reticle 108a may be removed from the reticle stage 140 and replaced with a second reticle 108b in the lithography system 100, and the second reticle 108b may be used to perform a fourth exposure operation (e.g., after the third exposure operation) to pattern the first dielectric layer 410 in the lateral region 208.

Patterning the first dielectric layer 410 in the lateral regions 206 and 208 may include patterning a photoresist layer or another type of patterning layer by performing the third and the fourth exposure operations, and then etching the first dielectric layer 410 (e.g., using an etch tool) based on the patterns formed in the lateral regions 206 and 208 in the photoresist layer to form recesses in the first dielectric layer 410. A layer of metal material may be deposited in the recesses in the lateral regions 206 and 208 to form different arrangements in a first layer of conductive structures 412 in the lateral regions 206 and 208. Subsequent reticles 108a and 108b may be used in a similar sequential manner for patterning additional layers of conductive structures 412 in the backside interconnect layer 404.

As indicated above, FIGS. 5A-5K are provided as an example. Other examples may differ from what is described with regard to FIGS. 5A-5K.

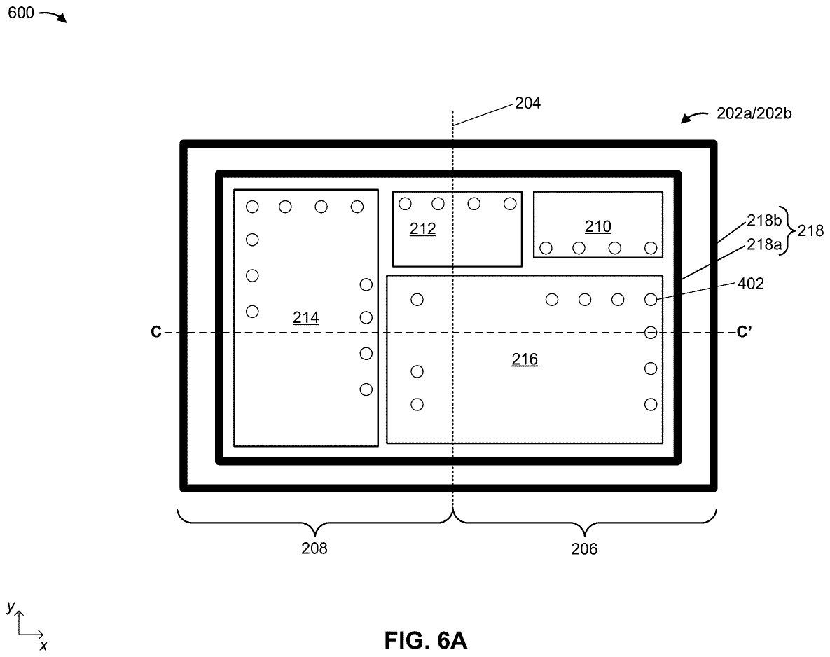

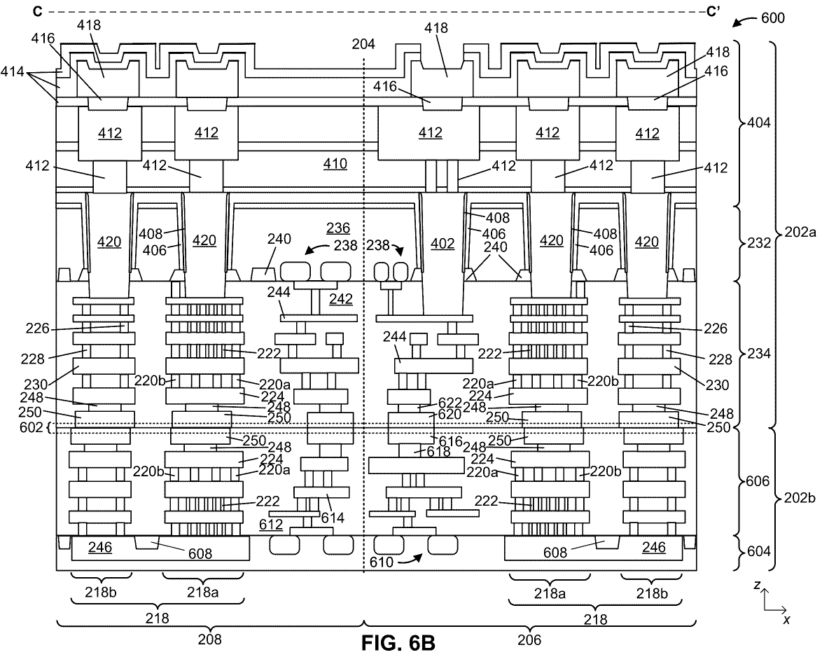

FIGS. 6A and 6B are diagrams of an example stacked semiconductor device 600 described herein. FIG. 6A illustrates a top view of the stacked semiconductor device 600, and FIG. 6B illustrates a cross-section view of the stacked semiconductor device 600 along the line C-C′ in FIG. 6A.

As shown in FIG. 6A, the stacked semiconductor device 600 includes a plurality of semiconductor devices 202, such as a semiconductor device 202a and a semiconductor device 202b. The semiconductor devices 202a and 202b may be stacked and vertically arranged in the z-direction. The stacked semiconductor device 600 may include the lateral regions 206 and 208 that may include respective lateral portions of the semiconductor device 202a and respective lateral portions of the semiconductor device 202b. Thus, the lateral region 206 of the stacked semiconductor device 600 may include a first portion of the semiconductor device 202a that is stacked together with a first portion of the semiconductor device 202b, and the lateral region 208 of the stacked semiconductor device 600 may include a second portion of the semiconductor device 202a that is stacked together with a second portion of the semiconductor device 202b. The functional regions 210-216 of the stacked semiconductor device 600 may be distributed across the semiconductor devices 202a and 202b.

As shown in FIG. 6B, the semiconductor devices 202a and 202b may be directly bonded together at a bonding interface 602. The semiconductor device 202a may include a similar arrangement of layers and/or structures as the semiconductor device 202 illustrated in FIG. 4B. In particular, the through-substrate isolation structures 420 protect the integrated circuit devices 238 in the device layer 232 from being affected by external electrical effects and/or electrical effects from the semiconductor device 202b, and/or protect the integrated circuit devices 610 in the device layer 604 from being affected by external electrical effects and/or electrical effects from the semiconductor device 202a. The semiconductor device 202b may include a device layer 604 and an interconnect layer 606 above the device layer 604. The semiconductor devices 202a and 202b may be bonded together such that the frontside interconnect layer 234 and the interconnect layer 606 are facing each other. Alternatively, the semiconductor devices 202a and 202b may be bonded together such that the backside interconnect layer 404 and the interconnect layer 606 are facing each other.

The device layer 604 may include a substrate layer (e.g., similar to the substrate layer 236), and isolation regions 608 (e.g., similar to isolation regions 240) and integrated circuit devices 610 (e.g., similar to the integrated circuit devices 238) in and/or on the substrate layer. The interconnect layer 606 may include one or more dielectric layers 612 (e.g., similar to the dielectric layer(s) 242) and one or more layers of conductive structures 614 (e.g., similar to the conductive structures 244) in the dielectric layer(s) 612.

The multiple seal ring structure 218 may extend through the interconnect layer 606. The portion of the seal ring structure 218a in the semiconductor device 202b may include a similar arrangement of layers of inner line interconnect structures 220a, outer line interconnect structures 220b, pillar interconnect structures 222, metallization structures 224, doped regions 246, top vias 248, and top pads 250 as the portion of the seal ring structure 218a in the semiconductor device 202a. The portion of the seal ring structure 218b in the semiconductor device 202b may include a similar arrangement of layers of inner pillar interconnect structures 226, outer line interconnect structures 228, metallization structures 230, doped regions 246, top vias 248, and top pads 250 as the portion of the seal ring structure 218b in the semiconductor device 202a.

The interconnect layer 606 may further include a plurality of bonding pads 616. The bonding pads 616 may be electrically coupled to the conductive structures 614 in the interconnect layer 606 by bonding vias 618 and/or other types of conductive structures. The bonding pads 616 and bonding vias 618 may each include tungsten (W), cobalt (Co), ruthenium (Ru), titanium (Ti), aluminum (Al), copper (Cu), gold (Au), and/or a combination thereof, among other examples of electrically conductive metals. In some implementations, one or more bonding pads 616 are each coupled to a single bonding via 618. In some implementations, one or more bonding pads 616 are each coupled to two or more bonding vias 618.

At the bonding interface 602, the bonding pads 616 of the semiconductor device 202b may be directly bonded together with bonding pads 620 in the frontside interconnect layer 234 of the semiconductor device 202a by metal-to-metal bonds. Moreover, a dielectric layer 612 of the interconnect layer 606 of the semiconductor device 202b may be directly bonded together with a dielectric layer 242 of the frontside interconnect layer 234 of the semiconductor device 202a by dielectric-to-dielectric bonds.

The bonding pads 620 of the semiconductor device 202a may be electrically coupled to the conductive structures 244 of the frontside interconnect layer 234 by bonding vias 622. The bonding pads 620 and bonding vias 622 may each include tungsten (W), cobalt (Co), ruthenium (Ru), titanium (Ti), aluminum (Al), copper (Cu), gold (Au), and/or a combination thereof, among other examples of electrically conductive metals.

As indicated above, FIGS. 6A and 6B are provided as an example. Other examples may differ from what is described with regard to FIGS. 6A and 6B.

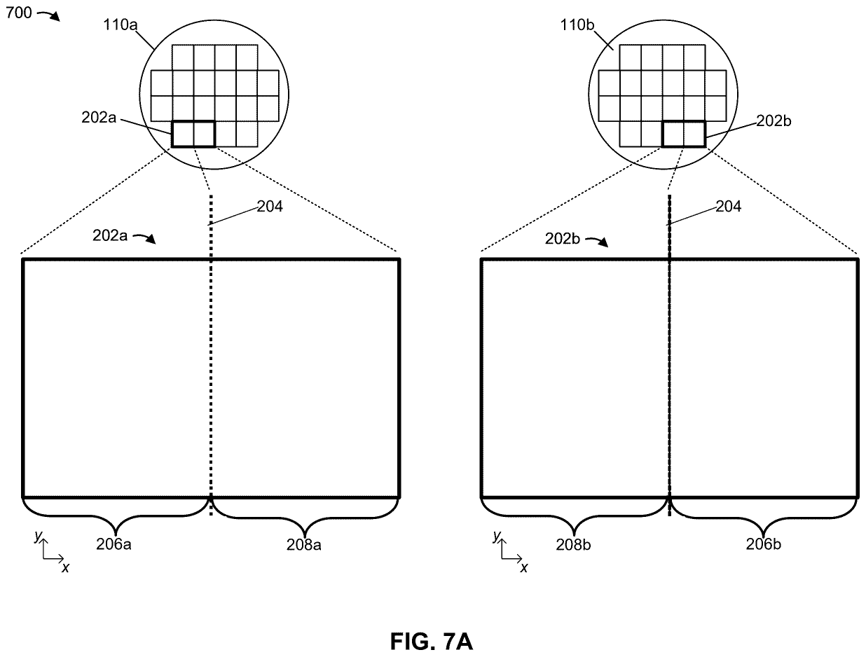

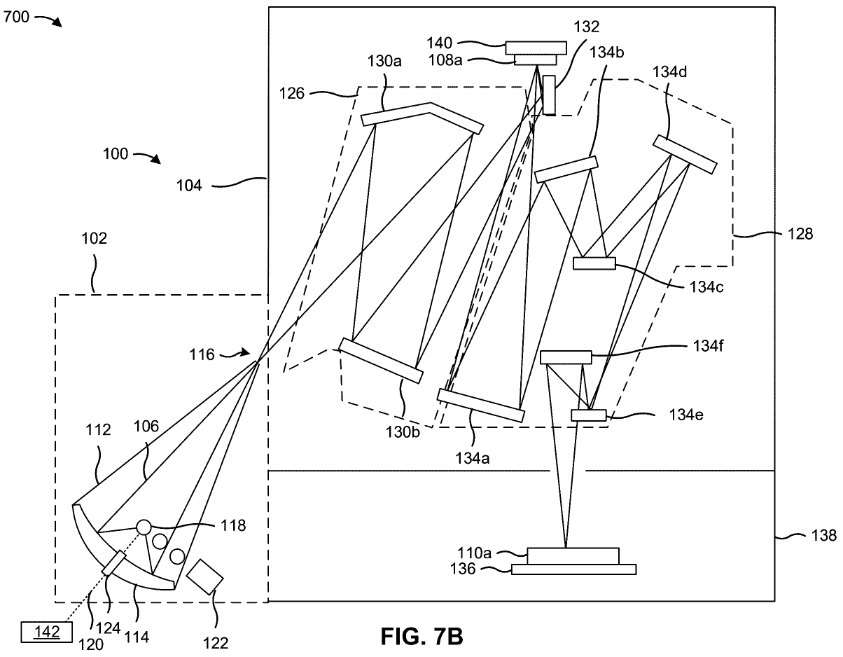

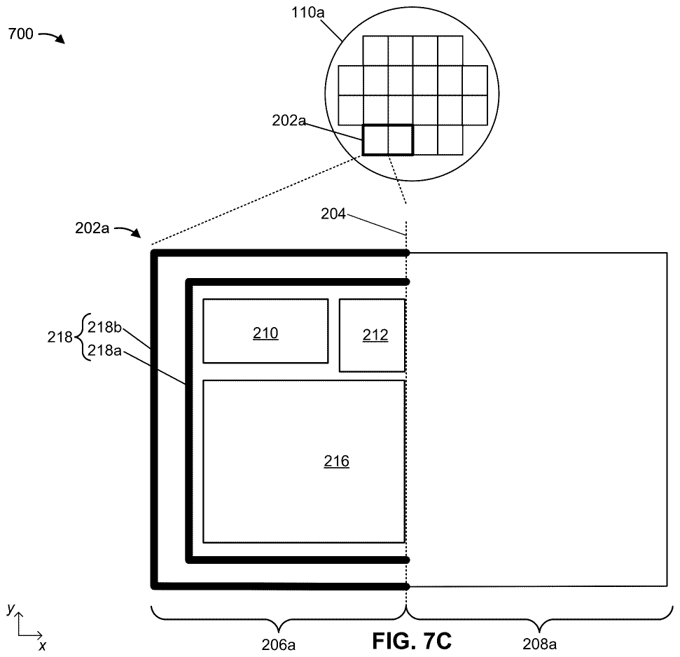

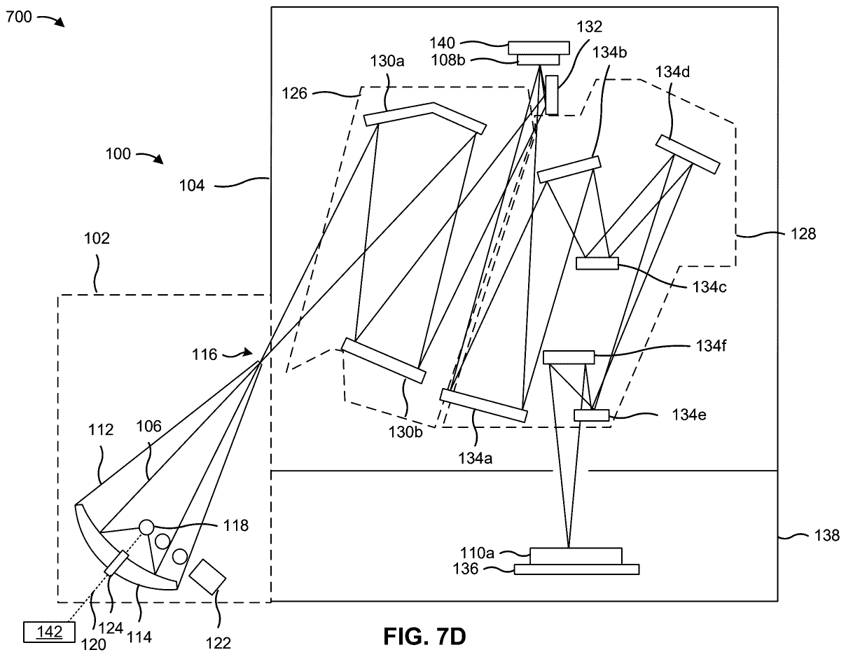

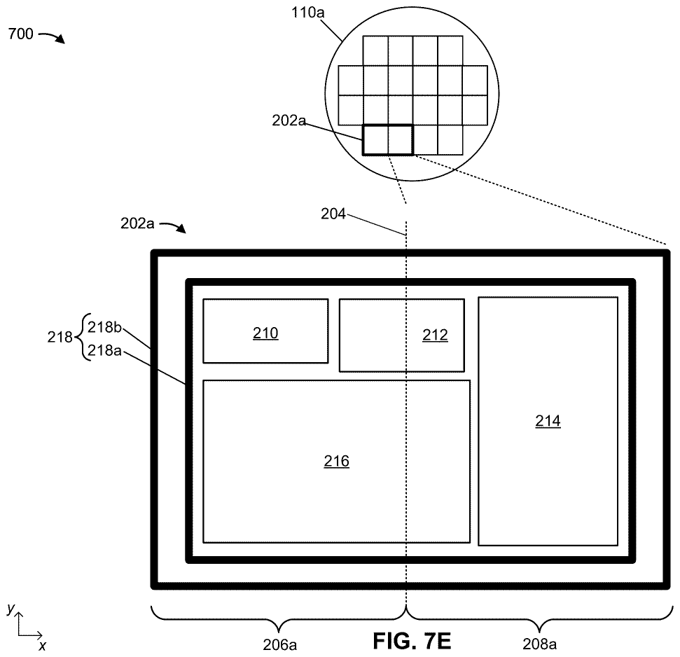

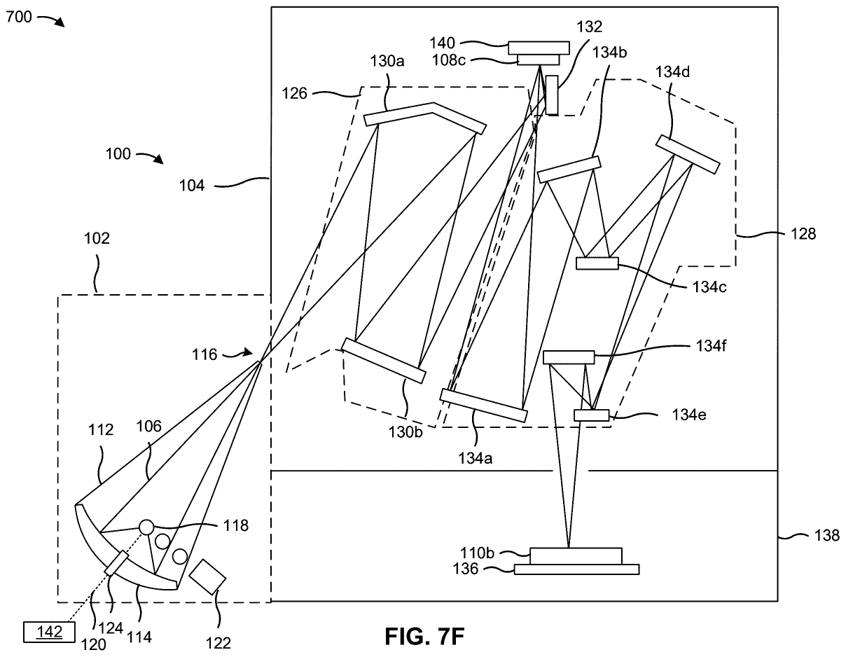

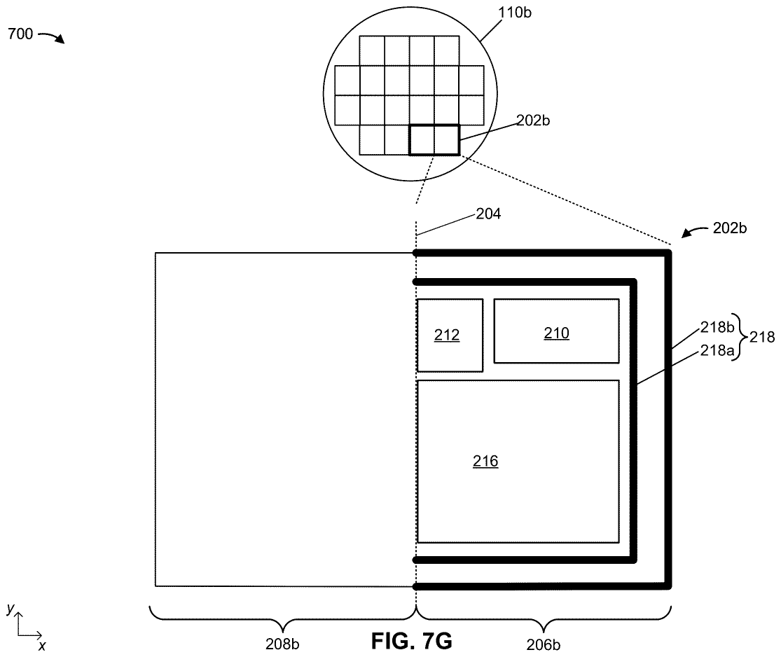

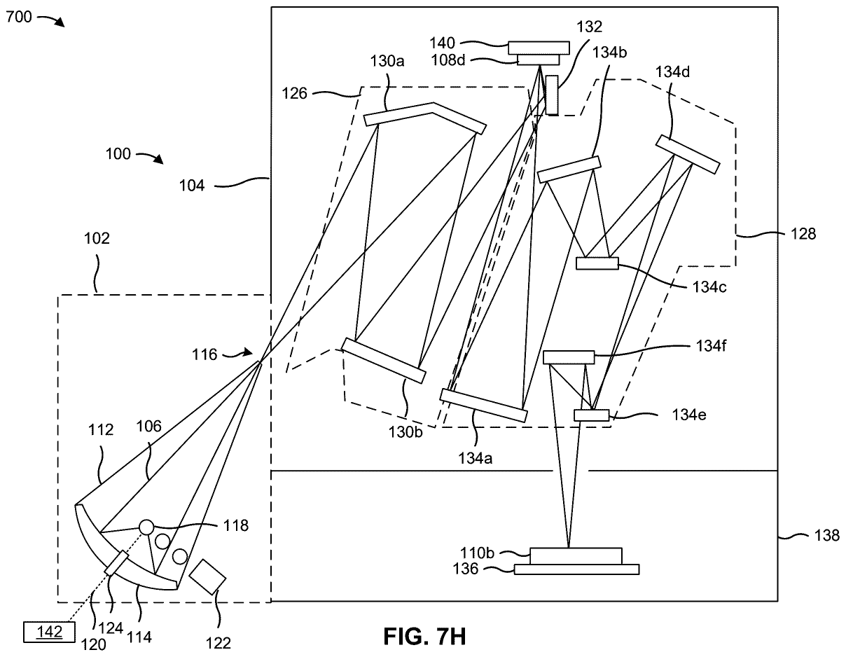

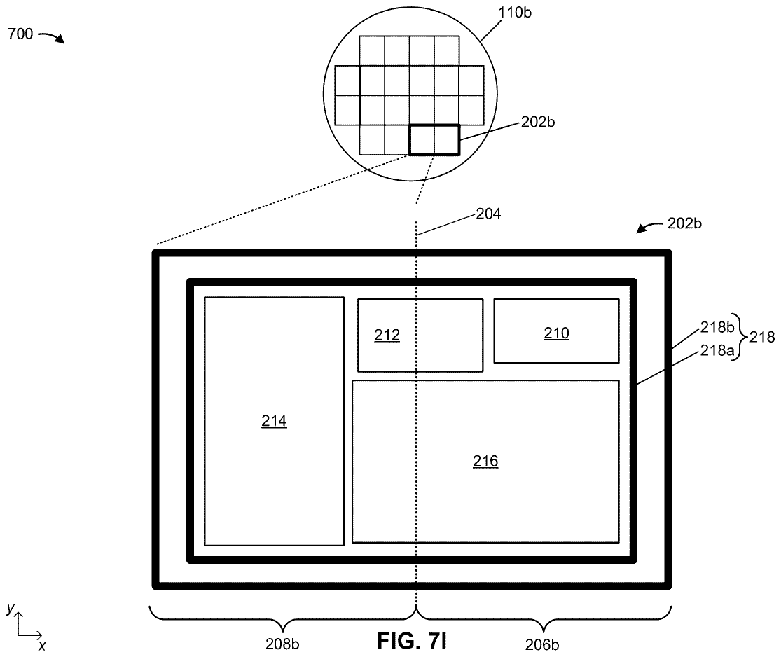

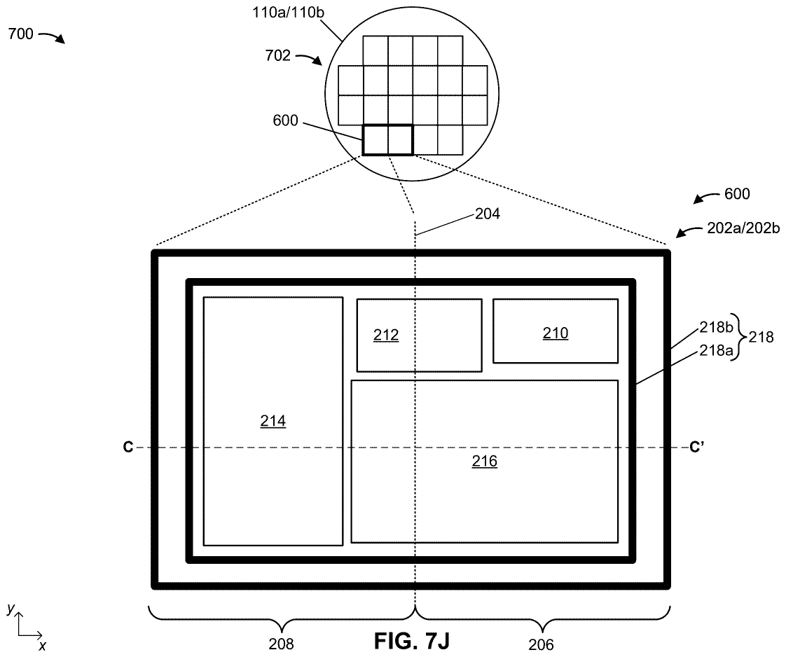

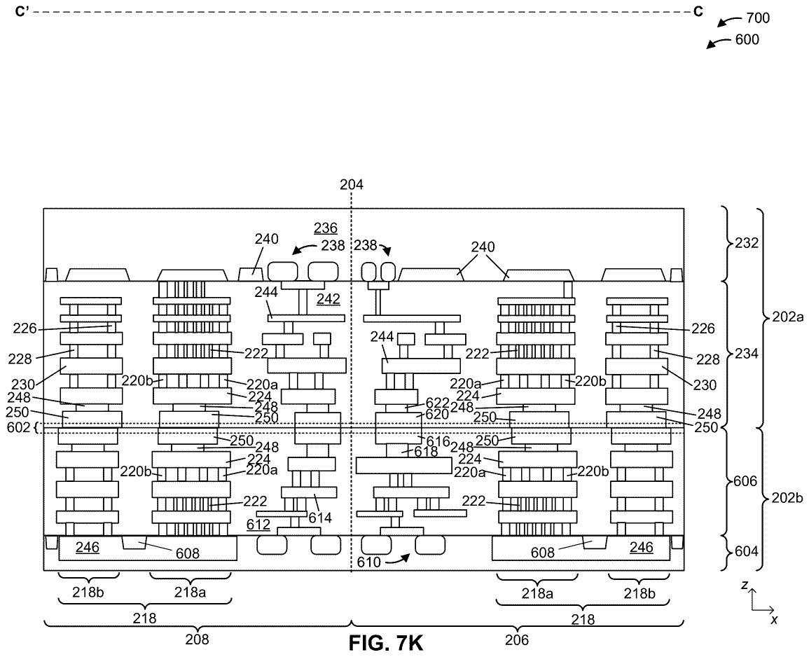

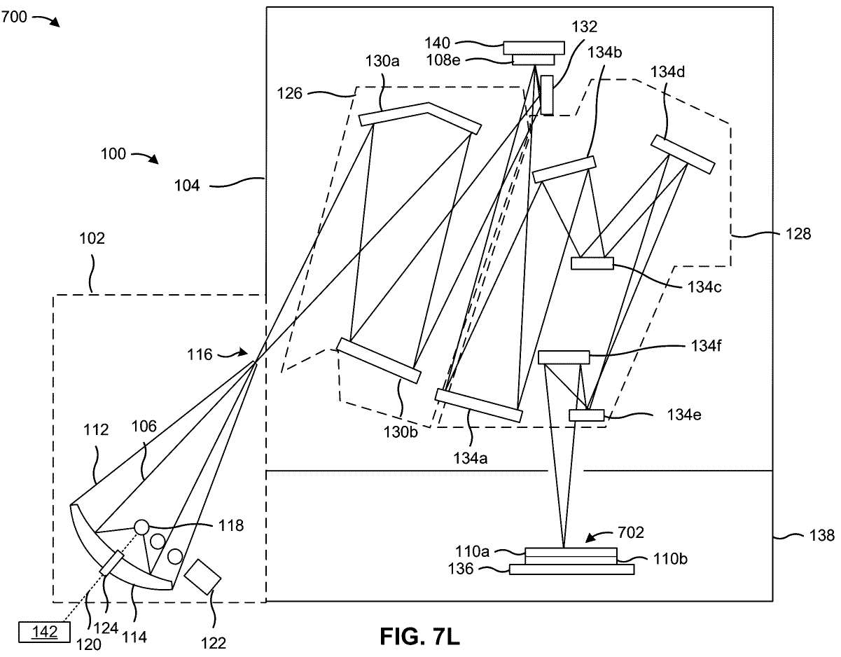

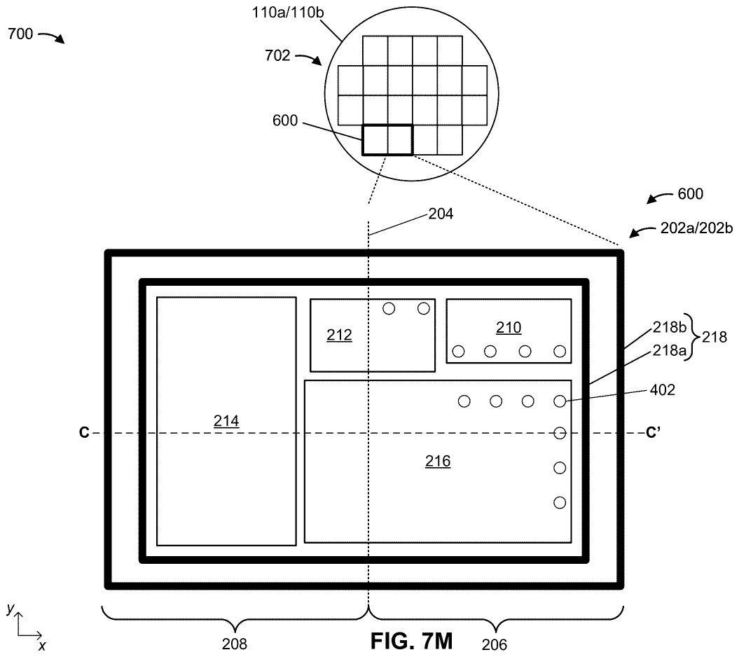

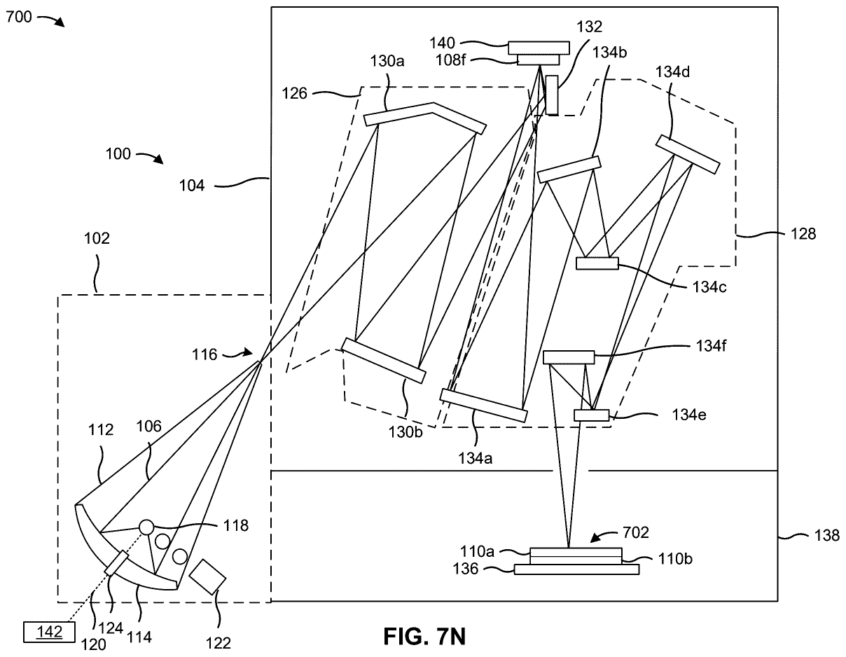

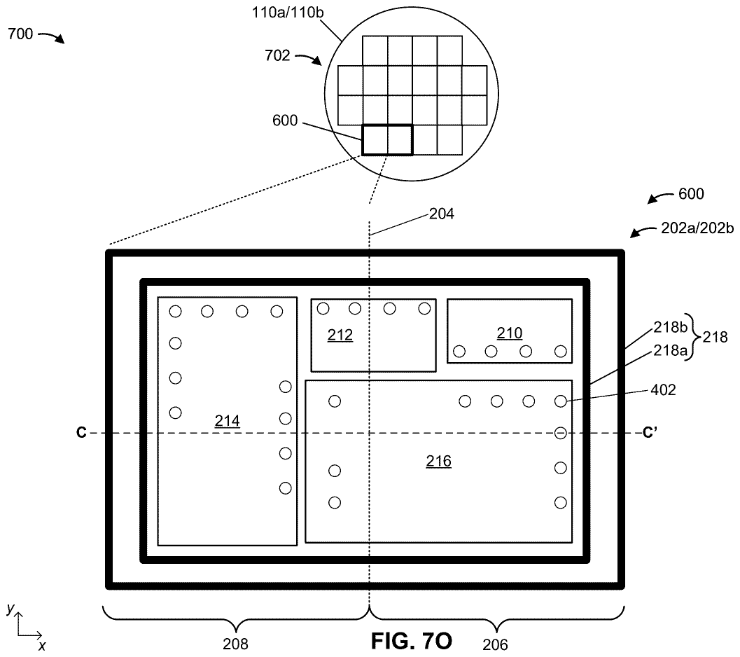

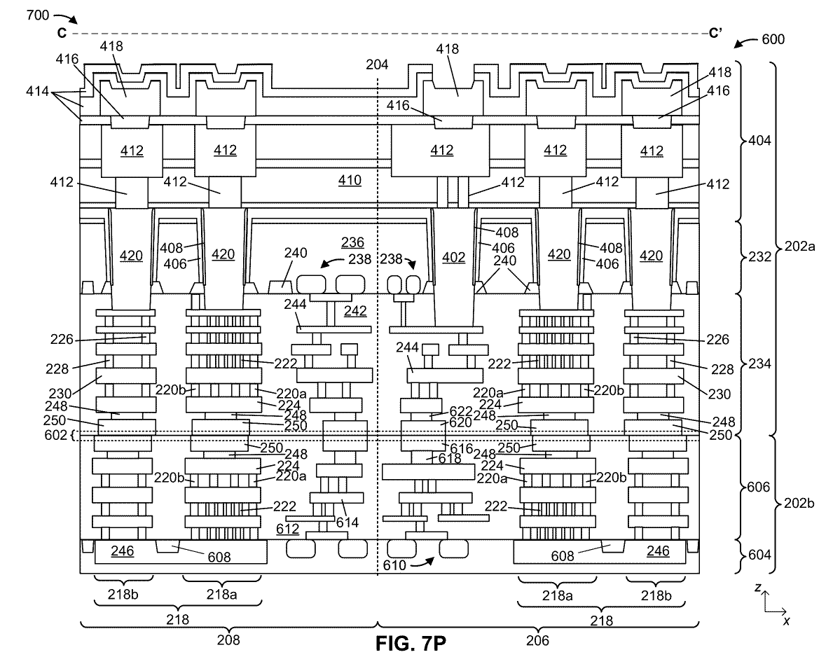

FIGS. 7A-7P are diagrams of an example implementation 700 of forming the stacked semiconductor device described herein. The example implementation 700 includes the use of similar multiple-reticle exposure techniques described in connection with FIGS. 3A-3L and/or 5A-5K to form different layouts on the frontsides of the semiconductor devices 202a and 202b, as well as on the backside of the semiconductor device 202a, using different sets of reticles 108. In some implementations, one or more semiconductor processing tools, such as a deposition tool, an exposure tool (e.g., the lithography system 100), a developer tool, an etch tool, an ion implantation tool, a bonding tool, a planarization tool, and/or another type of semiconductor processing tool, may be used to perform one or more operations described in connection with FIGS. 7A-7P.

As shown in FIG. 7A, the semiconductor devices 202a and 202b may be fabricated on different semiconductor wafers 110. For example, the semiconductor device 202a may be fabricated on a semiconductor wafer 110a, and the semiconductor device 202b may be fabricated on a semiconductor wafer 110b. This enables lateral regions 206 and 208 to be separately patterned using a multiple-reticle exposure technique for both of the semiconductor devices 202a and 202b. In particular, this enables lateral regions 206a and 208a to be patterned separately on the semiconductor device 202a using a multiple-reticle exposure technique, and enables lateral regions 206b and 208b to be separately on the semiconductor device 202b patterned using a multiple-reticle exposure technique.

As shown in FIGS. 7B-7I, multiple-reticle exposure techniques may be used to form patterns and/or structures on the frontsides of the semiconductor devices 202a and on the frontsides of the semiconductor devices 202b respectively formed on the semiconductor wafers 110a and 110b. The frontside processing for the semiconductor devices 202a and 202b may include a similar set of operations, including the use of the multiple-reticle exposure techniques, as illustrated and described in connection with FIGS. 3A-3L and/or 5A-5K.

As shown in FIGS. 7B and 7C, a set of reticles 108a may be used to pattern the lateral regions 206a of the semiconductor devices 202a on the semiconductor wafer 110a to form circuit layouts on the frontsides (e.g., the frontside regions) of the lateral regions 206a in and/or above the frontsides of the device layers 232 of the semiconductor devices 202a. This may include forming integrated circuit devices 238 in and/or on the frontsides of the device layers 232 in the lateral regions 206a, forming isolation regions 240 in and/or on the frontsides of the device layers 232, forming layers of conductive structures 244 in the frontside interconnect layers 234 above the frontsides of the device layers 232 of the semiconductor devices 202a, and/or forming layers of seal ring structures 218a and 218b of multiple seal ring structures 218 in the frontside interconnect layers 234 above the frontsides of the device layers 232 of the semiconductor devices 202a, among other examples.

As shown in FIGS. 7D and 7E, a set of reticles 108b may be used to pattern the lateral regions 208a of the semiconductor devices 202a on the semiconductor wafer 110a to form circuit layouts on the frontsides (e.g., the frontside regions) of the lateral regions 208a in and/or above the frontsides of the device layers 232 of the semiconductor devices 202a. This may include forming integrated circuit devices 238 in and/or on the frontsides of the device layers 232 in the lateral regions 208a, forming isolation regions 240 in and/or on the frontsides of the device layers 232, forming layers of conductive structures 244 in the frontside interconnect layers 234 above the frontsides of the device layers 232 of the semiconductor devices 202a, and/or forming layers of seal ring structures 218a and 218b of multiple seal ring structures 218 in the frontside interconnect layers 234 above the frontsides of the device layers 232 of the semiconductor devices 202a, among other examples.

The use of the sets of reticles 108a and 108b may be sequential. For example, the semiconductor wafer 110a may be placed on the wafer stage 136 of the lithography system 100, a first reticle 108a may be loaded into the reticle stage 140 of the lithography system 100, and the first reticle 108a may be used to perform a first exposure operation to pattern the frontsides of the device layers 232 in the lateral regions 206a to form an arrangement of integrated circuit devices 238 in the lateral regions 206a. The first reticle 108a may be removed from the reticle stage 140 and replaced with a first reticle 108b, and the first reticle 108b may be used to perform a second exposure operation (e.g., after the first exposure operation) to pattern the frontsides of the device layers 232 in the lateral regions 208a to form an arrangement of integrated circuit devices 238 in the lateral regions 208a. Subsequent reticles 108a and 108b may be used to form patterns and/or structures respectively in the lateral regions 206a and 208a of the device layers 232 of the semiconductor devices 202a accordingly.

As another example, a dielectric layer 242 of the frontside interconnect layer 234 may be deposited over the frontside of the device layer 232 of the semiconductor devices 202a. The semiconductor wafer 110a may be placed on the wafer stage 136 of the lithography system 100, a second reticle 108a may be loaded into the reticle stage 140 of the lithography system 100, and the second reticle 108a may be used to perform a third exposure operation (e.g., after the second exposure operation) to pattern the first dielectric layer 242 in the lateral regions 206a. The second reticle 108a may be removed from the reticle stage 140 and replaced with a second reticle 108b in the lithography system 100, and the second reticle 108b may be used to perform a fourth exposure operation (e.g., after the third exposure operation) to pattern the first dielectric layer 242 in the lateral regions 208a. A layer of metal material may be deposited in the respective patterns of the lateral regions 206a and 208a to form different arrangements in a first layer of conductive structures 244 in the lateral regions 206a and 208a, as well as a first layer of metallization structures 224 and 230 of the seal ring structures 218a and 218b of the multiple seal ring structure 218. Subsequent reticles 108a and 108b may be used in a similar sequential manner for patterning additional layers of conductive structures 244 and additional layers of the seal ring structures 218a and 218b of the multiple seal ring structure 218. Subsequent reticles 108a and 108b may be used to form patterns and/or structures respectively in the lateral regions 206a and 208a of the frontside interconnect layers 234 of the semiconductor devices 202a accordingly.

As shown in FIGS. 7F and 7G, a set of reticles 108c may be used to pattern the lateral regions 206b of the semiconductor devices 202b on the semiconductor wafer 110b to form circuit layouts on the frontsides (e.g., the frontside regions) of the lateral regions 206b in and/or above the frontsides of the device layers 604 of the semiconductor devices 202b. This may include forming integrated circuit devices 610 in and/or on the frontsides of the device layers 604 in the lateral regions 206b, forming layers of conductive structures 614 in the interconnect layers 606 above the frontsides of the device layers 604 of the semiconductor devices 202b, and/or forming layers of seal ring structures 218a and 218b of multiple seal ring structures 218 in the interconnect layers 606 above the frontsides of the device layers 604 of the semiconductor devices 202b, among other examples.

As shown in FIGS. 7H and 7I, a set of reticles 108d may be used to pattern the lateral regions 208b of the semiconductor devices 202b on the semiconductor wafer 110b to form circuit layouts on the frontsides (e.g., the frontside regions) of the lateral regions 208b in and/or above the frontsides of the device layers 604 of the semiconductor devices 202b. This may include forming integrated circuit devices 610 in and/or on the frontsides of the device layers 604 in the lateral regions 208b, forming layers of conductive structures 614 in the interconnect layers 606 above the frontsides of the device layers 604 of the semiconductor devices 202b, and/or forming layers of seal ring structures 218a and 218b of multiple seal ring structures 218 in the interconnect layers 606 above the frontsides of the device layers 604 of the semiconductor devices 202b, among other examples.

The use of the sets of reticles 108c and 108d may be sequential. For example, the semiconductor wafer 110b may be placed on the wafer stage 136 of the lithography system 100, a first reticle 108c may be loaded into the reticle stage 140 of the lithography system 100, and the first reticle 108c may be used to perform a first exposure operation to pattern the frontsides of the device layers 604 in the lateral regions 206b to form an arrangement of integrated circuit devices 610 in the lateral regions 206b. The first reticle 108c may be removed from the reticle stage 140 and replaced with a first reticle 108d, and the first reticle 108d may be used to perform a second exposure operation (e.g., after the first exposure operation) to pattern the frontsides of the device layers 604 in the lateral regions 208b to form an arrangement of integrated circuit devices 610 in the lateral regions 208b. Subsequent reticles 108c and 108d may be used to form patterns and/or structures respectively in the lateral regions 206b and 208b of the device layers 604 of the semiconductor devices 202b accordingly.

As another example, a dielectric layer 612 of the interconnect layers 606 may be deposited over the frontside of the device layers 604 of the semiconductor devices 202b. The semiconductor wafer 110b may be placed on the wafer stage 136 of the lithography system 100, a second reticle 108c may be loaded into the reticle stage 140 of the lithography system 100, and the second reticle 108c may be used to perform a third exposure operation (e.g., after the second exposure operation) to pattern the first dielectric layer 612 in the lateral regions 206b. The second reticle 108c may be removed from the reticle stage 140 and replaced with a second reticle 108d in the lithography system 100, and the second reticle 108d may be used to perform a fourth exposure operation (e.g., after the third exposure operation) to pattern the first dielectric layer 612 in the lateral regions 208b. A layer of metal material may be deposited in the respective patterns of the lateral regions 206b and 208b to form different arrangements in a first layer of conductive structures 614 in the lateral regions 206b and 208b, as well as a first layer of metallization structures 224 and 230 of the seal ring structures 218a and 218b of the multiple seal ring structure 218. Subsequent reticles 108c and 108d may be used in a similar sequential manner for patterning additional layers of conductive structures 614 and additional layers of the seal ring structures 218a and 218b of the multiple seal ring structure 218.

As shown in FIGS. 7J and 7K, the semiconductor devices 202a and 202b may be bonded together at the bonding interface 602 after frontside processing of the semiconductor devices 202a and 202b to form a plurality of stacked semiconductor devices 600. The bond between the semiconductor devices 202a and 202b may be formed by bonding the semiconductor wafers 110a and 110b together (e.g., wafer-to-wafer bonding), by bonding dies together (die-to-die bonding), and/or by bonding a die to a wafer (e.g., die-to-wafer bonding), among other example bonding configurations.

As shown in FIG. 7J, bonding the semiconductor wafers 110a and 110b together forms a wafer stack 702 that includes the bonded semiconductor wafers 110a and 110b. The wafer stack 702 includes a plurality of stacked semiconductor devices 600 that are formed by bonding the semiconductor devices 202a of the semiconductor wafer 110a with the semiconductor devices 202b of the semiconductor wafer 110b.

As shown in FIG. 7K, a bonding tool may be used to perform a bonding operation to bond the semiconductor devices 202a and 202b by forming metal-to-metal bonds between the bonding pads 616 of the semiconductor device 202b and the bonding pads 620 of the semiconductor device 202a, and/or dielectric-to-dielectric bonds between the dielectric layer(s) 242 of the semiconductor device 202a and the dielectric layer(s) 612 of the semiconductor device 202b.

As further shown in FIG. 7K, bonding the semiconductor devices 202a and 202b in the stacked arrangement joins together the lateral regions 206a and 206b respectively of the semiconductor devices 202a and 202b, as well as joins together the lateral regions 208a and 208b respectively of the semiconductor devices 202a and 202b. Thus, the integrated circuits of the functional regions 210, 212, and 216 may include a combination of electrically connected integrated circuit devices 238 and 610 respectively of the semiconductor devices 202a and 202b in the lateral region 206 of the stacked semiconductor device 600 (which includes the lateral regions 206a and 206b). The integrated circuits of the functional regions 212, 214, and 216 may include a combination of electrically connected integrated circuit devices 238 and 610 respectively of the semiconductor devices 202a and 202b in the lateral region 208 of the stacked semiconductor device 600 (which includes the lateral regions 208a and 208b).

Moreover, bonding the semiconductor devices 202a and 202b in the stacked arrangement joins together the portions of the seal ring structure 218a formed on the semiconductor devices 202a and 202b, and joins together the portions of the seal ring structure 218b formed on the semiconductor devices 202a and 202b. Thus, the seal ring structures 218a and 218b of the multiple seal ring structure 218 extend vertically through the semiconductor devices 202a and 202b.

As shown in FIGS. 7L-7P, backside processing may be performed for the semiconductor device 202a. The backside processing for the semiconductor device 202a may include a similar set of operations, including the use of the multiple-reticle exposure technique, as illustrated and described in connection with FIGS. 5A-5K. For example, and as shown in FIGS. 7L and 7M, a set of reticles 108e may be used to pattern the lateral region 206 of the stacked semiconductor device 600 to form a circuit layout from the backside of the device layer 232 to the frontside interconnect layer 234 as well as to form a circuit layout in the backside interconnect layer 404 (e.g., the backside region) of the lateral region 206 above the backside of the semiconductor device 202a. As shown in FIGS. 7N and 70, a different set of reticles 108f may be used to pattern the lateral region 208 of the stacked semiconductor device 600 to form a circuit layout from the backside of the device layer 232 to the frontside interconnect layer 234 as well as to form a circuit layout in the backside interconnect layer 404 (e.g., the backside region) of the lateral region 208 above the backside of the semiconductor device 202a.

The use of the sets of reticles 108e and 108f may be sequential. For example, a dielectric layer 410 of the backside interconnect layer 404 may be deposited over the backside of the device layer 232 of the semiconductor device 202a. The stacked semiconductor device 600 may be placed on the wafer stage 136 of the lithography system 100, a first reticle 108e may be loaded into the reticle stage 140 of the lithography system 100, and the first reticle 108e may be used to perform a first exposure operation to pattern the first dielectric layer 410 in the lateral region 206. The first reticle 108e may be removed from the reticle stage 140 and replaced with a first reticle 108f of the lithography system 100, and the first reticle 108f may be used to perform a second exposure operation to pattern the first dielectric layer 410 in the lateral region 208. A layer of metal material may be deposited in the respective patterns of the lateral regions 206 and 208 to form different arrangements in a first layer of conductive structures 412 in the lateral regions 206 and 208. Subsequent reticles 108e and 108f may be used in a similar sequential manner for patterning additional layers of conductive structures 412.

The above-described sequential process may be performed at the wafer level for a plurality of stacked semiconductor devices 600 formed from the wafer stack 702. For example, and as shown in FIGS. 7L and 7M, the set of reticles 108e may be used to pattern the lateral regions 206 of the stacked semiconductor devices 600 of the wafer stack 702 to form circuit layouts in the backside interconnect layers 404 (e.g., the backside regions) of the lateral regions 206 of the stacked semiconductor devices 600. As shown in FIGS. 7N and 70, a different set of reticles 108f may be used to pattern the lateral regions 208 of the stacked semiconductor devices 600 of the wafer stack 702 to form a circuit layout in the backside interconnect layers 404 (e.g., the backside regions) of the lateral regions 208 of the stacked semiconductor devices 600.

As shown in FIG. 7P, the backside processing may be performed to form one or more through-substrate interconnect structures 402 (and the associated liners 406, 408) through the substrate layer 236 of the semiconductor device 202a, to form one or more through-substrate isolation structures 420 (and the associated liners 406, 408) through the substrate layer 236 of the semiconductor device 202a, to form the dielectric layer(s) 410 of the backside interconnect layer 404, to form the conductive structures 412 of the backside interconnect layer 404, to form the passivation layers 414, and/or to form connection pads 416 and connection structures 418, among other examples.

After the semiconductor devices 202a and 202b are bonded together to form the stacked semiconductor device 600, a die singulation tool may be used to dice or cut the stacked semiconductor devices 600 from the wafer stack 702 so that the stacked semiconductor devices 600 can be packaged and/or shipped to another facility for further processing.

As indicated above, FIGS. 7A-7P are provided as an example. Other examples may differ from what is described with regard to FIGS. 7A-7P.

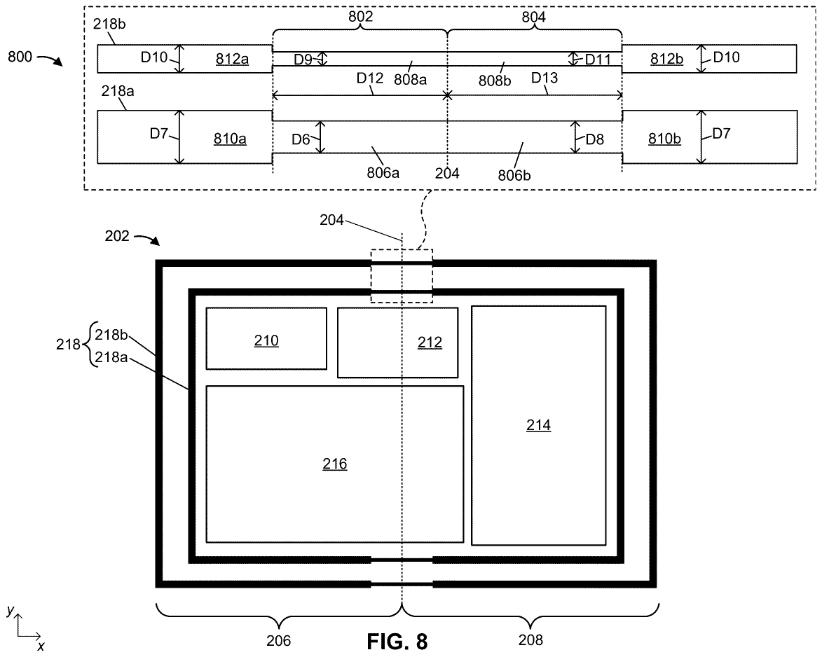

FIG. 8 is a diagram of an example implementation 800 of reticles for a multiple-reticle exposure technique described herein. FIG. 8 illustrates circuit pattern layouts for reticles 108a and 108b for respectively patterning lateral regions 206 and 208 of a semiconductor device 202 described herein. In particular, the circuit pattern layouts for the reticles 108a and 108b are configured such that multiple seal ring structures 218 in the circuit pattern layouts include seal ring structures 218a and/or 218b that have segments at the interface 204 that have different attributes than other segments away from the interface 204. The interface 204 corresponds to the edges of the circuit pattern layouts for the reticles 108a and 108b for the lateral regions 206 and 208. A higher rate of defects may occur near the interface 204 due to pattern misalignment, pattern density, and/or other factors. The different attributes of the segments of the seal ring structures 218a and/or 218b near the interface 204 may decrease the likelihood of and/or the rate of defects at the interface 204 for a semiconductor device 202 formed using the reticles 108a and 108b.

As shown in FIG. 8, the reticle 108a may include a buffer region 802 and the reticle 108b may include a buffer region 804. The buffer regions 802 and 804 may be located at the respective edges of the reticles 108a and 108b, which may be located on opposing lateral sides of the interface 204. The buffer region 802 may be used to pattern a portion of the lateral region 206 on a semiconductor device 202 in which pattern rules and/or parameters for a first set of reticles are selected to reduce and/or minimize the likelihood of defect formation at the interface 204. Similarly, the buffer region 804 may be used to pattern a portion of the lateral region 208 of a semiconductor device 202 in which pattern rules and/or parameters for a second set of reticles are selected to reduce and/or minimize the likelihood of defect formation at the interface 204.

The buffer regions 802 and 804 may be referred to as optical proximity correction (OPC) zones of the reticles 108a and 108b, respectively. In the OPC zones, OPC design processes are performed to tune (e.g., correct or optimize) the layout design of the reticles 108a and 108b for improved lithography imaging. The objective of the OPC process is to accurately transfer a specified circuit layout design onto a semiconductor device 202. For example, OPC can be used to compensate for image errors due to diffraction, distortion, process effects, and/or other types of aberrations. OPC may enable increased edge placement integrity to be achieved for a circuit layout design. For example, after processing, pattern images transferred onto the semiconductor device 202 can appear with irregularities such as line widths that are narrower or wider than designed. OPC can compensate for such irregularities by changing (e.g., correcting) or modifying the original circuit layout design for implementation in a circuit pattern layout of the reticles 108a and 108b.

In the buffer region 802, a segment 806a of the reticle 108a for patterning the seal ring structure 218a may have a lateral width (indicated in FIG. 8 as a dimension D6) approximately perpendicular to a length of the segment 806a, and the lateral width of the segment 806a may be less than the lateral width (indicated in FIG. 8 as a dimension D7) in another segment 810a of the reticle 108a for patterning the seal ring structure 218a outside of the buffer regions 802 and 804. In the buffer region 804, a segment 806b of the reticle 108b for patterning the seal ring structure 218a may have a lateral width (indicated in FIG. 8 as a dimension D8) approximately perpendicular to a length of the segment 806b, and the lateral width of the segment 806b may be less than the lateral width (indicated in FIG. 8 as dimension D8) of a segment 810b of the reticle 108b for patterning the seal ring structure 218a outside of the buffer regions 802 and 804.

In the buffer region 802, a segment 808a of the reticle 108a for patterning the seal ring structure 218b may have a lateral width (indicated in FIG. 8 as a dimension D9) approximately perpendicular to a length of the segment 808a, and the lateral width of the segment 808a may be less than the lateral width (indicated in FIG. 8 as a dimension D10) of another segment 812a of the reticle 108a for patterning the seal ring structure 218b outside of the buffer regions 802 and 804. In the buffer region 804, a segment 808b of the reticle 108b for patterning the seal ring structure 218b may have a lateral width (indicated in FIG. 8 as a dimension D11) approximately perpendicular to a length of the segment 808b, and the lateral width of the segment 808b may be less than the lateral width (indicated in FIG. 8 as dimension D10) of a segment 812b of the reticle 108b for patterning the seal ring structure 218b outside of the buffer regions 802 and 804.

The lesser lateral widths of the segments 806a, 806b, 808a and 808b in the buffer regions 802 and 804 (e.g., in the OPC zones) near the interface 204 may be implemented as OPC to compensate for distortion in line widths in the seal ring structures 218a and 218b at the edges of the lateral regions 206 and 208. The lateral widths of the segments 806a, 806b, 808a and 808b may be determined by a logic operation (LOP) as part of the OPC process for generating the circuit layouts for the reticles 108a and 108b.

As further shown in FIG. 8, the buffer region 802 may have a lateral width in the x-direction (indicated in FIG. 8 as dimension D12), and the buffer region 804 may have a lateral width in the x-direction (indicated in FIG. 8 as dimension D13). The lateral widths of the buffer regions 802 and 804 may each be included in a range of approximately 2 microns to approximately 10 microns. However, other values and ranges are within the scope of the present disclosure.

As indicated above, FIG. 8 is provided as an example. Other examples may differ from what is described with regard to FIG. 8.

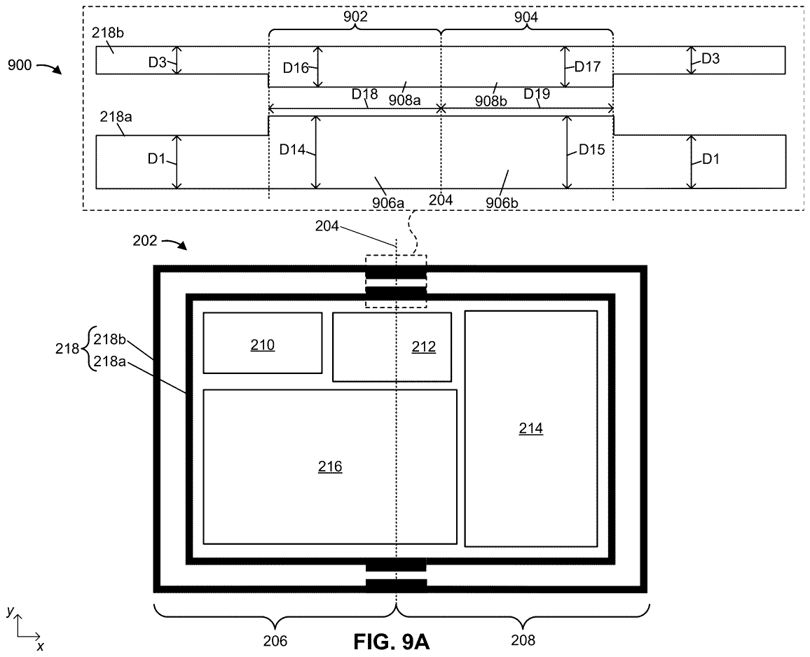

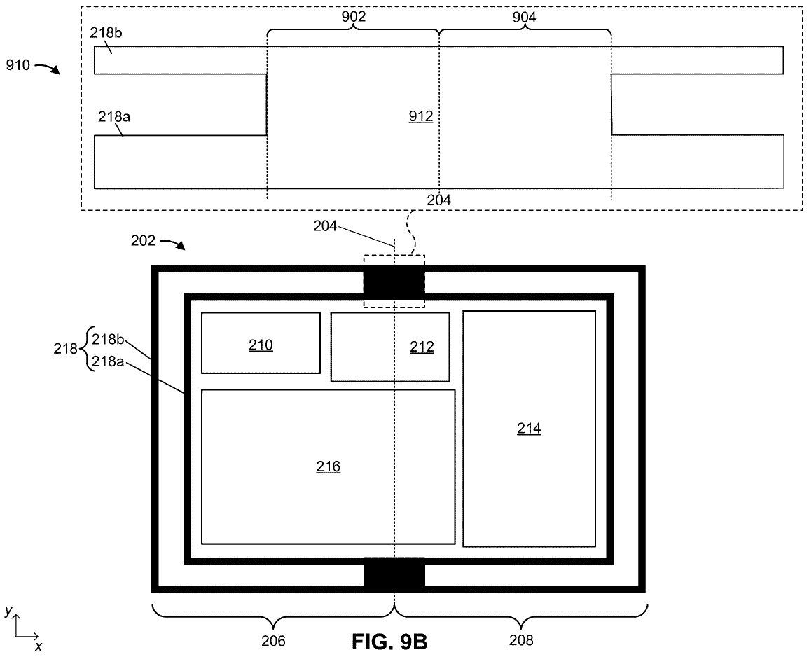

FIGS. 9A and 9B are diagrams of example implementations of semiconductor devices 202 described herein. In the example implementations illustrated in FIGS. 9A and 9B, the semiconductor devices 202 include implementations of multiple seal ring structures 218 in which the seal ring structures 218a and/or 218b include segments at the interface 204 that have different attributes than other segments away from the interface 204. The interface 204 corresponds to the edges of the patterns implemented by the different sets of reticles 108 for the lateral regions 206 and 208. Thus, a higher rate of defects may occur near the interface 204 due to pattern misalignment, pattern density, and/or other factors. The different attributes of the segments of the seal ring structures 218a and/or 218b near the interface 204 may decrease the likelihood of and/or the rate of defects at the interface 204.

In particular, the lateral widths of the seal ring structures 218a and/or 218b near the interface 204 in the example implementations of semiconductor devices 202 illustrated in FIGS. 9A and 9B are increased relative to the lateral widths of other segments of the seal ring structures 218a and/or 218b to compensate for reticle misalignment between the lateral regions 206 and 208 at the interface 204. Reticle misalignment between the lateral regions 206 and 208 at the interface 204 may result in misalignment of the sections of the seal ring structure 218a in the lateral regions 206 and 208 at the interface 204, and/or may result in misalignment of the sections of the seal ring structure 218b in the lateral regions 206 and 208 at the interface 204. The misalignment between the sections of the seal ring structure 218a in the lateral regions 206 and 208 may result in the sections of seal ring structure 218a in the lateral regions 206 and 208 not connecting together at the interface 204 to form a continuous seal ring structure 218a around the semiconductor device 202. Similarly, the misalignment between the sections of the seal ring structure 218b in the lateral regions 206 and 208 may result in the sections of seal ring structure 218b in the lateral regions 206 and 208 not connecting together at the interface 204 to form a continuous seal ring structure 218b around the semiconductor device 202. Discontinuities in the seal ring structure 218a and/or in the seal ring structure 218b may diminish the ability of the seal ring structures 218a and/or 218b to protect the functional regions 210-216 of the semiconductor device 202.

As shown in FIG. 9A, an example implementation 900 of a semiconductor device 202 may include buffer regions 902 and 904 respectively in the lateral regions 206 and 208 on opposing sides of the interface 204. In the buffer region 902, a segment 906a of the seal ring structure 218a may have a lateral width (dimension D14 illustrated in FIG. 9A) in a direction approximately perpendicular to the length of the segment 906a that is greater than a lateral width (dimension D1) of the seal ring structure 218a outside of the buffer regions 902 and 904. Similarly, in the buffer region 904, a segment 906b of the seal ring structure 218a may have a lateral width (dimension D15 illustrated in FIG. 9A) in a direction approximately perpendicular to the length of the segment 906b that is greater than a lateral width (dimension D1) of the seal ring structure 218a outside of the buffer regions 902 and 904. The greater lateral widths of the segments 906a and 906b than other segments of the seal ring structure 218a increase the likelihood that the sections of the seal ring structure 218a formed in the lateral regions 206 and 208 will be connected together at the interface 204, and provide for a wider process window for patterning the seal ring structure 218a using a multiple-reticle exposure technique. In some implementations, the lateral widths of the segments 906a and 906b may be approximately 20% to approximately 30% greater than the lateral width of the seal ring structure 218 a (e.g., of the dimension D1). However, other values and ranges are within the scope of the present disclosure.

In the buffer region 902, a segment 908a of the seal ring structure 218b may have a lateral width (dimension D16 illustrated in FIG. 9A) in a direction approximately perpendicular to the length of the segment 908a that is greater than a lateral width (dimension D3) of the seal ring structure 218b outside of the buffer regions 902 and 904. Similarly, in the buffer region 904, a segment 908b of the seal ring structure 218b may have a lateral width (dimension D17 illustrated in FIG. 9A) in a direction approximately perpendicular to the length of the segment 908b that is greater than a lateral width (dimension D3) of the seal ring structure 218b outside of the buffer regions 902 and 904. The greater lateral widths of the segments 908a and 908b than other segments of the seal ring structure 218b increase the likelihood that the sections of the seal ring structure 218b formed in the lateral regions 206 and 208 will be connected together at the interface 204, and provide for a wider process window for patterning the seal ring structure 218b using a multiple-reticle exposure technique. In some implementations, the lateral widths of the segments 908a and 908b may be approximately 20% to approximately 30% greater than the lateral width of the seal ring structure 218b (e.g., of the dimension D3). However, other values and ranges are within the scope of the present disclosure.

As further shown in FIG. 9A, the buffer region 902 may have a lateral width in the x-direction (indicated in FIG. 9A as dimension D18), and the buffer region 904 may have a lateral width in the x-direction (indicated in FIG. 9A as dimension D19). The lateral widths of the buffer regions 902 and 904 may each be included in a range of approximately 2 microns to approximately 10 microns. However, other values and ranges are within the scope of the present disclosure.

The multiple-reticle exposure techniques described in connection with FIGS. 3A-3L, 5A-5K, and/or 7A-7P may be performed to form the sections of the seal ring structures 218 a and 218b of the multiple seal ring structure 218 to include the segments 906a and 908a in the lateral region 206, and to include the segments 906b and 908b in the lateral region 208. For example, a first set of reticles 108 may be used to pattern the lateral region 206 to form the segments 906a and 908a in the buffer region 902 of the lateral region 206, and a second set of reticles 108 may be used to pattern the lateral region 208 to form the segments 906b and 908b in the buffer region 904 of the lateral region 208.

As shown in FIG. 9B, an example implementation 910 of a semiconductor device 202 may include seal ring structures 218a and 218b that have segments having greater lateral widths in the buffer regions 902 and 904 than outside of the buffer regions 902 and 904. The increased lateral widths of the segments of the seal ring structures 218a and 218b results in the seal ring structures 218a and 218b merging together in the buffer regions 902 and 904. Thus, the multiple seal ring structure 218 may include a merged segment 912 in the buffer regions 902 and 904 that extends across the interface 204 between the lateral regions 206 and 208.

The multiple-reticle exposure techniques described in connection with FIGS. 3A-3L, 5A-5K, and/or 7A-7P may be performed to form the sections of the seal ring structures 218 a and 218b of the multiple seal ring structure 218 to include the portions of the merged segment 912 in the lateral regions 206 and 208. For example, a first set of reticles 108 may be used to pattern the lateral region 206 to form a first portion of the merged segment 912 in the buffer region 902 of the lateral region 206, and a second set of reticles 108 may be used to pattern the lateral region 208 to form a second portion of the merged segment 912 in the buffer region 904 of the lateral region 208.

As indicated above, FIGS. 9A and 9B are provided as examples. Other examples may differ from what is described with regard to FIGS. 9A and 9B.

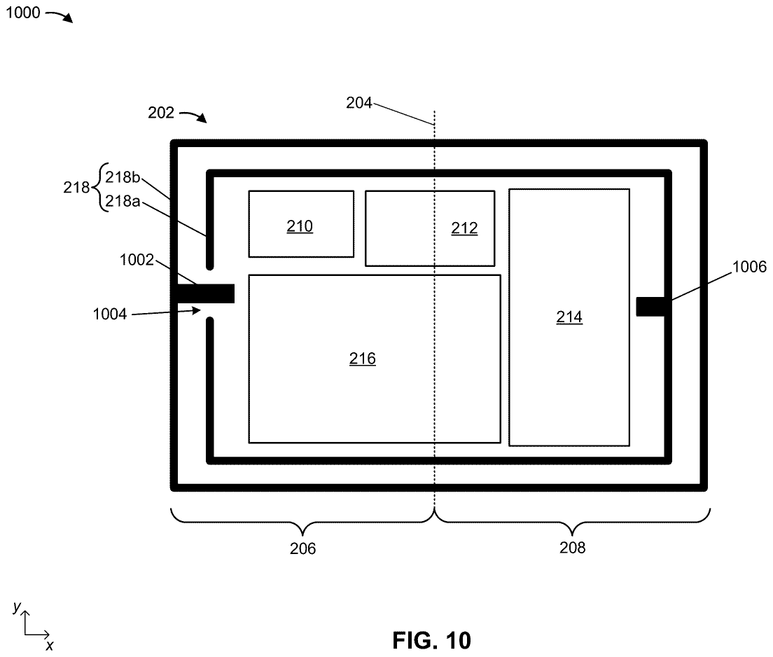

FIG. 10 is a diagram of example implementation 1000 of a semiconductor device 202 described herein. In the example implementation 1000, the seal ring structures 218a and 218b of the multiple seal ring structure 218 are configured as capacitor electrodes that are physically separated by the dielectric layer(s) 242 in the frontside interconnect layer 234 of the semiconductor device 202. In this way, the combination of the seal ring structures 218a and 218b and the dielectric layer(s) 242 between the seal ring structures 218a and 218b enables the multiple seal ring structure 218 to operate as a capacitor that can absorb leakage current around the functional regions 210-216 of the semiconductor device 202 for increased electrical isolation.

As shown in FIG. 10, the example implementation 1000 of the semiconductor device 202 includes a similar top view layout as the example implementation 200 of a semiconductor device 202 illustrated in FIG. 2A. However, the seal ring structure 218b in the example implementation 1000 of the semiconductor device 202 includes a terminal 1002 that extends through a cut section 1004 of the seal ring structure 218a. Similarly, the seal ring structure 218a includes a terminal 1006 that extends inward toward the center of the semiconductor device 202. The terminal 1002 may be a lateral extension of the seal ring structure 218b, and the terminal 1006 may be a lateral extension of the seal ring structure 218a.

The terminal 1002 may be grounded (e.g., may be electrically coupled to an electrical ground of the semiconductor device 202), and the terminal 1006 may be electrically coupled to a bias input to bias the multiple seal ring structure 218. The bias causes the seal ring structures 218a and 218b to absorb charge carriers around the multiple seal ring structure 218 to prevent or minimize the likelihood of the charge carriers interfering with the operation of the functional regions 210-216 of the semiconductor device 202.

The multiple-reticle exposure techniques described in connection with FIGS. 3A-3L, 5A-5K, and/or 7A-7P may be performed to form the sections of the seal ring structures 218 a and 218b of the multiple seal ring structure 218 to include the terminal 1002 and the cut section 1004 in the lateral region 206, and to form the sections of the seal ring structures 218a and 218b of the multiple seal ring structure 218 to include the terminal 1006 in the lateral region 208. For example, a first set of reticles 108 may be used to pattern the lateral region 206 to form a first section of the seal ring structure 218b in the lateral region 206 to include the terminal 1002, and to form a first section of the seal ring structure 218a to include the cut section 1004 in the lateral region 206. A second set of reticles 108 may be used to pattern the lateral region 208 to form a second section of the seal ring structure 218a to include the terminal 1006 in the lateral region 208.

As indicated above, FIG. 10 is provided as an example. Other examples may differ from what is described with regard to FIG. 10.

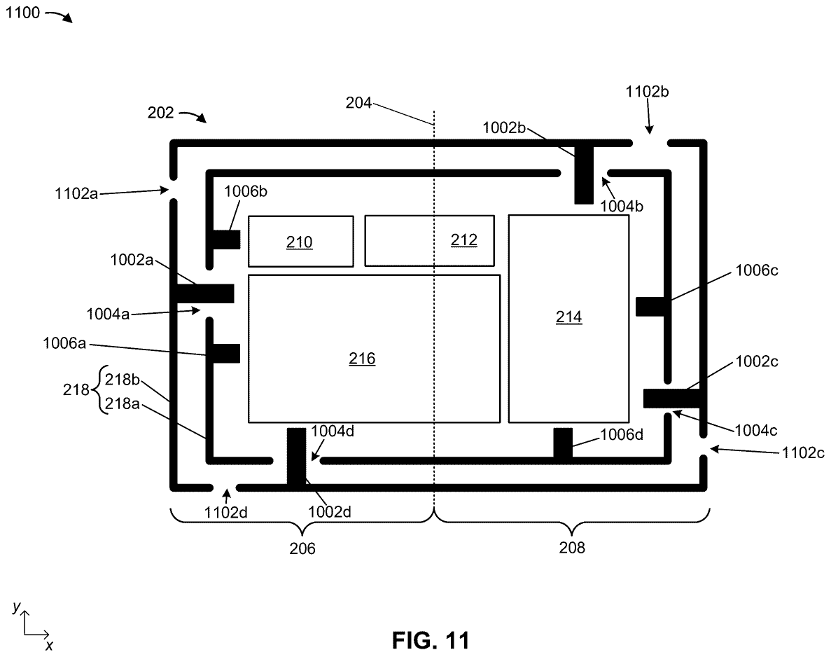

FIG. 11 is a diagram of example implementation 1100 of a semiconductor device 202 described herein. The example implementation 1100 of the semiconductor device 202 is similar to the example implementation 1000 of the semiconductor device 202 in that the multiple seal ring structure 218 in the example implementation 1100 of the semiconductor device 202 is configured to operate as a capacitor that can absorb leakage current around the functional regions 210-216 of the semiconductor device 202 for increased electrical isolation. However, in the example implementation 1100 of the semiconductor device 202, the multiple seal ring structure 218 is segmented to include a plurality of discontinuous capacitive segments around the perimeter of the semiconductor device 202.

As shown in FIG. 11, the seal ring structure 218b may include a terminal 1002a coupled to a first segment of the seal ring structure 218b, and the seal ring structure 218a may include a terminal 1006a coupled to a first segment of the seal ring structure 218a. The first segments of the seal ring structures 218a and 218b, along with the terminals 1002a and 1006a, may correspond to a capacitive segment of the multiple seal ring structure 218.

The seal ring structure 218b may include a terminal 1002b coupled to a second segment of the seal ring structure 218b, and the seal ring structure 218a may include a terminal 1006b coupled to a second segment of the seal ring structure 218a. The second segments of the seal ring structures 218a and 218b, along with the terminals 1002b and 1006b, may correspond to a capacitive segment of the multiple seal ring structure 218.

The seal ring structure 218b may include a terminal 1002c coupled to a third segment of the seal ring structure 218b, and the seal ring structure 218a may include a terminal 1006c coupled to a third segment of the seal ring structure 218a. The third segments of the seal ring structures 218a and 218b, along with the terminals 1002c and 1006c, may correspond to a capacitive segment of the multiple seal ring structure 218.

The seal ring structure 218b may include a terminal 1002d coupled to a fourth segment of the seal ring structure 218b, and the seal ring structure 218a may include a terminal 1006d coupled to a fourth segment of the seal ring structure 218a. The fourth segments of the seal ring structures 218a and 218b, along with the terminals 1002d and 1006d, may correspond to a capacitive segment of the multiple seal ring structure 218.

The capacitive segments of the multiple seal ring structure 218 may be spaced apart and separated by dielectric layers(s) 242 of the frontside interconnect layer 234 of the semiconductor device 202. Cut sections 1004a-1004d and 1102a-1102d may provide the spacing between the capacitive segments of the multiple seal ring structure 218. The cut sections 1004a-1004d and 1102a-1102d may be included to provide stress relief around the edge or perimeter of the semiconductor device 202.

A cut section 1004a may be located between the first and second segments of the seal ring structure 218a, a cut section 1004b may be located between the second and third segments of the seal ring structure 218a, a cut section 1004c may be located between the third and fourth segments of the seal ring structure 218a, and a cut section 1004d may be located between the fourth and first segments of the seal ring structure 218a. A cut section 1102a may be located between the first and second segments of the seal ring structure 218b, a cut section 1102b may be located between the second and third segments of the seal ring structure 218b, a cut section 1102c may be located between the third and fourth segments of the seal ring structure 218b, and a cut section 1102d may be located between the fourth and first segments of the seal ring structure 218b.

The terminal 1002a may extend laterally through the cut section 1004a. The terminal 1002b may extend laterally through the cut section 1004b. The terminal 1002c may extend laterally through the cut section 1004c. The terminal 1002d may extend laterally through the cut section 1004d.

As indicated above, FIG. 11 is provided as an example. Other examples may differ from what is described with regard to FIG. 11.

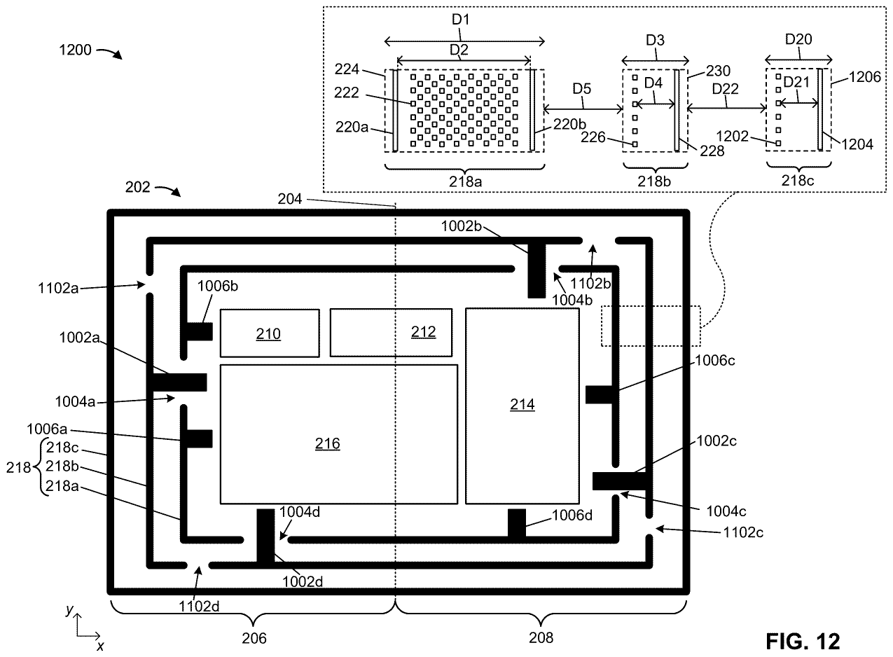

FIG. 12 is a diagram of example implementation 1200 of a semiconductor device 202 described herein. The example implementation 1200 of the semiconductor device 202 is similar to the example implementation 1100 of the semiconductor device 202 in that the multiple seal ring structure 218 in the example implementation 1200 of the semiconductor device 202 is configured to operate as a capacitor that can absorb leakage current around the functional regions 210-216 of the semiconductor device 202 for increased electrical isolation. However, in the example implementation 1200 of the semiconductor device 202, the multiple seal ring structure 218 further includes another seal ring structure 218c that laterally surrounds the perimeter of the semiconductor device 202.

As shown in FIG. 12, the seal ring structure 218c may be included around the seal ring structure 218b. Thus, in the example implementation 1200 of the semiconductor device 202, the seal ring structure 218a is an inner seal ring structure of the multiple seal ring structure 218, the seal ring structure 218b is a middle seal ring structure of the multiple seal ring structure 218, and the seal ring structure 218c is an outer seal ring structure of the multiple seal ring structure 218.

As further shown in FIG. 12, the seal ring structure 218c may include a closed-loop structure that extends fully and continuously around the perimeter of the semiconductor device 202. The seal ring structure 218c may include a vertical arrangement of inner pillar interconnect structures 1202, outer line interconnect structures 1204, and metallization structures 1206. Each layer of interconnect structures of the seal ring structure 218c may include an arrangement of inner pillar interconnect structures 1202 and an outer line interconnect structure 1204. Two layers of interconnect structures of the seal ring structure 218c may be coupled together by a metallization structure 1206 located vertically between the two layers of interconnect structures.

The seal ring structure 218c may have a lateral width (indicated in FIG. 12 as dimension D20) and a lateral spacing (indicated in FIG. 12 as dimension D21) between the inner pillar interconnect structures 1202 and an outer line interconnect structure 1204 of the seal ring structure 218c. In some implementations, the lateral width of the seal ring structure 218c may be less than the lateral width of the seal ring structure 218b (e.g., D20<D3). For example, the lateral width of the seal ring structure 218c may be approximately 1.5 microns to approximately 2 microns, whereas the lateral width of the seal ring structure 218b may be approximately 2.5 microns to approximately 3 microns. However, other values and ranges are within the scope of the present disclosure.

The seal ring structure 218c may be spaced apart from the seal ring structures 218b by a distance (indicated in FIG. 12 as dimension D22). In some implementations, the distance between the seal ring structure 218c and the seal ring structure 218b is greater than the distance between the seal ring structure 218b and the seal ring structure 218a (e.g., D22>D5). In some implementations, the distance between the seal ring structure 218c and the seal ring structure 218b is less than the distance between the seal ring structure 218b and the seal ring structure 218a (e.g., D22<D5). In some implementations, the distance between the seal ring structure 218c and the seal ring structure 218b and the distance between the seal ring structure 218b and the seal ring structure 218a are approximately equal (e.g., D22=D5).

As indicated above, FIG. 12 is provided as an example. Other examples may differ from what is described with regard to FIG. 12.

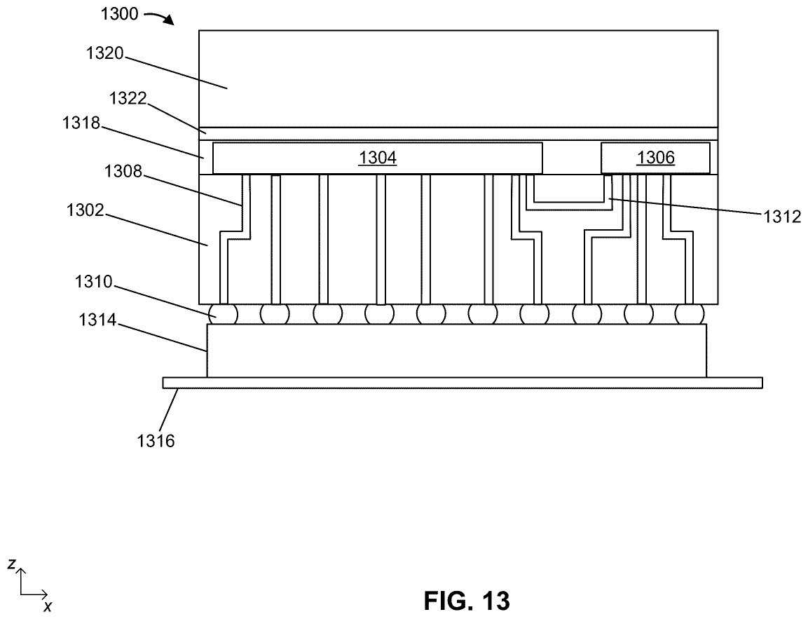

FIG. 13 is a diagram of an example implementation of a semiconductor package 1300 described herein. The semiconductor package 1300 includes a package substrate 1302 and a plurality of semiconductor devices 1304, 1306 mounted or attached to a first side (e.g., a top side) of the package substrate 1302. The semiconductor devices 1304, 1306 may be horizontally arranged (e.g., in an x-direction, in a y-direction) in the semiconductor package 1300 and/or vertically arranged in a z-direction in the semiconductor package 1300.

In some implementations, the semiconductor device 1304 may include one or more monolithic superchips, such as one or more of the example implementations of semiconductor devices 202 illustrated and described herein. In some implementations, the semiconductor device 1304 may include one or more stacked semiconductor devices 600 that include a plurality of vertically stacked monolithic superchips (e.g., vertically stacked semiconductor devices 202a and 202b).

In some implementations, the semiconductor device 1306 may include an SoC die, such as a logic die, a CPU die, a GPU die, a DSP die, an ASIC die, and/or another type of SoC die. In some implementations, the semiconductor device 1306 includes a memory die, an input/output (I/O) die, a pixel sensor die, a high voltage (HV) die, and/or another type of semiconductor die. Examples of such memory dies include a static random access memory (SRAM) die, a dynamic random access memory (DRAM) die, a NAND die, a high bandwidth memory (HBM) die, and/or another type of memory die. In some implementations, the semiconductor device 1306 includes an integrated passive device (IPD) that includes one or more passive semiconductor devices such as a resistor, a capacitor, an inductor, and/or a diode, among other examples.

The package substrate 1302 includes a plurality of electrically conductive traces 1308 that may be interconnected and may electrically connect the semiconductor devices 1304, 1306 to package connectors 1310 of the semiconductor package 1300. Moreover, the package substrate 1302 may include electrically conductive traces 1312 that electrically connect the semiconductor devices 1304 and 1306 together. The electrically conductive traces 1308 and 1312 enable signals and/or power to be routed between the semiconductor devices 1304 and 1306 and/or to be routed between the semiconductor devices 1304, 1306 and devices external to the semiconductor package 1300.

In some implementations, the package substrate 1302 is an interposer, and includes a silicon (Si) interposer, an organic interposer (e.g., an organic polymer interposer), a dielectric interposer (e.g., a silicon oxide (SiOx) or glass interposer), and/or another type of interposer. The electrically conductive traces 1308, 1312 in the package substrate 1302 may be arranged in interconnected layers referred to as redistribution layers (RDLs). Each RDL may include trenches, conductive lines, and/or other types of conductive structures that extend primarily laterally or horizontally (e.g., in the x-direction, in the y-direction) in the package substrate 1302. The RDLs in the package substrate 1302 may be interconnected by interconnect layers that include vias, conductive pillars, conductive columns, and/or other types of interconnect structures that primarily vertically extend (e.g., in the z-direction) in the package substrate 1302. The electrically conductive traces 1308, 1312 in the package substrate 1302 may include one or more electrically conductive materials such as gold (Au), copper (Cu), silver (Ag), nickel (Ni), aluminum (Al), ruthenium (Ru), cobalt (Co), titanium (Ti), tungsten (W), tin (Sn), lead (Pb), and/or palladium (Pd), among other examples.

Manufacturing the semiconductor device 1304 using the multiple-reticle exposure technique described herein enables the functions of the semiconductor package 1300 to be distributed across fewer semiconductor devices, which reduces the quantity and/or density of electrically conductive traces 1312 for interconnecting the semiconductor devices of the semiconductor package 1300. This may provide for greater I/O density in the package substrate 1302 and/or may provide for faster and lower latency communication between functional regions 210-216 of the semiconductor device 1304 (e.g., than if the functional regions 210-216 were included on separate semiconductor devices 1306 and interconnected by electrically conductive traces 1312).

The package connectors 1310 of the semiconductor package 1300 may enable the semiconductor package 1300 to be mounted or attached to a mounting structure 1314 on the system substrate 1316. The package connectors 1310 may include bonding pads, solder balls arranged in ball grid array (BGA), micro bumps, controlled collapse chip connection (C4) bumps, metal pads arranged in a land grid array (LGA), conductive pins arranged in a pin grid array (PGA), and/or another type of connection structures.

The mounting structure 1314 may include a socket, solder pads, a connector, and/or another type of mounting structure. The system substrate 1316 may include a printed circuit board such as a system board, a motherboard, a riser board, an adapter board, and/or another type of printed circuit board.

As further shown in FIG. 13, the semiconductor devices 1304, 1306 may be surrounded by an encapsulant layer 1318. The encapsulant layer 1318 may include an underfill layer, a molding compound layer, and/or another type of encapsulant layer that provides electrical isolation for the semiconductor devices 1304, 1306 as well as protection for the semiconductor devices 1304, 1306 against vibration and humidity ingress. The encapsulant layer 1318 may include an underfill material such as a polymer, one or more fillers dispersed in a resin, an epoxy-based resin, and/or another type of electrically insulating material. In some implementations, the encapsulant layer 1318 may include a plastic molding compound and/or another type of encapsulant.

The semiconductor package 1300 may include a thermal lid structure 1320 that is mounted or attached to the semiconductor devices 1304, 1306. The thermal lid structure 1320 may be thermally coupled to the semiconductor devices 1304, 1306 through a thermal interface material layer 1322. This enables the thermal lid structure 1320 to provide thermal management for the semiconductor devices 1304, 1306. In particular, the thermal lid structure 1320 may remove heat from the semiconductor devices 1304, 1306 and/or from around the semiconductor devices 1304, 1306, thereby providing cooling for the semiconductor devices 1304, 1306. The thermal lid structure 1320 may include a heatsink, a vapor chamber, heat pipes, and/or another type of thermal lid structure.

The thermal interface material layer 1322 may include a layer of thermal interface material. The thermal interface material may include a thermal interface paste, a thermal interface sheet, and/or another type of thermal interface material. In some implementations, the thermal interface material of the thermal interface material layer 1322 includes a paste that includes metal particles (e.g., gold particles, silver particles) suspended in a liquid compound. In some implementations, the thermal interface material of the thermal interface material layer 1322 includes a graphene sheet and/or another type of carbon-based thermal interface material. In some implementations, the thermal interface material of the thermal interface material layer 1322 includes a phase change material such as a polymer-based phase change material. In some implementations, the thermal interface material of the thermal interface material layer 1322 includes a liquid metal thermal interface material, which may include one or more types of metals (e.g., gallium (Ga), indium (In), tin (Sn)) in liquid form suspended in a compound.

As indicated above, FIG. 13 is provided as an example. Other examples may differ from what is described with regard to FIG. 13.

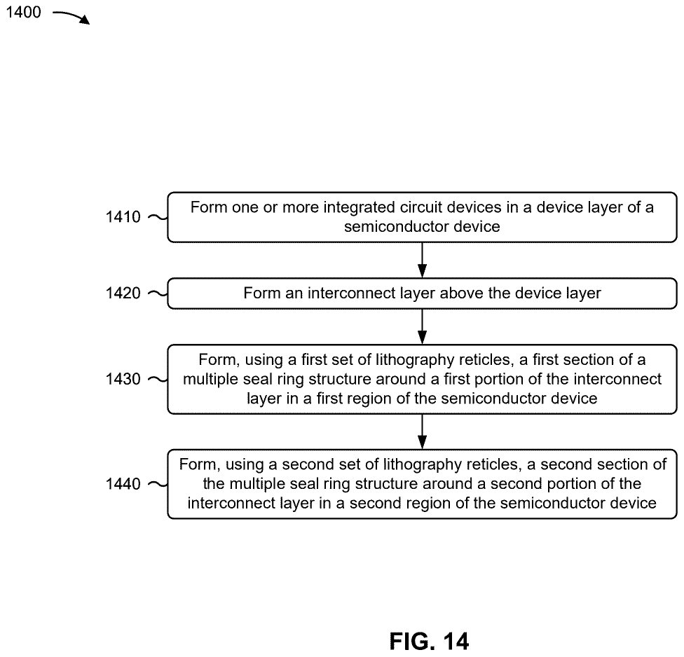

FIG. 14 is a flowchart of an example process 1400 associated with forming a semiconductor device described herein. In some implementations, one or more process blocks of FIG. 14 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 14, process 1400 may include forming one or more integrated circuit devices in a device layer of a semiconductor device (block 1410). For example, one or more semiconductor processing tools may be used to form one or more integrated circuit devices (e.g., integrated circuit device(s) 238) in a device layer (e.g., a device layer 232) of a semiconductor device (e.g., a semiconductor device 202), as described herein.

As further shown in FIG. 14, process 1400 may include forming an interconnect layer above the device layer (block 1420). For example, one or more semiconductor processing tools may be used to form an interconnect layer (e.g., a frontside interconnect layer 234) above the device layer, as described herein. In some implementations, the interconnect layer comprises one or more dielectric layers (e.g., one or more dielectric layers 242) and one or more conductive structures (e.g., one or more conductive structures 244) in the one or more dielectric layers. In some implementations, at least one of the integrated circuit devices is coupled to at least one of the one or more conductive structures.

As further shown in FIG. 14, process 1400 may include forming, using a first set of lithography reticles, a first section of a multiple seal ring structure around a first portion of the interconnect layer in a first region of the semiconductor device (block 1430). For example, one or more semiconductor processing tools may be used to form, using a first set of lithography reticles (e.g., a first set if reticles 108a), a first section of a multiple seal ring structure (e.g., a multiple seal ring structure 218) around a first portion of the interconnect layer in a first region (e.g., a lateral region 206) of the semiconductor device, as described herein.

As further shown in FIG. 14, process 1400 may include forming, using a second set of lithography reticles, a second section of the multiple seal ring structure around a second portion of the interconnect layer in a second region of the semiconductor device (block 1440). For example, one or more semiconductor processing tools may be used to form, using a second set of lithography reticles (e.g., a second set of reticles 108b), a second section of the multiple seal ring structure around a second portion of the interconnect layer in a second region (e.g., a lateral region 208) of the semiconductor device, as described herein. In some implementations, the first region and the second region are laterally adjacent in the semiconductor device. In some implementations, the first portion of the interconnect layer and the second portion of the interconnect layer are laterally adjacent in the semiconductor device. In some implementations, the first section of the multiple seal ring structure and the second section of the multiple seal ring structure are coupled together such that the multiple seal ring structure laterally and continuously surrounds the interconnect layer.

Process 1400 may include additional implementations, such as any single implementation or any combination of implementations described below and/or in connection with one or more other processes described elsewhere herein.

In a first implementation, the first set of lithography reticles is used to pattern the first region of the semiconductor device and additional first regions of additional semiconductor devices on a semiconductor wafer (e.g., a semiconductor wafer 110), and the second set of lithography reticles is used to pattern the second region of the semiconductor device and additional second regions of the additional semiconductor devices on the semiconductor wafer.

In a second implementation, alone or in combination with the first implementation, forming the first section of the multiple seal ring structure includes using a first lithography reticle (e.g., a reticle 108a) of the first set of lithography reticles to perform a first exposure operation to expose the first region to form the first section of the multiple seal ring structure in the first region, and forming the second section of the multiple seal ring structure includes using a first lithography reticle (e.g., a reticle 108b) of the second set of lithography reticles to perform a second exposure operation, after the first exposure operation, to expose the second region to form the second section of the multiple seal ring structure in the second region.

In a third implementation, alone or in combination with one or more of the first and second implementations, forming the first section of the multiple seal ring structure includes using a second lithography reticle (e.g., a reticle 108a) of the first set of lithography reticles to perform a third exposure operation, after the second exposure operation, to expose the first region to form the first section of the multiple seal ring structure in the first region, and forming the second section of the multiple seal ring structure includes using a second lithography reticle (e.g., a reticle 108b) of the second set of lithography reticles to perform a fourth exposure operation, after the third exposure operation, to expose the second region to form the second section of the multiple seal ring structure in the second region.

In a fourth implementation, alone or in combination with one or more of the first through third implementations, forming the first section of the multiple seal ring structure includes using the first set of lithography masks to form, in a first buffer region (e.g., a buffer region 902) at an interface (e.g., an interface 204) between the first region and the second region, a first segment (e.g., a segment 906a, a segment 908a) of the first section of the multiple seal ring structure (e.g., the section of the seal ring structure 218a in the lateral region 206, the section of the seal ring structure 218b in the lateral region 206) to a first lateral width, and forming the second section of the multiple seal ring structure includes using the second set of lithography masks to form, in a second buffer region (e.g., a buffer region 904) at the interface between the first region and the second region, a second segment (e.g., a segment 906b, a segment 908b) of the second section of the multiple seal ring structure (e.g., the section of the seal ring structure 218a in the lateral region 208, the section of the seal ring structure 218b in the lateral region 208) to a second lateral width, where the first segment of the first section of the multiple seal ring structure and the second segment of the second section of the multiple seal ring structure are coupled together at the interface.

In a fifth implementation, alone or in combination with one or more of the first through fourth implementations, a first pattern segment (e.g., a pattern segment 806a) in a first lithography reticle (e.g., a reticle 108a) of the first set of lithography reticles that is used to pattern the first segment has a third lateral width (dimension D6) that is less than a fourth lateral width (dimension D7) of a second pattern segment in the first lithography reticle that is used to pattern a third segment of the first section of the multiple seal ring structure outside of the first buffer region.

In a sixth implementation, alone or in combination with one or more of the first through fifth implementations, the first lateral width of the first segment of the first section of the multiple seal ring structure is greater than a third lateral width of a third segment of the first section of the multiple seal ring structure outside of the first buffer region, and the second lateral width of the second segment of the second section of the multiple seal ring structure is greater than a fourth lateral width of a fourth segment of the second section of the multiple seal ring structure outside of the second buffer region.

In a seventh implementation, alone or in combination with one or more of the first through sixth implementations, forming the first section of the multiple seal ring structure includes using the first set of lithography reticles to form a first section of an inner seal ring structure (e.g., a seal ring structure 218a) of the multiple seal ring structure and a first section of an outer seal ring structure (e.g., a seal ring structure 218b) of the multiple seal ring structure, the first section of the inner seal ring structure and the first section of the outer seal ring structure are merged together at the first segment of the first section of the multiple seal ring structure in the first buffer region.

In an eighth implementation, alone or in combination with one or more of the first through seventh implementations, forming the second section of the multiple seal ring structure includes using the second set of lithography reticles to form a second section of the inner seal ring structure of the multiple seal ring structure and a second section of the outer seal ring structure of the multiple seal ring structure, and the second section of the inner seal ring structure and the second section of the outer seal ring structure are merged together at the second segment of the second section of the multiple seal ring structure in the second buffer region.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

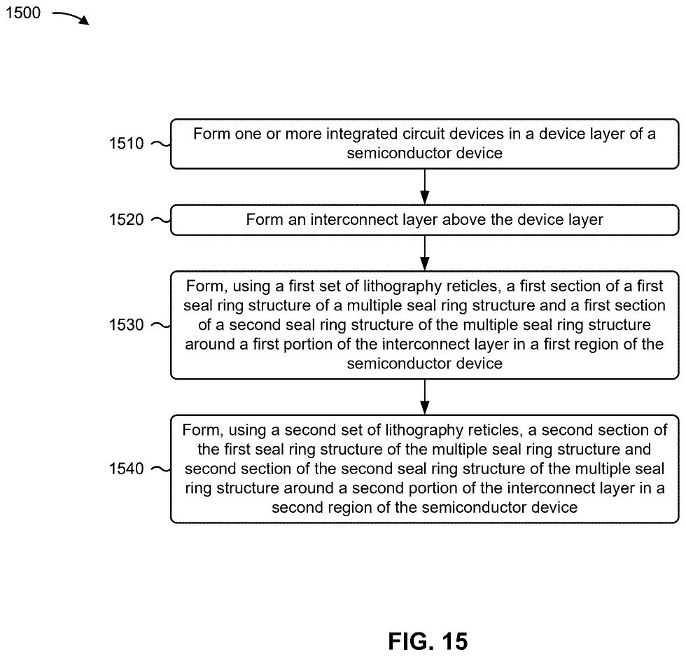

FIG. 15 is a flowchart of an example process 1500 associated with forming a semiconductor device described herein. In some implementations, one or more process blocks of FIG. 15 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 15, process 1500 may include forming one or more integrated circuit devices in a device layer of a semiconductor device (block 1510). For example, one or more semiconductor processing tools may be used to form one or more integrated circuit devices (e.g., integrated circuit device(s) 238) in a device layer (e.g., a device layer 232) of a semiconductor device (e.g., a semiconductor device 202), as described herein.

As further shown in FIG. 15, process 1500 may include forming an interconnect layer above the device layer (block 1520). For example, one or more semiconductor processing tools may be used to form an interconnect layer (e.g., a frontside interconnect layer 234) above the device layer, as described herein. In some implementations, the interconnect layer comprises one or more dielectric layers (e.g., dielectric layer(s) 242) and one or more conductive structures (e.g., conductive structure(s) 244) in the one or more dielectric layers. In some implementations, at least one of the integrated circuit devices is coupled to at least one of the one or more conductive structures.

As further shown in FIG. 15, process 1500 may include forming, using a first set of lithography reticles, a first section of a first seal ring structure of a multiple seal ring structure and a first section of a second seal ring structure of the multiple seal ring structure around a first portion of the interconnect layer in a first region of the semiconductor device (block 1530). For example, one or more semiconductor processing tools may be used to form, using a first set of lithography reticles (e.g., a first set of reticles 108a), a first section of a first seal ring structure (e.g., a seal ring structure 218a) of a multiple seal ring structure (e.g., a multiple seal ring structure 218) and a first section of a second seal ring structure (e.g., a seal ring structure 218b) of the multiple seal ring structure around a first portion of the interconnect layer in a first region (e.g., a lateral region 206) of the semiconductor device, as described herein. In some implementations, the first set of lithography reticles is used to form the first section of the first seal ring structure such that the first section of the first seal ring structure includes a cut section (e.g., a cut section 1004). In some implementations, the first set of lithography reticles is used to form the first section of the second seal ring structure such that the first section of the second seal ring structure includes a first terminal (e.g., a terminal 1002) that extends through the cut section.

As further shown in FIG. 15, process 1500 may include forming, using a second set of lithography reticles, a second section of the first seal ring structure of the multiple seal ring structure and a second section of the second seal ring structure of the multiple seal ring structure around a second portion of the interconnect layer in a second region of the semiconductor device (block 1540). For example, one or more semiconductor processing tools may be used to form, using a second set of lithography reticles (e.g., a second set of reticles 108b), a second section of the first seal ring structure of the multiple seal ring structure and a second section of the second seal ring structure of the multiple seal ring structure around a second portion of the interconnect layer in a second region (e.g., a lateral region 208) of the semiconductor device, as described herein. In some implementations, the second set of lithography reticles is used to form the second section of the first seal ring structure such that the second section of the first seal ring structure includes a second terminal (e.g., a terminal 1002) that extends laterally from the second section of the first seal ring structure.

Process 1500 may include additional implementations, such as any single implementation or any combination of implementations described below and/or in connection with one or more other processes described elsewhere herein.

In a first implementation, the first region and the second region are laterally adjacent in the semiconductor device, the first portion of the interconnect layer and the second portion of the interconnect layer are laterally adjacent in the semiconductor device, and the multiple seal ring structure laterally surrounds the interconnect layer.

In a second implementation, alone or in combination with the first implementation, the cut section is a first cut section, forming the first section of the second seal ring structure includes using the first set of lithography reticles to form the first section of the second seal ring structure such that the first section of the second seal ring structure includes a second cut section (e.g., a cut section 1102a), and forming the second section of the second seal ring structure includes using the second set of lithography reticles to form the second section of the second seal ring structure such that the second section of the second seal ring structure includes a third cut section (e.g., a cut section 1102c).

In a third implementation, alone or in combination with one or more of the first and second implementations, process 1500 includes forming, using the first set of lithography reticles, a first section of a third seal ring structure (e.g., a seal ring structure 218c) of the multiple seal ring structure around the first portion of the interconnect layer in the first region of the semiconductor device, and forming, using the second set of lithography reticles, a second section of the third seal ring structure of the multiple seal ring structure around the second portion of the interconnect layer in the second region of the semiconductor device, and first section of the third seal ring structure and the second section of the third seal ring structure are coupled together such that the third seal ring structure laterally and continuously surrounds the interconnect layer.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

In this way, a multiple-reticle exposure technique is used to manufacture monolithic superchips that have a greater amount of device area than if single-reticle exposures were used to manufacture the monolithic superchips. As described herein, different lateral regions of a semiconductor device (e.g., a monolithic superchip) may be patterned by different sets of lithography reticles. The multiple-reticle exposure technique may be expanded to manufacture a seal ring structure around the lateral regions of the semiconductor device. The multiple-reticle exposure technique may be used to manufacture the seal ring structure to have different attributes (e.g., different sizes, different shapes, different configurations) in different lateral regions of the semiconductor device, which provides for increased manufacturing flexibility in manufacturing monolithic superchips.

As described in greater detail above, some implementations described herein provide a method. The method includes forming one or more integrated circuit devices in a device layer of a semiconductor device. The method includes forming an interconnect layer above the device layer. The interconnect layer includes one or more dielectric layers and one or more conductive structures in the one or more dielectric layers. At least one of the integrated circuit devices is coupled to at least one of the one or more conductive structures. The method includes forming, using a first set of lithography reticles, a first section of a multiple seal ring structure around a first portion of the interconnect layer in a first region of the semiconductor device. The method includes forming, using a second set of lithography reticles, a second section of the multiple seal ring structure around a second portion of the interconnect layer in a second region of the semiconductor device, where the first region and the second region are laterally adjacent in the semiconductor device, where the first portion of the interconnect layer and the second portion of the interconnect layer are laterally adjacent in the semiconductor device, and where the first section of the multiple seal ring structure and the second section of the multiple seal ring structure are coupled together such that the multiple seal ring structure laterally and continuously surrounds the interconnect layer.

As described in greater detail above, some implementations described herein provide a method. The method includes forming one or more integrated circuit devices in a device layer of a semiconductor device. The method includes forming an interconnect layer above the device layer. The interconnect layer includes one or more dielectric layers and one or more conductive structures in the one or more dielectric layers. At least one of the integrated circuit devices is coupled to at least one of the one or more conductive structures. The method includes forming, using a first set of lithography reticles, a first section of a first seal ring structure of a multiple seal ring structure and a first section of a second seal ring structure of the multiple seal ring structure around a first portion of the interconnect layer in a first region of the semiconductor device, where the first set of lithography reticles is used to form the first section of the first seal ring structure such that the first section of the first seal ring structure includes a cut section, and where the first set of lithography reticles is used to form the first section of the second seal ring structure such that the first section of the second seal ring structure includes a first terminal that extends through the cut section. The method includes forming, using a second set of lithography reticles, a second section of the first seal ring structure of the multiple seal ring structure and a second section of the second seal ring structure of the multiple seal ring structure around a second portion of the interconnect layer in a second region of the semiconductor device, where the second set of lithography reticles is used to form the second section of the first seal ring structure such that the second section of the first seal ring structure includes a second terminal that extends laterally from the second section of the first seal ring structure.

As described in greater detail above, some implementations described herein provide a semiconductor device. The semiconductor device includes a device layer. The device layer includes a semiconductor layer and one or more integrated circuit devices in the semiconductor layer of the device layer. The semiconductor device includes an interconnect layer above the device layer. The interconnect layer includes one or more dielectric layers and one or more conductive structures in the one or more dielectric layers. At least one of the integrated circuit devices is coupled to at least one of the one or more conductive structures. The semiconductor device includes a multiple seal ring structure laterally surrounding the interconnect layer. The multiple seal ring structure includes a first seal ring structure in the one or more dielectric layers. A first segment of the first seal ring structure has a first lateral width in a direction that is approximately perpendicular to a length of the first seal ring structure. A second segment of the first seal ring structure has a second lateral width in the direction that is approximately perpendicular to the length of the first seal ring structure. The first lateral width and the second lateral width are different lateral widths. The multiple seal ring structure includes a second seal ring structure in the one or more dielectric layers. The second seal ring structure laterally surrounds the first seal ring structure. A third segment of the second seal ring structure has a third lateral width in a direction that is approximately perpendicular to a length of the second seal ring structure. A fourth segment of the second seal ring structure has a fourth lateral width in the direction that is approximately perpendicular to the length of the second seal ring structure. The third lateral width and the fourth lateral width are different lateral widths.

The terms “approximately” and “substantially” can indicate a value of a given quantity that varies within 5% of the value (e.g., ±1%, ±2%, ±3%, +4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming one or more integrated circuit devices in a device layer of a semiconductor device;
forming an interconnect layer above the device layer,
wherein the interconnect layer comprises one or more dielectric layers and one or more conductive structures in the one or more dielectric layers, and
wherein at least one of the integrated circuit devices is coupled to at least one of the one or more conductive structures;
forming, using a first set of lithography reticles, a first section of a multiple seal ring structure around a first portion of the interconnect layer in a first region of the semiconductor device; and
forming, using a second set of lithography reticles, a second section of the multiple seal ring structure around a second portion of the interconnect layer in a second region of the semiconductor device,
wherein the first region and the second region are laterally adjacent in the semiconductor device,
wherein the first portion of the interconnect layer and the second portion of the interconnect layer are laterally adjacent in the semiconductor device, and
wherein the first section of the multiple seal ring structure and the second section of the multiple seal ring structure are coupled together such that the multiple seal ring structure laterally and continuously surrounds the interconnect layer.

2. The method of claim 1, wherein the first set of lithography reticles is used to pattern the first region of the semiconductor device and additional first regions of additional semiconductor devices on a semiconductor wafer; and
wherein the second set of lithography reticles is used to pattern the second region of the semiconductor device and additional second regions of the additional semiconductor devices on the semiconductor wafer.

3. The method of claim 1, wherein forming the first section of the multiple seal ring structure comprises:
using a first lithography reticle of the first set of lithography reticles to perform a first exposure operation to expose the first region to form the first section of the multiple seal ring structure in the first region; and
wherein forming the second section of the multiple seal ring structure comprises:
using a first lithography reticle of the second set of lithography reticles to perform a second exposure operation, after the first exposure operation, to expose the second region to form the second section of the multiple seal ring structure in the second region.

4. The method of claim 3, wherein forming the first section of the multiple seal ring structure comprises:
using a second lithography reticle of the first set of lithography reticles to perform a third exposure operation, after the second exposure operation, to expose the first region to form the first section of the multiple seal ring structure in the first region; and
wherein forming the second section of the multiple seal ring structure comprises:
using a second lithography reticle of the second set of lithography reticles to perform a fourth exposure operation, after the third exposure operation, to expose the second region to form the second section of the multiple seal ring structure in the second region.

5. The method of claim 1, wherein forming the first section of the multiple seal ring structure comprises:
using the first set of lithography masks to form, in a first buffer region at an interface between the first region and the second region, a first segment of the first section of the multiple seal ring structure to a first lateral width; and
wherein forming the second section of the multiple seal ring structure comprises:
using the second set of lithography masks to form, in a second buffer region at the interface between the first region and the second region, a second segment of the second section of the multiple seal ring structure to a second lateral width,
wherein the first segment of the first section of the multiple seal ring structure and the second segment of the second section of the multiple seal ring structure are coupled together at the interface.

6. The method of claim 5, wherein a first pattern segment in a first lithography reticle of the first set of lithography reticles that is used to pattern the first segment has a third lateral width that is less than a fourth lateral width of a second pattern segment in the first lithography reticle that is used to pattern a third segment of the first section of the multiple seal ring structure outside of the first buffer region.

7. The method of claim 5, wherein the first lateral width of the first segment of the first section of the multiple seal ring structure is greater than a third lateral width of a third segment of the first section of the multiple seal ring structure outside of the first buffer region; and
wherein the second lateral width of the second segment of the second section of the multiple seal ring structure is greater than a fourth lateral width of a fourth segment of the second section of the multiple seal ring structure outside of the second buffer region.

8. The method of claim 5, wherein forming the first section of the multiple seal ring structure comprises:
using the first set of lithography reticles to form a first section of an inner seal ring structure of the multiple seal ring structure and a first section of an outer seal ring structure of the multiple seal ring structure,
wherein the first section of the inner seal ring structure and the first section of the outer seal ring structure are merged together at the first segment of the first section of the multiple seal ring structure in the first buffer region.

9. The method of claim 8, wherein forming the second section of the multiple seal ring structure comprises:
using the second set of lithography reticles to form a second section of the inner seal ring structure of the multiple seal ring structure and a second section of the outer seal ring structure of the multiple seal ring structure,
wherein the second section of the inner seal ring structure and the second section of the outer seal ring structure are merged together at the second segment of the second section of the multiple seal ring structure in the second buffer region.

10. A method, comprising:
forming one or more integrated circuit devices in a device layer of a semiconductor device;
forming an interconnect layer above the device layer,
wherein the interconnect layer comprises one or more dielectric layers and one or more conductive structures in the one or more dielectric layers, and
wherein at least one of the integrated circuit devices is coupled to at least one of the one or more conductive structures;
forming, using a first set of lithography reticles, a first section of a first seal ring structure of a multiple seal ring structure and a first section of a second seal ring structure of the multiple seal ring structure around a first portion of the interconnect layer in a first region of the semiconductor device,
wherein the first set of lithography reticles is used to form the first section of the first seal ring structure such that the first section of the first seal ring structure includes a cut section, and
wherein the first set of lithography reticles is used to form the first section of the second seal ring structure such that the first section of the second seal ring structure includes a first terminal that extends through the cut section; and
forming, using a second set of lithography reticles, a second section of the first seal ring structure of the multiple seal ring structure and a second section of the second seal ring structure of the multiple seal ring structure around a second portion of the interconnect layer in a second region of the semiconductor device,
wherein the second set of lithography reticles is used to form the second section of the first seal ring structure such that the second section of the first seal ring structure includes a second terminal that extends laterally from the second section of the first seal ring structure.

11. The method of claim 10, wherein the first region and the second region are laterally adjacent in the semiconductor device;
wherein the first portion of the interconnect layer and the second portion of the interconnect layer are laterally adjacent in the semiconductor device; and
wherein the multiple seal ring structure laterally surrounds the interconnect layer.

12. The method of claim 10, wherein the cut section is a first cut section;
wherein forming the first section of the second seal ring structure comprises:
using the first set of lithography reticles to form the first section of the second seal ring structure such that the first section of the second seal ring structure includes a second cut section; and
wherein forming the second section of the second seal ring structure comprises:
using the second set of lithography reticles to form the second section of the second seal ring structure such that the second section of the second seal ring structure includes a third cut section.

13. The method of claim 10, further comprising:
forming, using the first set of lithography reticles, a first section of a third seal ring structure of the multiple seal ring structure around the first portion of the interconnect layer in the first region of the semiconductor device; and
forming, using the second set of lithography reticles, a second section of the third seal ring structure of the multiple seal ring structure around the second portion of the interconnect layer in the second region of the semiconductor device; and
wherein the first section of the third seal ring structure and the second section of the third seal ring structure are coupled together such that the third seal ring structure laterally and continuously surrounds the interconnect layer.

14. A semiconductor device, comprising:
a device layer comprising a semiconductor layer;
one or more integrated circuit devices in the semiconductor layer of the device layer;
an interconnect layer above the device layer, comprising:
one or more dielectric layers; and
one or more conductive structures in the one or more dielectric layers,
wherein at least one of the integrated circuit devices is coupled to at least one of the one or more conductive structures;
a multiple seal ring structure laterally surrounding the interconnect layer, comprising:
a first seal ring structure in the one or more dielectric layers,
wherein a first segment of the first seal ring structure has a first lateral width in a direction that is approximately perpendicular to a length of the first seal ring structure,
wherein a second segment of the first seal ring structure has a second lateral width in the direction that is approximately perpendicular to the length of the first seal ring structure, and
wherein the first lateral width and the second lateral width are different lateral widths; and
a second seal ring structure in the one or more dielectric layers,
wherein the second seal ring structure laterally surrounds the first seal ring structure,
wherein a third segment of the second seal ring structure has a third lateral width in a direction that is approximately perpendicular to a length of the second seal ring structure,
wherein a fourth segment of the second seal ring structure has a fourth lateral width in the direction that is approximately perpendicular to the length of the second seal ring structure, and
wherein the third lateral width and the fourth lateral width are different lateral widths.

15. The semiconductor device of claim 14, wherein the first segment of the first seal ring structure and the third segment of the second seal ring structure are spaced apart from each other;
wherein the first segment of the first seal ring structure and the third segment of the second seal ring structure are approximately parallel to each other;
wherein the second segment of the first seal ring structure and the fourth segment of the second seal ring structure are spaced apart from each other; and
wherein the second segment of the first seal ring structure and the fourth segment of the second seal ring structure are approximately parallel to each other.

16. The semiconductor device of claim 14, wherein the first lateral width is greater than the second lateral width; and
wherein the third lateral width is greater than the fourth lateral width.

17. The semiconductor device of claim 14, wherein the second lateral width is greater than the first lateral width; and
wherein the fourth lateral width is greater than the second lateral width.

18. The semiconductor device of claim 17, wherein the second segment of the first seal ring structure extends laterally toward the second seal ring structure in the direction that is approximately perpendicular to the length of the first seal ring structure; and
wherein the fourth segment of the second seal ring structure extends laterally toward the first seal ring structure in the direction that is approximately perpendicular to the length of the second seal ring structure.

19. The semiconductor device of claim 17, wherein the second segment of the first seal ring structure and the fourth segment of the second seal ring structure are merged together.

20. The semiconductor device of claim 17, wherein the first lateral width is greater than the third lateral width.
